(19) United States
(12) Patent Application Publication
(10) Pub. No.: US 2022/0131125 A1
(43) Pub. Date: Apr. 28, 2022

(54) SURFACE COATED POROUS SUBSTRATES AND PARTICLES AND SYSTEMS AND METHODS THEREOF

(71) Applicant: Sila Nanotechnologies Inc., Alameda, CA (US)

(72) Inventors: Gleb YUSHIN, Atlanta, GA (US); Laura GERBER, Oakland, CA (US); Matthew CLARK, Oakland, CA (US); Valentin LULEVICH, Stockton, CA (US); Mareva FEVRE, Oakland, CA (US); Eric LACHMAN, Dublin, CA (US)

(21) Appl. No.: 17/451,772

(22) Filed: Oct. 21, 2021

Related U.S. Application Data
(60) Provisional application No. 63/104,077, filed on Oct. 22, 2020.

(51) Int. Cl. H01M 4/04; H01M 4/66; H01M 4/134; H01M 4/133; H01M 4/1393; H01M 4/1395; H01M 10/0525

(52) U.S. Cl. CPC H01M 4/0428; H01M 4/0404; H01M 4/661; H01M 10/0525; H01M 4/133; H01M 4/1393; H01M 4/1395; H01M 4/134

(57) ABSTRACT

In an aspect, a functional, a conformal surface layer coating on an internal surface of pores of a porous substrate may be formed via exposure to gas streams of precursor molecules in an atomic-layer deposition (ALD) reactor. In another aspect, a functional surface layer coating on particles of a powder (or particle powder) may be formed via exposure to gas streams of precursor molecules in an ALD reactor. In another aspect, an ALD reactor system may be configured with mechanisms for supplying gas streams of precursor molecules to form the conformal surface layer(s). In another aspect, the porous electrode(s) and/or particle(s) with the conformal surface coating(s) may be made part of a Li-ion battery cell, which in turn be made part of a Li-ion battery module or Li-ion battery pack.

### CROSS-REFERENCE TO RELATED APPLICATIONS

The present application for patent claims the benefit of U.S. Provisional Application No. 63/104,077, entitled “SURFACE COATED BATTERY ELECTRODES AND BATTERY ELECTRODE PARTICLES AND METHODS THEREOF,” filed Oct. 22, 2020, assigned to the assignee hereof, and expressly incorporated herein by reference in its entirety.

### BACKGROUND

### Field

Embodiments of the present disclosure relate generally to energy storage devices, and more particularly to battery technology and the like.

### Background

Owing in part to their relatively high energy densities, relatively high specific energy, light weight, and potential for long lifetimes, advanced rechargeable and primary (not rechargeable) batteries are desirable for a wide range of wearables, portable consumer electronics, electric vehicles, grid storage, aerospace and other important applications.

However, despite the increasing commercial prevalence of rechargeable Li-ion batteries, further development of these and other related batteries is needed, particularly for potential applications in battery-powered electrical vehicles, consumer electronics, aerospace applications, electrical grid, among others. In particular, fabrication of electrodes or electrode particles with improving battery cycle stability, calendar life, temperature performance, rate performance and other performance characteristics is strongly desired. Unfortunately, conventional routes to produce such electrodes typically fail to achieve the desired characteristics or require unacceptable excessive efforts, time, and costs.

Accordingly, there remains a need for improved battery cells, components, and other related materials and manufacturing processes.

### SUMMARY

Embodiments disclosed herein address the above stated needs by providing improved battery components, improved batteries made therefrom, and methods of making and using the same.

An aspect is directed to a porous electrode for use in an Li-ion battery cell, comprising a current collector, an active material-comprising coating, and one or more functional, conformal surface layer coatings at least partially deposited on an internal surface of pores of the porous electrode, wherein the one or more functional, conformal surface layer coatings exhibit an average thickness in the range from around 0.3 nm to around 50 nm on at least part of the internal surface, and wherein the porous electrode exhibits an areal loading of more than about 4 mAh/cm² (e.g., in the range of 4-5 mAh/cm² or 5-6 mAh/cm² or 6-7 mAh/cm² or 7-8 mAh/cm² or 8-12 mAh/cm² or 12-20 mAh/cm², etc.). In some designs, the porous electrode is integrated into the Li-ion battery cell, and further comprises electrolyte filling pores of the electrode and ionically coupling the porous electrode with another porous electrode, and a separator electrically separating the porous electrode from another porous electrode (e.g., a cathode from an anode or an anode from a cathode). In some designs, the porous electrode corresponds to an anode electrode for use in the Li-ion battery cell. In some designs, the anode electrode comprises silicon (Si) or carbon (C) or both. In some designs, the porous electrode corresponds to a cathode electrode for use in the Li-ion battery cell (e.g., intercalation-type cathode or conversion-type cathode or mixed-type cathode, etc.). In some designs, the active material-comprising coating comprises electrode particles, and the one or more functional, conformal surface layer coatings are at least partially deposited at least upon outer surfaces of the electrode particles that are accessible via the pores of the porous electrode. In some designs, the one or more functional, conformal surface layer coatings exhibit the average thickness in the range from around 0.3 nm to around 50 nm (e.g., from around 0.3 nm to around 3 nm or from around 3 nm to around 5 nm or from around 5 nm to around 10 nm or from around 10 nm to around 20 nm or from around 20 nm to around 50 nm, depending on the conformal layer chemistry, morphology, electrode composition and overall cell chemistry and operational conditions) across a bottom 20% part of the active material-comprising coating that is on a first side of the active material-comprising coating adjacent to the current collector, or across a top 20% part of the active material-comprising coating that is on a second side of the active material-comprising coating away from the current collector (e.g., adjacent to the separator), or across an entirety of the active material-comprising coating.

Another aspect is directed to a Li-ion battery cell, comprising an electrode particle comprising an active material and internal pores, wherein one or more functional, conformal suitable surface layer coatings are at least partially deposited on an internal surface of the internal pores of the electrode particle, and wherein the one or more functional, conformal surface layer coatings exhibit an average thickness in the range from around 0.3 nm to around 50 nm (e.g., from around 0.3 nm to around 3 nm or from around 3 nm to around 5 nm or from around 5 nm to around 10 nm or from around 10 nm to around 20 nm or from around 20 nm to around 50 nm, depending on the conformal layer chemistry, morphology, electrode composition and overall cell chemistry and operational conditions) on at least part of the internal surface. In some designs, the electrode particle is an anode particle or a cathode particle. In some designs, the electrode particle comprises one or more closed internal pores that are inaccessible via the internal pores and upon which no functional, conformal surface layer coating is deposited.

In an aspect, a method of forming a functional, conformal surface layer coating on an internal surface of pores of a porous substrate includes (A1) supplying a first gas stream of first precursor molecules to a porous substrate at a first region in an atomic-layer deposition (ALD) reactor, a portion of the first precursor molecules forming a chemically-bonded layer on the internal surface, another portion of the first precursor molecules becoming physisorbed first precursor molecules; (A2) moving the porous substrate from the first region to a second region in the ALD reactor, the second region being spatially separated from the first region; and (A3) purging the physisorbed first precursor molecules from the porous substrate at the second region; (A4) moving the porous substrate from the second to a third region in the ALD reactor, the third region being spatially separated from the first region and the second region; (A5) supplying a second gas stream of second precursor molecules to the porous substrate at the third region, a portion of the second precursor molecules reacting with the first precursor molecules in the chemically-bonded layer to form at least a portion of the functional, conformal surface layer coating, another portion of the second precursor molecules becoming physisorbed second precursor molecules; (A6) moving the porous substrate from the third region to a fourth region in the ALD reactor, the fourth region being spatially separated from the first region, the second region, and the third region; and (A7) purging the physisorbed second precursor molecules from the porous substrate at the fourth region.

In some aspects, (A3) comprises supplying a first inert gas stream to the porous substrate at the second region; and (A7) comprises supplying a second inert gas stream to the porous substrate at the fourth region.

In some aspects, the supplying of the gas stream in one or more of (A1), (A3), (A5), and (A7) comprises supplying the gas stream from one or more supply nozzles such that the gas stream flows from the one or more supply nozzles through the porous substrate to one or more exhaust nozzles, the one or more exhaust nozzles removing the gas stream from the ALD reactor, a spacing between (a) the one or more supply nozzles and the one or more exhaust nozzles and (b) the porous substrate ranging from around 5 microns to around 1 mm, a pressure gradient between the one or more supply nozzles and the one or more exhaust nozzles ranging between around 0.1 atm to around 1000 atm.

In some aspects, (A1) through (A7) are repeated.

In some aspects, the first precursor molecules and/or the second precursor molecules are selected from: metal alkoxides, metal 2,2,6,6-tetramethyl-3,5-heptanedionates, isobutyl-metals, methyl-metals, dimethylamido-metals, cyclopentadienyl-metals, cyclopentadienyl-metal-hydrides, methyl-η⁵-cyclopentadienyl-methoxymethyl-metals, ethyl-metal-hydrides, methyl-metal-hydrides, butyl-metal-hydrides, methyl-pentamethylcyclopentadienyl-metals, metal-alkoxide-(2,2,6,6-tetramethyl-3,5-heptanedionate), pentafluorophenyl-metals, ethyl-metals, phenyl-metals, N,N-bis(trimethylsilyl)amide-metals, butylcyclopentadienyl-metals, metal halides, tert-butoxy-metals, tert-pentoxy-metals, and hexamethyldisilazane.

In some aspects, the first precursor molecules and/or the second precursor molecules comprise one or more of the following: reductants, lithium sources, fluorine sources, aluminum sources, oxygen sources, phosphorous sources, nitrogen sources, iron sources, titanium sources, lanthanum sources, zirconium sources, cerium sources, and niobium sources.

In some aspects, the method further includes (A8) fluorinating the porous substrate, after formation of at least one portion of the functional, conformal surface layer coating.

In some aspects, the method further includes (A9) annealing the porous substrate, after formation of at least one portion of the functional, conformal surface layer coating.

In some aspects, the porous substrate comprises a current collector and a porous electrode coating on the current collector.

In some aspects, the current collector is porous.

In some aspects, the current collector comprises Cu or Al.

In some aspects, the porous substrate corresponds to at least part of an anode electrode for a Li-ion battery cell.

In some aspects, the anode electrode comprises silicon and/or carbon.

In some aspects, the porous substrate corresponds to at least part of a cathode electrode for a Li-ion battery cell.

In an aspect, a method of forming a functional surface layer coating on particles of a particle powder, includes the steps of: (B1) supplying a first gas stream of first precursor molecules to the particles of the particle powder at a first region in a tubular atomic-layer deposition (ALD) reactor, a portion of the first precursor molecules forming a chemically-bonded layer on the particles of the particle powder, another portion of the first precursor molecules becoming physisorbed first precursor molecules; (B2) moving the particle powder from the first region to a second region in the tubular ALD reactor, the second region being spatially separated from the first region; (B3) purging the physisorbed first precursor molecules from the particle powder at the second region; (B4) moving the particle powder from the second to a third region in the tubular ALD reactor, the third region being spatially separated from the first region and the second region; (B5) supplying a second gas stream of second precursor molecules to the particle powder at the third region, a portion of the second precursor molecules reacting with the first precursor molecules in the chemically-bonded layer to form at least a portion of the functional surface layer coating, another portion of the second precursor molecules becoming physisorbed second precursor molecules; (B6) moving the particle powder from the third region to a fourth region in the tubular ALD reactor, the fourth region being spatially separated from the first region, the second region, and the third region; and (B7) purging the physisorbed second precursor molecules from the particle powder at the fourth region.

In some aspects, the particle powder is moved from the first region to the second region at (B2), from the second region to the third region at (B4), and from the third region to the fourth region at (B6) via a rotating auger inside the tubular ALD reactor.

In some aspects, (B3) comprises supplying a first inert gas stream to the particle powder at the second region; and (B7) comprises supplying a second inert gas stream to the particle powder at the fourth region.

In some aspects, the supplying of the gas stream in one or more of (B1), (B3), (B5), and (B7) comprises supplying the gas stream from one or more supply nozzles such that the inert gas stream flows from the one or more supply nozzles through the particle powder to one or more exhaust nozzles, the one or more exhaust nozzles removing the gas stream from the tubular ALD reactor, a pressure gradient between the one or more supply nozzles and the one or more exhaust nozzles ranging between around 0.1 atm to around 1000 atm.

In some aspects, steps (B1) through (B7) are repeated.

In some aspects, the first precursor molecules and/or the second precursor molecules are selected from: metal alkoxides, metal 2,2,6,6-tetramethyl-3,5-heptanedionates, isobutyl-metals, methyl-metals, dimethylamido-metals, cyclopentadienyl-metals, cyclopentadienyl-metal-hydrides, methyl-η⁵-cyclopentadienyl-methoxymethyl-metals, ethyl-metal-hydrides, methyl-metal-hydrides, butyl-metal-hydrides, methyl-pentamethylcyclopentadienyl-metals, metal-alkoxide-(2,2,6,6-tetramethyl-3,5-heptanedionate), pentafluorophenyl-metals, ethyl-metals, phenyl-metals, N,N-bis(trimethylsilyl)amide-metals, butylcyclopentadienyl-metals, metal halides, tert-butoxy-metals, tert-pentoxy-metals, and hexamethyldisilazane.

In some aspects, the first precursor molecules and/or the second precursor molecules comprise one or more of the following: reductants, lithium sources, fluorine sources, aluminum sources, oxygen sources, phosphorous sources, nitrogen sources, iron sources, titanium sources, lanthanum sources, zirconium sources, cerium sources, and niobium sources.

In some aspects, the method further includes (B8) fluorinating the particle powder, after formation of at least one portion of the functional surface layer coating.

In some aspects, the method further includes (B9) annealing the particle powder, after formation of at least one portion of the functional surface layer coating.

In some aspects, the particles of the particle powder comprise anode particles or cathode particles.

In an aspect, an atomic-layer deposition (ALD) system for forming a functional, conformal surface layer coating on an internal surface of pores of a porous substrate, includes an ALD reactor comprising a plurality of regions, each one of the regions being spatially separated from others of the regions, the plurality of regions including a first region, a second region, a third region, and a fourth region; a substrate mover configured to move the porous substrate in the ALD reactor including moving the porous substrate from the first region to the second region, from the second region to the third region, and from the third region to the fourth region; one or more first gas supply nozzles at the first region for supplying a first gas stream of first precursor molecules to the porous substrate, a portion of the first precursor molecules forming a chemically-bonded layer on the internal surface, another portion of the first precursor molecules becoming physisorbed first precursor molecules; one or more first gas exhaust nozzles at the first region for removing the first gas stream from the ALD reactor, the first gas stream flowing from the first gas supply nozzles through the porous substrate to the first gas exhaust nozzles; one or more first inert gas supply nozzles at the second region for supplying a first inert gas stream to the porous substrate; one or more first inert gas exhaust nozzles at the second region for removing the first inert gas stream from the ALD reactor, the first inert gas stream flowing from the first inert gas supply nozzles through the porous substrate to the first inert gas exhaust nozzles, the physisorbed first precursor molecules being purged from the porous substrate by the first inert gas stream; one or more second gas supply nozzles at the third region for supplying a second gas stream of second precursor molecules to the porous substrate, a portion of the second precursor molecules reacting with the first precursor molecules in the chemically-bonded layer to form at least a portion of the functional, conformal surface layer coating, another portion of the second precursor molecules becoming physisorbed second precursor molecules; one or more second gas exhaust nozzles at the third region for removing the second gas stream from the ALD reactor, the second gas stream flowing from the second gas supply nozzles through the porous substrate to the second gas exhaust nozzles; one or more second inert gas supply nozzles at the fourth region for supplying a second inert gas stream to the porous substrate; and one or more second inert gas exhaust nozzles at the fourth region for removing the second inert gas stream from the ALD reactor, the second inert gas stream flowing from the second inert gas supply nozzles through the porous substrate to the second inert gas exhaust nozzles, the physisorbed second precursor molecules being purged from the porous substrate by the second inert gas stream.

In some aspects, for one or more of (1) the first gas supply nozzles and the first gas exhaust nozzles, (2) the first inert gas supply nozzles and the first inert gas exhaust nozzles, (3) the second gas supply nozzles and the second gas exhaust nozzles, and (4) the second inert gas supply nozzles and the second inert gas exhaust nozzles, a pressure gradient between the respective gas supply nozzles and the respective gas exhaust nozzles ranges between around 0.1 atm to around 1000 atm.

In an aspect, an atomic-layer deposition (ALD) system for forming a functional, surface layer coating on individual particles of a particle powder includes a tubular ALD reactor comprising a plurality of regions, each one of the regions being spatially separated from others of the regions, the plurality of regions including a first region, a second region, a third region, and a fourth region; a powder mover inside the tubular ALD reactor configured to move the powder in the tubular ALD reactor including moving the powder from the first region to the second region, from the second region to the third region, and from the third region to the fourth region; one or more first gas supply nozzles at the first region for supplying a first gas stream of first precursor molecules to the powder, a portion of the first precursor molecules forming a chemically-bonded layer on the particles, another portion of the first precursor molecules becoming physisorbed first precursor molecules; one or more first gas exhaust nozzles at the first region for removing the first gas stream from the tubular ALD reactor, the first gas stream flowing from the first gas supply nozzles through the powder to the first gas exhaust nozzles; one or more first inert gas supply nozzles at the second region for supplying a first inert gas stream to the powder; one or more first inert gas exhaust nozzles at the second region for removing the first inert gas stream from the tubular ALD reactor, the first inert gas stream flowing from the first inert gas supply nozzles through the powder to the first inert gas exhaust nozzles, the physisorbed first precursor molecules being purged from the powder by the first inert gas stream; one or more second gas supply nozzles at the third region for supplying a second gas stream of second precursor molecules to the powder, a portion of the second precursor molecules reacting with the first precursor molecules in the chemically-bonded layer to form at least a portion of the functional, surface layer coating, another portion of the second precursor molecules becoming physisorbed second precursor molecules; one or more second gas exhaust nozzles at the third region for removing the second gas stream from the tubular ALD reactor, the second gas stream flowing from the second gas supply nozzles through the powder to the second gas exhaust nozzles; one or more second inert gas supply nozzles at the fourth region for supplying a second inert gas stream to the powder; and one or more second inert gas exhaust nozzles at the fourth region for removing the second inert gas stream from the tubular ALD reactor, the second inert gas stream flowing from the second inert gas supply nozzles through the powder to the second inert gas exhaust nozzles, the physisorbed second precursor molecules being purged from the powder by the second inert gas stream.

In some aspects, for one or more of (1) the first gas supply nozzles and the first gas exhaust nozzles, (2) the first inert gas supply nozzles and the first inert gas exhaust nozzles, (3) the second gas supply nozzles and the second gas exhaust nozzles, and (4) the second inert gas supply nozzles and the second inert gas exhaust nozzles, a pressure gradient between the respective gas supply nozzles and the respective gas exhaust nozzles ranges between around 0.1 atm to around 1000 atm.

In some aspects, the powder mover comprises a rotating auger.

In an aspect, a porous electrode for use in an Li-ion battery cell includes a current collector; an active material-comprising coating; and one or more functional, conformal surface layer coatings at least partially deposited on an internal surface of pores of the porous electrode, wherein the one or more functional, conformal surface layer coatings exhibit an average thickness in the range from around 0.3 nm to around 50 nm on at least part of the internal surface, and wherein the porous electrode exhibits an areal capacity loading of more than about 4 mAh/cm².

In some aspects, the standard deviation of the surface layer coating thickness is less than or equal to 4 nm.

In some aspects, the porous electrode is integrated into the Li-ion battery cell, further comprising: electrolyte filling pores of the electrode and ionically coupling the porous electrode with another porous electrode; and a separator electrically separating the porous electrode from the another porous electrode.

In some aspects, the porous electrode corresponds to an anode electrode for use in the Li-ion battery cell.

In some aspects, the anode electrode comprises silicon (Si) or carbon (C) or both.

In some aspects, the porous electrode corresponds to a cathode electrode for use in the Li-ion battery cell.

In some aspects, the active material-comprising coating comprises electrode particles, and the one or more functional, conformal surface layer coatings are at least partially deposited at least upon outer surfaces of the electrode particles that are accessible via the pores of the porous electrode.

In some aspects, the one or more functional, conformal surface layer coatings exhibit the average thickness in the range from around 0.3 nm to around 50 nm: across a bottom 20% part of the active material-comprising coating that is on a first side of the active material-comprising coating adjacent to the current collector, or across a top 20% part of the active material-comprising coating that is on a second side of the active material-comprising coating away from the current collector, or across an entirety of the active material-comprising coating.

In an aspect, a Li-ion battery cell includes the porous electrode.

In some aspects, the Li-ion battery cell is capable of charging to above about 4.4 V during operation, or the Li-ion battery cell is capable of exhibiting a calendar life in excess of about 10 years, or wherein the Li-ion battery cell is capable of remaining operable in response to exposure to over about 60° C. for over about 10 hours during manufacturing, operation or storage, or any combination thereof.

In an aspect, a Li-ion battery module or Li-ion battery pack includes the Li-ion battery cell.

In an aspect, a battery electrode composition for use in an Li-ion battery cell includes an electrode particle comprising an active material and internal pores, wherein one or more functional, conformal surface layer coatings are at least partially deposited on an internal surface of the internal pores of the electrode particle, and wherein the one or more functional, conformal surface layer coatings exhibit an average thickness in the range from around 0.3 nm to around 50 nm on at least part of the internal surface.

In some aspects, the electrode particle is an anode particle or a cathode particle.

In some aspects, the electrode particle comprises one or more closed internal pores that are inaccessible via the internal pores and upon which no functional, conformal surface layer coating is deposited.

In an aspect, a Li-ion battery cell includes the battery electrode composition.

In some aspects, the Li-ion battery cell is capable of charging to above about 4.4 V during operation, or the Li-ion battery cell is capable of exhibiting a calendar life in excess of about 10 years, wherein the Li-ion battery cell is capable of remaining operable in response to exposure to over about 60° C. for over about 10 hours during manufacturing, operation or storage, or any combination thereof.

In an aspect, a Li-ion battery module or Li-ion battery pack includes the Li-ion battery cell.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of embodiments of the invention and are provided solely for illustration of the embodiments and not limitation thereof.

FIG. 1 illustrates an example (e.g., Li-ion) battery in which the components, materials, methods, and other techniques described herein, or combinations thereof, may be applied according to various embodiments.

FIGS. 2A-2C illustrate example ALD process flow processes, according to various embodiments.

FIGS. 3A, 3B, 4, 5A and 5B illustrate example embodiments of the selected ALD systems for the deposition of conformal coatings on the surface of porous battery components (e.g., Li-ion battery electrodes) or other (e.g., porous or flexible) planar substrates, according to various embodiments.

FIGS. 6, 7 illustrate example surface functionalization of electrodes or electrode particles, according to various embodiments.

FIGS. 8, 9A, 9B illustrate example embodiments of the selected ALD systems for the deposition of conformal coatings on the surface of powders (e.g., Li-ion battery electrode material powders), according to various embodiments.

FIGS. 10, 11A-11B and 12 illustrate example surface coatings deposited on the active electrode materials, according to various embodiments.

FIGS. 13A and 13B show illustrative examples of methods that may be involved in the fabrication of improved battery (e.g., Li-ion battery) cell or module or pack or battery-powered device, according to various embodiments.

### DETAILED DESCRIPTION

Aspects of the present invention are disclosed in the following description and related drawings directed to specific embodiments of the invention. The term “embodiments of the invention” does not require that all embodiments of the invention include the discussed feature, advantage, process, or mode of operation, and alternate embodiments may be devised without departing from the scope of the invention. Additionally, well-known elements of the invention may not be described in detail or may be omitted so as not to obscure other, more relevant details. Further, the terminology of “at least partially” is intended for interpretation as “partially, substantially or completely”.

While the description below may describe certain examples in the context of rechargeable and primary Li and Li-ion batteries (for brevity and convenience, and because of the current popularity of Li technology), it will be appreciated that various aspects may be applicable to other rechargeable and primary batteries (such as Na and Na-ion, Mg and Mg-ion, K and K-ion, Ca and Ca-ion, Al and Al-ion, Cs and Cs-ion, Ca and Ca-ion, Zn and Zn-ion, Fe and Fe-ion and other metal-ion batteries, anion-ion (e.g., F-ion) batteries, dual ion batteries, alkaline batteries, acid batteries, solid state batteries, etc.) as well as electrochemical capacitors (including double layer capacitors and so-called supercapacitors or pseudo-capacitors) with various electrolytes and various hybrid devices.

While the description below may describe certain examples in the context of depositing a conformal “functional” surface coating on electrode(s), electrode particles, separator(s) (e.g., a separator membrane or a separator coating), conductive additives, binder(s), current collector(s) or other parts of the electrodes, it will be appreciated that various aspects may be applicable to depositing “active” materials (e.g., materials for Li or Na-ion storage, in case of Li metal, Na metal, Li-ion or Na-ion batteries or other electrochemically active materials for other batteries or supercapacitors or hybrid devices) within the electrode(s) or the electrode particles of energy storage devices. Note that under “functional” coatings we imply surface coatings deposited to attain certain supplementary functions for performance improvements, such as protecting against undesirable side reactions between “active” electrode material or electrode particles and the electrolyte, improving cycle stability of the energy storage device (e.g., a battery), improving calendar life of the energy storage device (e.g., a battery), improving thermal stability of the electrode(s), improving thermal performance of the energy storage device (e.g., a battery), increasing maximum charge or storage voltage of the energy storage device (e.g., a battery), improving electrolyte wetting with the electrode or the separator or both (or otherwise favorably tuning the interfaces and interphases between different energy storage device components), improving rate performance of the energy storage device, or improving other useful characteristics of the energy storage device (e.g., a Li, Li-ion, Na or Na-ion battery). Such functional coatings do not necessarily include any functional groups, although this is possible for some applications. Also note that the deposited “active” materials may be in the form of particles of various shapes and sizes or in the form of a uniform surface layer (e.g., a shell). It will also be appreciated that in some designs, the deposited surface layer may serve for multiple purposes. For example, the deposited surface layer may be deposited not only to improve energy storage device stability, but also store Li or Na ions during electrochemical energy storage reactions.

While the description below may describe certain examples in the context of depositing a conformal “functional” surface coating onto the surface of porous electrode(s), electrode particles, binder(s), or other parts of the electrodes, it will be appreciated that various aspects may be applicable to at least partial infiltrating the coating material into the bulk of the electrode particles, binder(s) or other parts of the electrodes.

While the description below may describe certain examples in the context of depositing a conformal inorganic surface coating onto the surface of porous electrode(s), electrode particles, separator(s), binder(s), or other parts of the electrodes, it will be appreciated that various aspects may be applicable to depositing organic (e.g., a polymer) or mixed organic-inorganic composite surface coatings.

While the description below may describe certain examples of the material formulations for several specific types of cathode or anode materials, it will be appreciated that various aspects may be applicable to various other electrode materials.

While the description below may describe certain examples of battery electrode compositions in the form of a powder, in some designs, the powder form of the battery electrode composition may alternatively (i.e., interchangeably) be characterized as a particle powder (e.g., a powder comprising electrode particles and/or precursor particles, etc.).

While the description below may also describe certain examples of the cathode material formulations (for use in combination with melt-infiltrated and other suitable solid electrolytes) either in a Li-free (e.g., charged) state or in a fully lithiated (e.g., discharged) state, it will be appreciated that various aspects may be applicable to various Li-containing electrodes (e.g., in either a partially or fully discharged state) or to essentially Li-free electrodes (e.g., in either a partially or fully charged state).

While the description below may describe certain examples of the electrolytes and methods of their introduction to several types of batteries or other energy storage devices, it will be appreciated that various aspects may be applicable to various other electrolyte materials and various methods of their introduction within the cells. While the description below may describe certain examples in the context of one type or composition of the electrolyte in cells, it will be appreciated that various aspects may be applicable to cells comprising two or three or more electrolyte compositions.

While the description below may describe certain examples of the binders for the formation of electrodes, it will be appreciated that various aspects may be applicable to various other binders and their combinations or the binder-free electrodes.

While the description below may describe certain examples of the electrode formation (e.g., via a slurry coating/drying/calendaring method), it will be appreciated that various aspects may be applicable to various other electrode preparation methods (e.g., various dry electrode coatings, various standalone electrode preparations, sintering, etc. etc.).

While the description below may describe certain examples of the particular range of electrode thickness, electrode areal capacity loadings, electrode porosities and other electrode properties, it will be appreciated that various aspects may be applicable to various other ranges of the electrodes' thicknesses, capacity loadings, electrode porosities and other properties.

While the description below may describe certain examples of the energy storage device (e.g., a battery) fabrication method(s), it will be appreciated that various aspects may be applicable to various other energy storage device (e.g., a battery) fabrication methods.

While the description below may describe certain embodiments in the context of preparation of porous electrodes for certain energy storage devices (e.g., Li or Li-ion batteries), it will be appreciated that various aspects may be applicable for preparation of porous parts (e.g., electrodes or separators or solid electrolytes or current collectors, etc.) of other energy storage devices or various energy conversion devices (e.g., fuel cells) or various energy harvesting devices (e.g., solar cells) or various catalysts or various sensors.

While the description below may describe certain embodiments in the context of preparation of porous electrodes for energy storage devices, it will be appreciated that various aspects may be applicable for preparation of other porous bodies comprised of compacted individual particles.

While the description below may describe certain embodiments in the context of preparation of porous electrodes comprising certain polymer binders, it will be appreciated that various aspects may be applicable to porous electrodes (and other porous bodies) comprising other types of binder(s) or mixture of binders or not comprising binder at all.

While the description below may describe certain embodiments in the context of depositing of an individual surface coating, it will be appreciated that two, three or more surface coating layers of distinctly different composition or morphology may be deposited in some designs.

While the description below may describe certain embodiments in the context of depositing of suitable surface coating(s) on the surface of electrode or electrode particles, it will be appreciated that suitable surface coating(s) may also be deposited on the surface of the separator(s) (e.g., imbedded separator layer(s) or separator membranes or both, etc.) for various improved cell, battery module, and overall battery pack performance characteristics.

While the description below may describe certain embodiments in the context of depositing of a surface coating of uniform composition, it will be appreciated that gradient in composition or morphology within the surface coating may be introduced.

While the description below may describe certain embodiments in the context of improved battery cells, it will be appreciated that improved battery modules or packs may be enabled with different aspects of the disclosed technologies. Such modules or packs, for example, may be smaller, lighter, safer, simpler, less expensive, provide more energy, provide higher power, provide longer cycle life, provide longer calendar life, provide better operation at low temperatures, provide better operation at high temperatures and/or other important features. It will similarly be appreciated that improved electronic devices, improved electric scooters, electric bicycles, electric cars, electric trucks, electric buses, electric ships, electric planes and, more broadly, improved electric and hybrid electric ground, sea, and aerial (flying) vehicles (including heavy vehicles, autonomous vehicles, unmanned vehicles, planes, space vehicles, satellites, submarines, etc.), improved robots, improved stationary home or stationary utility energy storage units and improved other end products may be enabled with different aspects of the disclosed technologies. Such devices may be smaller, lighter, offer longer range, faster charging, faster acceleration, better operation at different temperatures, lower cost, longer calendar life, slower degradation with repeated charging and discharging, better safety, etc.

Various embodiments described below refer to electrode pores, electrode particle pores, or both. As used herein, electrode pores comprise pores (open or closed) in the electrode separate from internal pores of the electrode particles, if any. So, increasing an internal porosity of the electrode particles would not function to increase the pore space of the electrode itself. An increase to surface pore size of the electrode particles by contrast would increase the electrode pore space somewhat (assuming the electrode is otherwise kept identical). In some designs, anode particles may comprise internal pores while cathode particles do not comprise internal pores. In other designs, both anode particles and cathode particles may comprise internal pores.

Various embodiments described below may be either advantageously combined or used on their own for the improved performance of battery components, battery cells, battery modules and packs and battery-powered devices, in various designs.

Any numerical range described herein with respect to any embodiment of the present invention is intended not only to define the upper and lower bounds of the associated numerical range, but also as an implicit disclosure of each discrete value within that range in units or increments that are consistent with the level of precision by which the upper and lower bounds are characterized. For example, a numerical distance range from 50 μm to 1200 μm (i.e., a level of precision in units or increments of ones) encompasses (in μm) a set of [50, 51, 52, 43, . . . , 1199, 1200], as if the intervening numbers 51 through 1199 in units or increments of ones were expressly disclosed. In another example, a numerical percentage range from 0.01% to 10.00% (i.e., a level of precision in units or increments of hundredths) encompasses (in %) a set of [0.01, 0.02, 0.03, . . . , 9.99, 10.00], as if the intervening numbers between 0.02 and 9.99 in units or increments of hundredths were expressly disclosed. In another example, if the upper and lower bounds of a numerical range are associated with different levels of precision (e.g., lower bound=50.131 and upper bound=60.99), the respective numerical range is intended to be interpreted so as to encompass sub-ranges in units or increments that are consistent with the higher level of precision by which the upper and lower bounds are characterized (e.g., in this case, the 50.131 lower bound is the higher level of precision, i.e., thousands, rather than hundredths, so as to function as an implicit disclosure of a set of [50.131, 50.132, . . . , 60.989, 60.990]). Hence, any of the intervening numbers encompassed by any disclosed numerical range are intended to be interpreted as if those intervening numbers had been disclosed expressly, and any such intervening number may thereby constitute its own upper and/or lower bound of a sub-range that falls inside of the broader range. Each sub-range (e.g., each range that includes at least one intervening number from the broader range as an upper and/or lower bound) is thereby intended to be interpreted as being implicitly disclosed by virtue of the express disclosure of the broader range. In yet another example, a numerical range with upper and lower bounds defined at different levels of precision shall be interpreted in increments corresponding to the bound with the higher level of precision. For example, a numerical percentage range from 30.92% to 47.4% (i.e., levels of precision in units or increments of hundredths and tenths, respectively) encompasses (in %) a set of [30.92, 30.93, 30.94, . . . , 47.39, 47.40], as if 47.4% (tenths) was recited as 47.40% (hundredths) and as if the intervening numbers between 30.92 and 47.40 in units or increments of hundredths were expressly disclosed.

Some examples below characterize numerical values using approximations (e.g., terms such as “about”, “around”, “approximately”, “˜”, etc.). In some designs, such approximations may be accurate either to a degree commensurate with the relevant instrumentation (e.g., caliper or thickness gauge or pressure gauge, etc.) for measuring the associated value, or to a degree to which that value would be rounded at an associated level of precision (e.g., whichever is greater). For example, “about 4” may encompass any value between 3.5 and 4.5, “about 4.0” may encompass any value between 3.95 and 4.05”, “about 4.00” may encompass any value between 3.995 and 4.005, and so on.

As used herein, reference to some material or device (e.g., a battery) or part of the device (e.g., electrolyte or separator or anode or cathode or current collector or packaging, etc.) “comprise” some elements (or compositions or components, etc.) these referenced elements (or compositions or components, etc.) are present in some meaningful amounts (e.g., in the range from around 0.001 vol. % to around 100 vol. %), while other elements or compositions or components may also be part of the same material (or device or parts of the device, etc.).

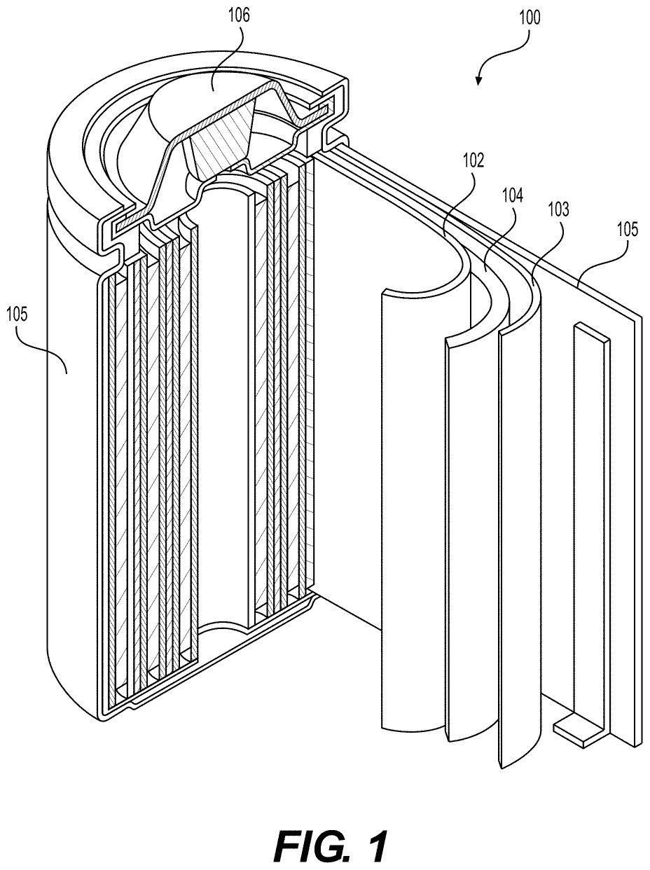

FIG. 1 illustrates an example metal-ion (e.g., Li-ion or Na-ion) battery in which the components, materials, methods, and other techniques described herein, or combinations thereof, may be applied according to various embodiments. A cylindrical battery is shown here for illustration purposes, but other types of arrangements, including prismatic or pouch (laminate-type) or coin-type batteries, may also be used as desired. The example battery 100 includes a negative anode 102, a positive cathode 103, a separator 104 interposed between the anode 102 and the cathode 103, an electrolyte (not shown) impregnating the separator 104, a battery case 105, and a sealing member 106 sealing the battery case 105.

Conventional electrodes utilized in Li-ion or Na-ion batteries may be produced by (i) formation of a slurry comprising active materials, conductive additives, binder solutions and, in some cases, surfactant or other functional additives; (ii) casting the slurry onto a metal foil (e.g., Cu foil for most Li-ion battery anodes and Al foil for most Li-ion battery cathodes and for most Na-ion battery anodes and cathodes); (iii) drying the casted electrodes to completely evaporate the solvent; and (iv) calendaring (densification) of the dried electrodes (e.g., by uniform pressure rolling). Both aqueous (water-based) and organic solvent-based slurry formulations may be utilized for electrode preparation. Furthermore, solvent-free (so-called “dry”) electrode preparation may also be successfully used. In some designs (e.g., particularly when one of the dry electrode preparation method(s) is used), the electrodes may be prepared “standalone” (not casted onto the current collectors). Other electrode fabrication methods may also be utilized in the designs herein.

Batteries may be produced by (i) assembling/stacking (or rolling/winding into so-called jelly roll) the anode/separator/cathode/separator sandwich; (ii) inserting the stack (or jelly roll) into the battery housing (casing); (iii) filling electrolyte into the pores of the electrodes and the separator (and also into the remaining areas of the casing)—often under vacuum; (iv) pre-sealing the battery cell (often under vacuum); (v) conducting so-called “formation” cycle(s) where the battery is slowly charged and discharged (e.g., one or more times); (vi) removing formed gases, sealing the cell, testing the cell for quality and shipping quality cells to customers. However, other battery fabrication stages may also be utilized in the designs herein.

Both liquid and solid electrolytes may be used for the designs herein. Exemplary liquid electrolytes for Li- or Na-based batteries of this type may comprise a single Li or Na salt (such as LiPF₆ for Li-ion batteries and NaPF₆ or NaClO₄ salts for Na-ion batteries) in a mixture of organic solvents (such as a mixture of carbonates, esters (e.g., linear esters and/or branched esters) and/or other suitable solvents) or a mixture of two or more Li or Na salts (such as a mixture of two, three or more of the following Li salts: LiPF₆, LiBF₄, LiClO₄, LiNO₃, Li₃PO₄, lithium bis(oxalato)borate (LiBOB), lithium oxalyldifluoroborate (LiODFB), LiB(CF₃)₄, LiBF(CF₃)₃, LiBF₂(CF₃)₂, LiBF₃(CF₃), LiB(C₂F₅)₄, LiBF(C₂F₅)₃, LiBF₂(C₂F₅)₂, LiBF₃(C₂F₅), LiB(CF₃SO₂)₄, LiBF(CF₃SO₂)₃, LiBF₂(CF₃SO₂)₂, LiBF₃(CF₃SO₂), LiB(C₂F₅SO₂)₄, LiBF(C₂F₅SO₂)₃, LiBF₂, LiAsF₆, LiSbF₆, LiTaF₆, LiNbF₆, LiAlCl₄, lithium bis(trifluoromethanesulfonyl)imide (LiTFSI), LiFTFSI, LiFSI, lithium trifluoromethane sulfolate (LiOTF), other lithium imide salts, etc., for Li-ion batteries, etc.) in a mixture of organic solvents (such as a mixture of carbonates, esters (e.g., linear esters and/or branched esters) and/or other suitable solvents). Other suitable organic solvents include nitriles, sulfones, sulfoxides, phosphorous-based solvents, silicon-based solvents, ethers, and others. In some designs, at least some of such solvents may be modified (e.g., be sulfonated or fluorinated to various degrees). In some designs (e.g., to attain reduced viscosity or improved low temperature performance), about 20-95 wt. % of all the organic solvents in the electrolyte may exhibit melting point below about minus (−) 60° C. (in some designs, below about minus (−) 75° C.). In some designs, at least some of such solvents may be branched. In some designs (particularly if reduced gas generation on the electrodes and improved safety are strongly desired), at least some of such branched solvents may be branched esters. In some designs, branched esters may comprise about 10-95 wt. % of all the solvents in the liquid electrolyte (e.g., in some designs, about 10-20 wt. %; in other designs, about 20-50 vol. %; in other designs, about 50-70 vol. %; in yet other designs, about 70-95 vol. %). In some designs, esters and/or branched esters used in liquid electrolytes may comprise no more than 10 carbon atoms in their molecular structure. In some designs, the electrolytes may also comprise ionic liquids (in some designs, neutral ionic liquids; in other designs, acidic and basic ionic liquids). In some designs, the electrolytes may also comprise mixtures of various salts (e.g., mixtures of several Li salts or mixtures of Li and non-Li salts for rechargeable Li and Li-ion batteries). In some designs, the most common salt concentration in the Li and Li-ion cells is in the range from around 0.8M to around 1.2M. However, salt concentrations below around 0.8M and above around 1.2M may also be used in the designs herein. In some designs, the total salt concentration in the electrolytes may range from around 0.1 M to around 5 M.

In the case of aqueous Li-ion (or aqueous Na-ion, K-ion, Ca-ion, etc.) batteries, electrolytes may include a solution (e.g., aqueous solution or mixed aqueous-organic solution) of inorganic Li (or Na, K, Ca, etc.) salt(s) (such as Li₂SO₄, LiNO₃, LiCl, LiBr, Li₃PO₄, H₂LiO₄P, C₂F₃LiO₂, C₂F₃LiO₃S, Na₂O₃Se, Na₂SO₄, Na₂O₇Si₃, Na₃O₉P₃, C₂F₃NaO₂, etc.). These electrolytes may also comprise solutions of organic Li (or Na, K, Ca, etc.) salts, such as (listed with respect to Li for brevity) metal salts of carboxylic acids (such as HCOOLi, CH₃COOLi, CH₃CH₂COOLi, CH₃(CH₂)₂COOLi, CH₃(CH₂)₃COOLi, CH₃(CH₂)₄COOLi, CH₃(CH₂)₅COOLi, CH₃(CH₂)₆COOLi, CH₃(CH₂)₇COOLi, CH₃(CH₂)₈COOLi, CH₃(CH₂)₉COOLi, CH₃(CH₂)₁₀COOLi, CH₃(CH₂)₁₁COOLi, CH₃(CH₂)₁₂COOLi, CH₃(CH₂)₁₃COOLi, CH₃(CH₂)₁₄COOLi, CH₃(CH₂)₁₅COOLi, CH₃(CH₂)₁₆COOLi, CH₃(CH₂)₁₇COOLi, CH₃(CH₂)₁₈COOLi and others with the formula CH₃(CH₂)ₓCOOLi, where x ranges up to about 50); metal salts of sulfonic acids (e.g., RS(═O)₂—OH, where R is a metal salt of an organic radical, such as a CH₃SO₃Li, CH₃CH₂SO₃Li, C₆H₅SO₃Li, CH₃C₆H₄SO₃Li, CF₃SO₃Li, [CH₂CH(C₆H₄)SO₃Li]ₙ and others) and various other organometallic reagents (such as various organolithium reagents), to name a few. In some designs, such solutions may also comprise mixtures of inorganic and organic salts, various other salt mixtures (for example, a mixture of a Li salt and a salt of non-Li metals and semimetals), and, in some cases, hydroxide(s) (such as LiOH, NaOH, KOH, Ca(OH)₂, etc.), and, in some cases, acids (including organic acids). In some designs, such aqueous electrolytes may also comprise neutral or acidic or basic ionic liquids (from approximately 0.00001 wt. % to approximately 40 wt. % relative to the total weight of electrolyte). In some designs, such “aqueous” (or water containing) electrolytes may also comprise organic solvents (from approximately 0.00001 wt. % to approximately 40 wt. % relative to the total weight of electrolyte), in addition to water. Illustrative examples of suitable organic solvents may include carbonates (e.g., propylene carbonate, ethylene carbonate, diethyl carbonate, dimethyl carbonate, ethyl methyl carbonate, fluoroethylene carbonate, vinylene carbonate, and others), various nitriles (e.g., acetonitrile, etc.), various esters, various sulfones (e.g., propane sulfone, etc.), various sultones, various sulfoxides, various phosphorous-based solvents, various silicon-based solvents, various ethers, and others.

The most common salt used in a Li-ion battery electrolyte, for example, is LiPF₆, while less common salts include lithium tetrafluoroborate (LiBF₄), lithium perchlorate (LiClO₄), lithium bis(oxalato)borate (LiB(C₂O₄)₂), lithium difluoro(oxalate)borate (LiBF₂(C₂O₄)), various lithium imides (such as SO₂FN⁻(Li⁺)SO₂F, CF₃SO₂N⁻(Li⁺)SO₂CF₃, CF₃CF₂SO₂N⁻(Li⁺)SO₂CF₃, CF₃CF₂SO₂N⁻(Li⁺)SO₂CF₂CF₃, CF₃SO₂N⁻(Li⁺)SO₂CF₂OCF₃, CF₃OCF₂SO₂N (Li⁺)SO₂CF₂OCF₃, C₆F₅SO₂N⁻(Li⁺)SO₂CF₃, C₆F₅SO₂N⁻(Li⁺)SO₂C₆F₅ or CF₃SO₂N⁻(Li⁺)SO₂PhCF₃, and others), and others. Electrolytes for Mg-ion, K-ion, Ca-ion, and Al-ion batteries are often more exotic as these batteries are in earlier stages of development. In some designs, such electrolytes may comprise different salts and solvents (in some cases, ionic liquids may replace organic solvents for certain applications).

In some designs, some electrolytes in aqueous batteries (such as alkaline batteries, including nickel-metal hydride batteries) may comprise an alkaline solution (for example, a mixture of KOH and LiOH solutions). In some designs, electrolytes in aqueous batteries (such as lead acid batteries) may comprise an acidic aqueous solution (for example, H₂SO₄ aqueous solution). In some designs, electrolytes in aqueous batteries may comprise an organic solvent as an additive. In some designs, electrolytes in aqueous batteries may comprise two or more organic solvent(s) or ionic liquid(s) as additive(s) or substantial components of the electrolyte.

In some designs, electrolytes for Li, Li-ion, Na, Na-ion and other types of batteries and other electrochemical energy storage devices may be solid or semi-solid. In some designs, solid or semi-solid electrolytes may be based on polymers (e.g., dry solid polymer electrolytes, polymer-in-salt electrolyte systems, single-ion conducting polymer electrolytes, polymer-ceramic composite electrolytes, gel polymer electrolytes where, and inorganic or organic Li (or Na) salt and organic solvent(s) or ionic liquids (ILs) or oligomers (or, more generally, small organic molecules with molecular weight of MW<400 g/mol) may be mixed with (or dissolved within) a polymer (or, more generally, large organic molecules with molecular weight of MW>400 g/mol) to act as plasticizer(s) or conductivity promoter(s), etc.), solid polymer electrolytes) or inorganic materials (e.g., in organic solid electrolytes) or their mixtures (organic-inorganic hybrid or mixed electrolytes, where for example, inorganic nanoparticles or nanofibers are interspersed within a polymer matrix, where additional plasticizers or solvents may be added or in other configurations). In some designs, polymer electrolytes may comprise ILs or polymerized ILs. In some designs, inorganic solid electrolytes for Li or Li-ion batteries may comprise one or more lithium metal halides (or sodium metal halides in case of Na or Na-ion batteries). In some designs of lithium metal halide solid electrolytes, either Cl or Br or both may be present within the one or more lithium metal halides, and the one or more lithium metal halides may comprise one, two, three, four or more of Na, K, Mg, Ca, Sc, Al, Zn, Ga, Sr, Y, Zr, Nb, Mo, Cd, In, B, Sn, Sb, Si, Ge, Cs, Ba, La, Ce, other lanthanoids(s), Hf, Ta and Bi. In some designs, inorganic solid electrolytes for Li or Li-ion batteries may comprise one or more lithium metal hydrides (or sodium metal hydrides in case of Na or Na-ion batteries). In some designs of lithium metal hydrides in addition to Li and H, the one or more lithium metal hydrides comprise one, two or more of B, Al, Ga, Zn, Zr, Ca, Mg, Na, K, Y, Sc, Ce, La, Ga, Sm, and the one or more solid electrolytes may additionally comprise one or more of N, O, Cl, F, Br, I. In some designs, solid electrolytes may comprise one, two, three, four or more of the following hydrides in their compositions: LiBH₄, LiNH₂, LiAlH₄, LiGaH₄, LiYH₄, LiScH₄, LiCeH₄, LiLaH₄, LiYH₃, LiLaH₃, LiBaH₃, LiCaH₃, LiMgH₃, KBH₄, KNH₂, KAlH₄, KGaH₄, KYH₄, KScH₄, KCeH₄, KLaH₄, KYH₃, KLaH₃, KBaH₃, KCaH₃, KMgH₃, NaBH₄, NaNH₂, NaAlH₄, NaGaH₄, NaYH₄, NaYH₃, NaScH₄, NaCeH₄, NaLaH₄, NaYH₃, NaLaH₃, NaBaH₃, NaCaH₃, NaMgH₃, Ca(BH₄)₂, Ca(NH₂)₂, Ca(AlH₄)₂, Ca(GaH₄)₂, Ca(YH₄)₂, Ca(YH₃)₂, Ca(ScH₄)₂, Ca(CeH₄)₂, Ca(LaH₄)₂, Ca(LaH₃)₂, Ca(BaH₃)₂, Ca(MgH₃)₂, Mg(BH₄)₂, Mg(NH₂)₂, Mg(AlH₄)₂, Mg(GaH₄)₂, Mg(LaH₃)₂, Mg(BaH₃)₂, Mg(CaH₃)₂, Mg(YH₄)₂, Mg(YH₃)₂, Mg(ScH₄)₂, Mg(CeH₄)₂, Mg(LaH₄)₂. In some designs, hydride solid electrolytes may comprise closo-borate-based salts of Li and their mixtures. Suitable examples of closo-borate-based Li salts may include, but are not limited to: Li₂B₁₀H₁₀, Li₂B₁₂H₁₂, LiCB₁₁H₁₂, and LiCB₉H₁₀. In some designs, hydride solid electrolytes with Li closo-borate-based salts may comprise the following compositions: Li₂B₁₀H₁₀, Li₂B₁₂H₁₂, (Li₂B₁₀H₁₀)×(Li₂B₁₂H₁₂)₁₋ₓ, (LiCB₉H₁₀)ₓ(LiCB₁₁H₁₂)₁₋ₓ, (Li₂B₁₂H₁₂)ₓ(LiCB₉H₁₀)₁₋ₓ, (Li₂B₁₀H₁₀)×(Li₂CB₉H₁₀)₁₋ₓ, (Li₂B₁₂H₁₂)×(LiCB₁₁H₁₂)₁₋ₓ, (Li₂B₉H₉)×(Li₂CB₁₁H₁₂)₁₋ₓ, where 0<x<1. In some designs, solid electrolytes may comprise one or more of the following types of the solid electrolytes: various sulfide-based electrolytes (such as Li₂S—P₂S₅, Li₂S—Ga₂S₃—GeS₂, Li₂S—SiS₂, etc.), various phosphate-based electrolytes (such as Li₁₊ₓAlₓTi₂₋ₓ(PO₄)₃, etc.), various halide-based electrolytes, various oxide-based electrolytes (such as Li—La—Ti—O garnet, Li—La—Zr—O garnet, Li—La—Ta—O garnet, such and other garnet electrolytes and their various mixtures, some of which may be aliovalently doped (e.g., with Al, Ta, Nb, and other elements); Li₄SiO₄, Li—Si—O glass, Li—Ge—O glass, Li_{9.5}SiAlO₈, Li_{3.2}P_{0.8}Si_{0.2}O₄, Li_{3.53}(Ge_{0.75}P_{0.25})_{0.75}V_{0.3}O₄, etc.), mixed sulfide-oxide, sulfide-halide and sulfide-oxide-halide electrolytes (such as Li₆PS₅Cl, Li_{9.5}Si_{1.74}P_{1.44}S_{11.7}Cl_{0.3}, Li_{6.6}P_{0.4}Ge_{0.6}S₅I, Li₂S—SiS₂—Li₄SiO₄, Li₂S—SiS₂—Li₄SiO₄—LiCl, LiI—La₂O₂S—La₂O₂S₂, etc.), oxy-chloride and oxy-hydro-chloride electrolytes (such as Li₃OCl electrolyte, Li₂OHCl electrolyte, Li₃(OH)₂Cl electrolyte, etc.) and others.

In some designs, solid electrolytes in accordance with embodiments of the present disclosure may exhibit small or moderate grain size at battery operational temperatures (e.g., average grain size may be below around 500 nm). Such operational temperatures depend on a particular application, but commonly are from around minus (−) 40° C. to around +100° C. (although higher or lower operational temperatures may be required in some applications). In some designs, solid electrolytes in accordance with embodiments of the present disclosure may exhibit relatively high conductivity at 25 and 60° C. (e.g., above around 10⁻⁴ at 60° C. and/or above around 10⁻⁵ S/cm at 25° C.).

In some designs, solid electrolytes, or solid electrolyte precursors in accordance with embodiments of the present disclosure may be infiltrated into one or more electrodes or into anode/separator/cathode stacks or rolls after the electrode or stack assembling. In some designs, such an infiltration may take place when a solid electrolyte (e.g., “solid” at cell operational temperature or at room temperature) or a solid electrolyte precursor is in a liquid or semi-liquid state (e.g., melt-infiltration). In some designs, solid electrolyte could be fully formed after the electrode or stack heating. In some designs, solid electrolyte could be fully formed after the so-called “formation” cycle(s).

Deposition of an interfacial, ionically conducting layer between the electrolyte and the electrode may offer significant advantages for different types of electrolytes. For example, in case of aqueous batteries or other types of energy storage devices, deposition of a conformal ionically conductive (e.g., stable in water) layer onto the electrodes surface may reduce hydrogen evolution on the anode (e.g., when deposited on the anode) and oxygen evolution on the cathode (e.g., when deposited on the cathode), particularly at elevated temperatures. Such a layer may also enhance electrolyte wetting on the electrode surface. In case of batteries or other types of energy storage devices based on organic electrolytes, such a layer may, for example, reduce or even eliminate gassing during storage at elevated temperatures in a charged state, improve electrolyte wetting, improve high temperature performance, improve calendar life, improve cycle life, enable higher accessible capacity with still acceptable cycle stability and other performance characteristics, enable higher charging voltage with still acceptable cycle stability and other performance characteristics, enable higher reversible energy density with acceptable cycle stability and other performance characteristics among other performance improvements. In case of batteries or other types of energy storage devices based on solid electrolytes, such a layer may, for example, improve batteries cycle stability, improve calendar life, reduce undesirable side reactions, increase maximum operating temperature, increase maximum potential on the cathode, reduce minimum potential on the anode, increase maximum cell charging voltage, increase accessible energy density and reduce resistance of the interface (or interphase) between the solid electrolyte and electrode material. In some designs, it may be advantageous for the deposited interfacial layer to be present for over about 50% of the contact surface area between the electrolyte and electrode. In other designs, it may be advantageous for the deposited interfacial layer to coat over about 60% of the area (in some designs—over about 70%, in some designs—over about 80%, in some designs—over about 90%, in some designs—over about 95%, in some designs—over about 98%, in some designs—over about 99%, in some designs—over about 99.5%, in some designs—over about 99.9%). In many cases, however, the deposition of suitable interfacial layer (e.g., on the electrode surface or on the surface of solid electrolytes) with high level uniformity is commonly challenging, time consuming and expensive. As a result, an interfacial, ionically conducting layer between the electrolyte and the electrode is not currently used in commercial cell production. Some embodiments of the present disclosure describe routes to mitigate or overcome such a limitation.

Certain conventional cathode materials utilized in Li-ion batteries are of an intercalation-type. Such cathode materials may be used in accordance with embodiments of the present disclosure. In such cathodes, metal ions are intercalated into and occupy the interstitial positions of such materials during the charge or discharge of a battery. No breakage in chemical bonds typically takes place during insertion and extraction of Li. Such cathodes typically experience very small volume changes when used in electrodes. Such cathode materials also may exhibit high density (e.g., about 3.8-6 g/cm³ at the individual particle basis). Illustrative examples of such intercalation-type cathode materials include but are not limited to lithium cobalt oxide (LCO), lithium nickel cobalt aluminum oxide (NCA), lithium nickel manganese cobalt oxide (NMC or NCM), lithium nickel manganese cobalt aluminum oxide (NMCA), lithium manganese oxide (LMO), lithium nickel oxide (LNO), high voltage spinel, such as lithium manganese nickel oxide (LiMn_{1.5}Ni_{0.5}O₄ or LMNO), various lithium metals (e.g., iron or cobalt or nickel or manganese or mixture of these and other metals) phosphate (LMP such as lithium iron phosphate (LFP), lithium iron manganese phosphate (LFMP), lithium manganese phosphate (LMP), lithium cobalt phosphate (LCP), lithium nickel phosphate (LNP), their various alloys and mixtures, other phosphates, etc.), various lithium metal silicates (Li₂MSiO₄, where M could be Ni, Co, Mn, Fe, various mixture of these and other metals, etc.), various other intercalation cathode materials including those that comprise surface coatings or exhibit gradient composition within individual particles, among others.

In some designs, intercalation-type cathode materials in accordance with embodiments of the present disclosure may comprise from around 75.0 at. % to around 100.0 at. % Nickel (Ni) as a fraction of all non-Li metals in the cathode composition. In some designs, cathode materials in accordance with embodiments of the present disclosure may comprise from around 75.0 at. % to around 100.0 at. % Cobalt (Co) as a fraction of all non-Li metals in the cathode composition. In some designs, cathode materials in accordance with embodiments of the present disclosure may comprise from around 50.0 at. % to around 100.0 at. % (e.g., in some designs, from around 75.0 at. % to around 100.0 at. %) Iron (Fe) as a fraction of all non-Li metals in the cathode composition. In some designs, cathode materials in accordance with embodiments of the present disclosure may comprise from around 50.0 at. % to around 100.0 at. % Manganese (Mn) as a fraction of all non-Li metals in the cathode composition.

Deposition of an interfacial, ionically conducting layer between the electrolyte and the intercalation-type cathode may offer significant advantages. For example, an interfacial, ionically conducting layer between the electrolyte and the intercalation-type cathode may reduce or even eliminate gassing during storage at elevated temperatures in a charged state (particularly at higher potentials), improve electrolyte wetting, improve high temperature performance (particularly at higher potentials), improve calendar life, improve cycle life, enable higher accessible capacity (higher theoretical capacity utilization) with still acceptable cycle stability and other performance characteristics, enable higher charging voltage with still acceptable cycle stability and other performance characteristics, enable higher reversible energy density with acceptable cycle stability and other performance characteristics, reduce (or even eliminate) metal dissolution during cycling (particularly at elevated temperatures), enable the use of a broader range of electrolyte compositions (e.g., in some designs, including those that offer higher conductivity or reduced cost or enhanced safety, but commonly suffer from other poor performance characteristics when used with uncoated electrodes), enable the use of a broader range of binder compositions, among other performance improvements. In some designs, it may be advantageous for the deposited surface layer to coat over about 50% of the cathode surface (e.g., over about 50% of the surface accessible by nitrogen gas during gas sorption measurements or over about 50% of the surface accessible by a low surface tension liquid (e.g., methanol) during emersion tests). In other designs, it may be advantageous for the deposited surface layer to coat over about 60% of the cathode surface (in some designs—over about 70%, in some designs—over about 80%, in some designs—over about 90%, in some designs—over about 95%, in some designs—over about 98%, in some designs—over about 99%, in some designs—over about 99.5%, in some designs—over about 99.9%).

Apart from intercalation-type cathode materials, conversion-type cathode materials are gaining popularity for use in Li-ion and Li (or Na-ion and Na) batteries. Such conversion-type cathode materials undergo changes in chemical bonds during Li (or Na) insertion and extraction. Conversion-type cathode materials are often sub-divided into “true” conversion materials and chemical transformation materials. Displacement reactions are often considered as a sub-class of a “true” conversion reaction (when one phase is being significantly displaced/extruded during the transformation). Conversion-type cathode materials for rechargeable Li-ion or Li batteries may offer higher energy density, higher specific energy, or higher specific or volumetric capacities compared to intercalation-type cathode materials. For example, fluoride-based cathodes may offer outstanding technological potential due to their very high capacities, in some cases exceeding about 300 mAh/g (e.g., greater than about 1200 mAh/cm³ at the electrode level). For example, in a Li-free state, FeF₃ offers a theoretical specific capacity of 712 mAh/g; FeF₂ offers a theoretical specific capacity of 571 mAh/g; MnF₃ offers a theoretical specific capacity of 719 mAh/g; CuF₂ offers a theoretical specific capacity of 528 mAh/g; NiF₂ offers a theoretical specific capacity of 554 mAh/g; PbF₂ offers a theoretical specific capacity of 219 mAh/g; BiF₃ offers a theoretical specific capacity of 302 mAh/g; BiF₅ offers a theoretical specific capacity of 441 mAh/g; SnF₂ offers a theoretical specific capacity of 342 mAh/g; SnF₄ offers a theoretical specific capacity of 551 mAh/g; SbF₃ offers a theoretical specific capacity of 450 mAh/g; SbF₅ offers a theoretical specific capacity of 618 mAh/g; CdF₂ offers a theoretical specific capacity of 356 mAh/g; and ZnF₂ offers a theoretical specific capacity of 519 mAh/g. Mixtures (for example, in the form of alloys) of fluorides may offer a theoretical capacity approximately calculated according to the rule of mixtures. In some designs, the use of mixed metal fluorides may sometimes be advantageous (e.g., may offer higher rates, lower resistance, higher practical capacity, or longer stability). In some designs, some of the metal fluorides or oxyfluorides (e.g., fluorides or oxyfluorides of Ba, Sb, Y, La, Ce, Sm, Gd, Sr, Cs, Bi, Ga, In, Zr, Al, Zn, Nb, Mo, etc.) or metals (e.g., Ba, Sb, Y, La, Ce, Sm, Gd, Sr, Cs, Bi, Ga, In, Zr, Al, Zn, Nb, Mo, etc.) may be added to the fluoride mix in order to enhance conductivity, stability or rate performance. In a fully lithiated state, metal fluorides convert to a composite comprising a mixture of metal and LiF clusters (or nanoparticles). Examples of the overall reversible reactions of the conversion-type metal fluoride cathodes may include 2Li+CuF₂⇄2LiF+Cu for CuF₂-based cathodes or 3Li+FeF₃⇄3LiF+Fe for FeF₃-based cathodes or 2Li+NiF₂⇄2LiF+Ni for NiF₂-based cathodes, etc.). It will be appreciated that metal fluoride-based cathodes may be prepared in both Li-free or partially lithiated or fully lithiated states.

Another example of a promising conversion-type Li-ion battery cathode (or, in some cases, anode) material is sulfur (S) (in a Li-free state) or lithium sulfide (Li₂S, in a fully lithiated state). In order to reduce dissolution of active material during cycling, to improve electrical conductivity, or to improve mechanical stability of S/Li₂S electrodes in some designs, one may advantageously utilize porous S, Li₂S, porous S—C (nano)composites, Li₂S—C (nano)composites, Li₂S-metal oxide (nano)composites, Li₂S—C-metal oxide (nano)composites, Li₂S—C-metal sulfide (nano)composites, Li₂S-metal sulfide (nano)composites, Li₂S—C-mixed metal oxide (nano)composites, Li₂S—C-mixed metal sulfide (nano)composites, porous S-polymer (nano)composites, or other composites or (nano)composites comprising S or Li₂S, or both. In some designs, such (nano)composites may advantageously comprise conductive carbon. In some designs, such (nano)composites may advantageously comprise metal oxides or mixed metal oxides. In some designs, such (nano)composites may advantageously comprise metal sulfides or mixed metal sulfides. In some examples, mixed metal oxides or mixed metal sulfides may comprise lithium metal. In some examples, mixed metal oxides may comprise titanium metal. In some examples, lithium-comprising metal oxides or metal sulfides may exhibit a layered structure. In some examples, metal oxides or mixed metal oxides or metal sulfides or mixed metal sulfides may advantageously be both ionically and electrically conductive. In some examples, various other intercalation-type active materials may be utilized instead of or in addition to metal oxides or metal sulfides. In some designs, such an intercalation-type active material exhibits charge storage (e.g., Li insertion/extraction capacity) in the potential range close to that of S or Li₂S (e.g., within about 1.5-3.8 V vs. Li/Li⁺).

Unfortunately, many conversion-type electrodes used in Li-ion batteries suffer from performance limitations. Formation of (nano)composites may, at least partially, overcome such limitations. For example, (nano)composites in some designs may offer reduced voltage hysteresis, improved capacity utilization, improved rate performance, improved mechanical and sometimes improved electrochemical stability, reduced volume changes, and/or other positive attributes. Examples of such composite cathode materials include, but are not limited to: LiF—Fe—C nanocomposites, LiF—Fe-another metal-C nanocomposites (e.g., LiF—Cu—Fe—C nanocomposites or various others), LiF—Fe—Fe₂O₃—C nanocomposites, LiF—Fe—FeOₓF_{y}—C nanocomposites, LiF—Feₓ—FeO_{y1}F_{y2}—CF_{z} nanocomposites, LiF—Feₓ—FeO_{y1}F_{y2}—CF_{z}-another metal (or metal fluoride) nanocomposites, LiF—Cu—CuO—C nanocomposites, LiF—Cu—Fe—CuO—C nanocomposites, LiF—Cu—Fe—CuO—Fe₂O₃—C nanocomposites, FeF₂—C nanocomposites, FeF₂—FeO_{y1}F_{y2}—CF_{z} nanocomposites, FeF₃—C nanocomposites, FeF₃—Fe₂O₃—C nanocomposites, FeF₃—Fe₂O₃—C—Fe nanocomposites, FeF₃—Fe₂O₃—C nanocomposites, CuF₂—C nanocomposites, CuO—CuF₂—C nanocomposites, LiF—Cu—C nanocomposites, LiF—Cu—C-polymer nanocomposites, LiF—Cu—CuO—C-polymer nanocomposites, LiF—Cu-metal-polymer nanocomposites, and many other dense or porous nanocomposites comprising LiF, FeF₃, FeF₂, MnF₃, CuF₂, NiF₂, PbF₂, BiF₃, BiF₅, AlF₃, CoF₂, SnF₂, SnF₄, ZrF₄, SbF₃, SbF₅, CdF₂, LaF₃, CeF₃, SmF₃, VF₃, GaF₃ or ZnF₂, or other metal fluorides or their alloys or mixtures and (in some designs) comprising metals (e.g., Fe, Mn, Cu, Ni, Pb, Bi, Al, Co, Sn, Zr, Sc, Sr, Y, Ti, Cr, Sb, Cd, La, Ce, Sm, Nb, Mo, V, Ga, Zn, among others) or oxides or oxyfluorides of such or other metals and their alloys or mixtures. In some examples, metal sulfides or mixed metal sulfides may be used instead of or in addition to metals, metal oxides or metal oxyfluorides in such (nano)composites. In some design examples, metal fluoride nanoparticles may be infiltrated into the pores of porous carbon (for example, into the pores of activated carbon particles) to form these metal-fluoride-C nanocomposites. In some designs, metal fluoride nanoparticles may be infiltrated into other porous media (e.g., oxides, phosphates, sulfides, metals, carbides, conductive polymers, composite porous media, etc.), which may preferably be electrically conductive. In some examples, such composite particles may also comprise metal oxides (including mixed metal oxides or metal oxyfluorides or mixed metal oxyfluorides) or metal sulfides (including mixed metal sulfides) or metal phosphates or metal carbides. In some examples, mixed metal oxides or mixed metal sulfides or mixed metal phosphates may comprise lithium. In some examples, lithium-comprising metal oxides or metal sulfides may exhibit a layered structure. In some examples, metal oxides or mixed metal oxides or metal sulfides or mixed metal sulfides may advantageously be both ionically and electrically conductive. In some examples, various intercalation-type active materials may be utilized instead of or in addition to metal oxides or metal sulfides. In some designs, such an intercalation-type active material may exhibit charge storage (e.g., Li insertion/extraction capacity) in the same potential range as metal fluorides or in the nearby potential range (e.g., within about 1.5-4.2 V vs. Li/Li⁺). In some examples, such metal oxides may encase the metal fluorides and advantageously prevent (or significantly reduce) direct contact of metal fluorides (or oxyfluorides) with liquid electrolytes (e.g., in order to reduce or prevent metal corrosion and dissolution during cycling). In some examples, nanocomposite particles may comprise carbon shells or carbon coatings. In some designs, such a coating may enhance electrical conductivity of the particles and may also prevent (or help to reduce) undesirable direct contact of metal fluorides (or oxyfluorides) with liquid electrolytes. In some designs, such fluoride-comprising (nano)composite particles may be used in nonlithiated, fully lithiated and partially lithiated states.

In some embodiments of the present disclosure, cathodes may comprise both intercalation-type and conversion-type active materials. In some designs, cathodes may comprise cathode particles that, in turn, comprise both intercalation-type and conversion-type active material in their composition. In some designs, cathodes may both exhibit intercalation-type and conversion-type charge storage mechanisms (e.g., with one prevailing in a certain potential range).

Conversion-type cathode materials may exhibit more undesirable interactions with electrolytes and often benefit even more from depositing conformal surface coatings on the electrodes (or individual cathode particles or both). Deposition of an interfacial, ionically conducting layer between the electrolyte and the conversion-type (or mixed intercalation- and conversion-type) cathode may offer multiple significant advantages. For example, an interfacial, ionically conducting layer between the electrolyte and the conversion-type (or mixed intercalation- and conversion-type) cathode may reduce or even eliminate gassing during storage at elevated temperatures in a charged state (particularly at higher potentials), improve electrolyte wetting, improve high temperature performance, improve calendar life, improve cycle life, enable higher accessible capacity (higher theoretical capacity utilization) with still acceptable cycle stability and other performance characteristics, enable higher charging voltage with still acceptable cycle stability and other performance characteristics, enable faster charging, enable higher reversible energy density with acceptable cycle stability and other performance characteristics, reduce (or even eliminate) metal dissolution during cycling (particularly at elevated temperatures), enable the use of a broader range of electrolyte compositions (e.g., in some designs, including those that offer higher conductivity or reduced cost or enhanced safety, but commonly suffer from other poor performance characteristics when used with uncoated electrodes), enable the use of a broader range of binder compositions, among other performance improvements. In some designs, it may be advantageous for the deposited surface layer to coat over about 50% of the cathode surface (e.g., over about 50% of the surface accessible by nitrogen gas during gas sorption measurements or over about 50% of the surface accessible by a low surface tension liquid (e.g., methanol) during emersion tests). In other designs, it may be advantageous for the deposited surface layer to coat over about 60% of the cathode surface (in some designs—over about 70%, in some designs—over about 80%, in some designs—over about 90%, in some designs—over about 95%, in some designs—over about 98%, in some designs—over about 99%, in some designs—over about 99.5%, in some designs—over about 99.9%).

Polyvinylidene fluoride, or polyvinylidene difluoride (PVDF), is the most common binder used in various types of cathodes. Other cathode binders include, but are not limited to: various polyacrylates (e.g., polyacrylic acid (PAA) and their various salts, polymethyl acrylate (PMA), polybutyl acrylate (PBA), polyvinyl acrylate (PVA), polyacrylonitrile (PAN), etc.), various aliphatic and aromatic synthetic polymers (e.g., polyethylene (PE), polyisoprene, polyvinyl butyral (PVB), polystyrene (PS), polyurethane (PU), etc.), various proteins (e.g., gelatine, caseinate, etc.), various oligo and polysaccharides (e.g., cellulose and their various salts, alginic acids and their various salts, starch, chitosan, pectine, amylose, gums, etc., some of which may be modified by fluorination or other means), various fluorinated acrylate polymer latexes, poly(tetrafluoroethylene) (PTFE), modified (incl. partially fluorinated) styrene butadiene rubber copolymers (SBR), and many others. Carbon black and carbon nanotubes are the most common conductive additive used, although other conductive additives may also be successfully utilized in some embodiments of the present disclosure. Conventional anode materials utilized in Li-ion batteries are also of an intercalation-type. The most common anode material in conventional intercalation-type Li-ion batteries is synthetic or natural graphite or soft carbon or hard carbon or graphite-comprising composites, mixture of carbons (including graphites), lithium titanium oxides (LTO), lithium vanadium oxides (LVO) and others.

PVDF, carboxymethyl cellulose (CMC), alginic acid and their various salts (e.g., often Na or Li, etc.), polyacrylic acid (PAA) and their various salts (e.g., often Na or Li, etc.), other polyacrylates olymethyl acrylate (PMA), polybutyl acrylate (PBA), polyvinyl acrylate (PVA), polyacrylonitrile (PAN), etc.), various aliphatic and aromatic synthetic polymers (e.g., polyethylene (PE), polyisoprene, polyvinyl butyral (PVB), polystyrene (PS), polyurethane (PU), etc.) and their various salts, various proteins (e.g., gelatine, caseinate, etc.), various oligo and polysaccharides (e.g., cellulose and their various salts, alginic acids and their various salts, starch, chitosan, pectine, amylose, gums, etc., some of which may be modified by fluorination or other means), various fluorinated acrylate polymer latexes, poly(tetrafluoroethylene) (PTFE), modified (incl. partially fluorinated) styrene butadiene rubber copolymers (SBR) are some of the useful binders that may be used in various anodes, although other binders may also be successfully utilized in various designs and embodiments of the present disclosure. Carbon black and carbon nanotubes are some of the most common conductive additive used in the anodes, although other conductive additives (e.g., metal nanoparticles or nanowires or carbon fibers or carbon-metal composite fibers, etc.) may also be used in some embodiments of the present disclosure.

Apart from intercalation-type anode materials, conversion-type, alloying-type, and metal-type anode materials are gaining popularity for use in Li-ion and Li (or Na-ion and Na) batteries. Such conversion-type and alloying-type anode materials undergo changes in chemical bonds during Li (or Na) insertion and extraction. Displacement reactions are often considered as a sub-class of a conversion or alloying reaction (when one phase is being significantly displaced/extruded during the transformation).

Alloying-type and conversion-type anode materials for use in Li-ion batteries offer higher gravimetric and volumetric capacities compared to intercalation-type anodes. For example, silicon (Si) offers approximately 10 times higher gravimetric capacity and approximately 3 times higher volumetric capacity compared to an intercalation-type graphite (or graphite-like) anode. However, Si suffers from significant volume expansion during Li insertion (up to approximately 300 vol. %) and thus may induce thickness changes and mechanical failure of Si-comprising anodes in some designs. In addition, Si (and some Li—Si alloy compounds that may form during lithiation of Si) suffers from relatively low electrical conductivity and relatively low ionic (Li-ion) conductivity. Electronic and ionic conductivity of Si is lower than that of graphite. In some designs, formation of (nano)composite Si-comprising particles (including, but not limited to Si-carbon composites, Si-metal composites, Si-polymer composites, Si-metal-polymer composites, Si-carbon-polymer composites, Si-metal-carbon-polymer composites, Si-ceramic composites, or other types of porous composites comprising nanostructured Si or nanostructured or nano-sized Si particles of various shapes and forms) and their combinations may reduce volume changes during Li-ion insertion and extraction, which, in turn, may lead to better cycle stability in rechargeable Li-ion cells. In addition to Si-comprising nanocomposite anodes, other examples of such nanocomposite anodes comprising alloying-type active materials include, but are not limited to, those that comprise germanium, antimony, aluminum, magnesium, zinc, gallium, arsenic, phosphorous, silver, cadmium, indium, tin, lead, bismuth, their alloys, and others. In addition to (nano)composite anodes comprising alloying-type active materials, other interesting types of high capacity (nano)composite anodes may comprise metal oxides (including, but not limited to silicon oxide, lithium oxide, various sub-oxides, etc.), metal nitrides (including, but not limited to silicon nitride, various sub-nitrides, etc.), metal oxy-nitrides (including, but not limited to silicon oxy-nitrides), metal phosphides (including, but not limited to lithium phosphide and other metal phosphides and sub-phosphides), metal hydrides, and others as well as their various mixtures, alloys and combinations.

In addition to conversion-type and alloying-type anodes, Li (or Na) metal anodes are considered as high-capacity anodes for rechargeable Li (or Na) batteries. Such anodes may be in a Li (or Na)-free state during the initial cell assembling (so that Li (or Na) plates during the first charge) or in a Li-comprising state (e.g., in the form of Li metal foil) during the initial cell assembling. In some designs, assembling the battery in a Li-free state may be advantageous in terms of the lower cost, higher cell energy density attainable and even better stability, or other performance characteristics.

In some embodiments of the present disclosure, anodes may comprise more than one type of the intercalation-type, alloying-type, conversion-type and metal-type active anode materials. In some designs, anodes may comprise anode particles that, in turn, comprise more than one of the intercalation-type, alloying-type, conversion-type and metal-type active material in their composition.

Deposition of a conformal, ionically conducting interfacial layer between the electrolyte and the anodes may offer significant advantages for different types of anode materials. Such a layer may reduce gassing and improve both cycle stability and calendar life of cells. In case of intercalation-type anodes, such a layer may reduce first cycle losses, reduce or minimize electrolyte reduction on the anode surface, improve stability of the cells, particularly during storage or operations at elevated temperatures. In case of conversion-type or alloying-type anode materials, such a layer may also reduce first cycle losses, improve stability of the solid electrolyte interphase (SEI) layer, improve long-term cycle stability, improve coulombic efficiency of cells and their performance at elevated temperatures, among other benefits. In case of Li metal anodes, such a layer may reduce formation of Li dendrites and improve cycle stability of the cells, among other benefits. In some designs where Li plating or alloying takes place inside the pores of various electrically conductive host materials (e.g., porous host material particles; in some designs—comprising closed pores), the deposition of the surface layer on the outer surface of such particles may not only improve electrolyte wetting, but also reduce, minimize or prevent Li metal deposition on such outer particle surface (e.g., so that Li deposits only inside). In some designs, it may be advantageous for the deposited surface layer to coat over about 50% of the electrode's surface (e.g., over about 50% of the surface accessible by nitrogen gas during gas sorption measurements or over about 50% of the surface accessible by a low surface tension liquid (e.g., methanol) during emersion tests). In other designs, it may be advantageous for the deposited surface layer to coat over about 60% of the electrode's surface (in some designs—over about 70%, in some designs—over about 80%, in some designs—over about 90%, in some designs—over about 95%, in some designs—over about 98%, in some designs—over about 99%, in some designs—over about 99.5%, in some designs—over about 99.9%).

In many cases, the deposition of suitable interfacial layer on the surface of intercalation-type cathodes and anodes, conversion-type cathodes and anodes, alloying-type anodes and Li metal anodes may be challenging, time consuming and expensive. As a result, such a layer is not used in large scale production facilities and in commercial cell production. Some embodiments of the present disclosure describe routes to overcome such a limitation.

In some embodiments of the present disclosure, it may be advantageous for the conversion-type anodes and cathodes as well as alloying-type anodes to comprise electrode materials in the form of composite particles that exhibit small volume changes at the particle level during each battery cycle in spite of the large volume changes in conversion or alloying type active materials. In some designs, this is because the functional surface (or interfacial layer) on the surface of the electrode (e.g., deposited to prevent a direct contact with electrolyte) may otherwise crack or delaminate during such cycling. In some designs, it may be preferable for these (e.g., composite) particles comprising conversion-type or alloying-type active material to exhibit volume changes of less than around 25 vol. %. In some designs, the maximum particle-level volume changes depend on the adhesion of this surface layer to the surface of the electrode and on the mechanical properties of such a layer. In some designs, it may be advantageous for these (e.g., composite) particles to exhibit volume changes of less than around 20 vol. % in each cycle (in other designs—less than 15 vol. %; in other designs—less than 10 vol. %; in other designs—less than 5 vol. %; in other designs—less than 3 vol. %; in yet other designs—less than 1 vol. %). In some designs, it may be advantageous for the intercalation-type anodes and cathodes to comprise electrode materials with a tuned composition to exhibit small volume changes at the particle level during each battery cycle. In some designs, it may be advantageous for these intercalation-type particles to exhibit volume changes of less than around 5 vol. % in each cycle (in other designs—less than around 4 vol. %; in other designs—less than around 3 vol. %; in other designs—less than around 2 vol. %; in other designs—less than around 1 vol. %; in other designs—less than around 0.5 vol. %).

Organic solution-soluble or water-soluble (e.g., polymer) binders are commonly used in electrode construction. In some designs, the amount of binder may be optimized for: a particular electrode active material (e.g., and its particle size distribution, specific surface area, shape, density, surface chemistry and/or other material parameters), conductive additives type(s) (e.g., and their particle size distribution, specific surface area, shape, density, surface chemistry and/or other material parameters) and relative amount, electrode density, capacity loading, final electrode thickness, calendaring (pressure rolling) conditions and/or other parameters. Excessive binder content in the electrodes (both anodes and cathodes), for example, may undesirably reduce volumetric capacity of the electrodes or reduce electrode porosity and increase tortuosity, thus negatively affecting energy density or power density or both. In some designs, excessive binder content and insufficient remaining pore volume may also induce premature failure due to excessively increased resistance growing during cycling. Finally, higher binder content may increase total material costs. Too little binder, on the other hand, may provide insufficient mechanical robustness to the electrode and induce premature electrode failure during cycling or delamination from the current collector in some designs. While the optimum content may vary greatly, electrodes in accordance with some designs may comprise from around 0.15 wt. % to around 15 wt. % of the binder relative to a total weight of the respective electrode.

Unfortunately, in many cell designs, some polymer binders suffer from undesirable interactions in contact with the electrolyte during either cell manufacturing or cell operation. Some of such binders may suffer from insufficiently good thermal or chemical or mechanical or physical properties. In some embodiments of the present disclosure, it may be advantageous for (e.g., organic) polymer binders (e.g., various polyacrylates (e.g., PAA, PMA, PBA, PVA, PAN, etc.), various aliphatic and aromatic synthetic polymers (e.g., PE, polyisoprene, PVB, PS, PU, etc.), various proteins (e.g., gelatine, caseinate, etc.), various oligo and polysaccharides (e.g., cellulose, alginate, starch, chitosan, pectine, amylose, gums, etc., some of which may be modified by fluorination or other means), various fluorinated acrylate polymer latexes, and/or PTFE, modified (incl. partially fluorinated) styrene butadiene rubber copolymers (SBR), etc.), in the electrodes (anodes or cathodes or both) to enhance their thermal stability or enhance their wetting by the electrolyte or reduce swelling in the electrolyte or attain larger elastic modulus or toughness or enhance oxidation stability on the cathode or enhance reduction stability on the anode or attain other modifications of their thermal, mechanical, chemical and/or physical properties. For example, some of the polymer binders may exhibit undesirably large swelling in certain electrolytes or may lose their mechanical properties in contact with certain electrolytes or suffer from poor wetting by certain electrolytes. One or more embodiments of the present disclosure enable one to reduce or overcome some or all of such limitations. In some designs, some or all such enhancements may be attained by the depositing the surface layer of, for example, inorganic material on the binder surface (in some designs, at least partially, infiltrating such an inorganic (in some designs, metalorganic or organometallic) material into the bulk or the surface layer of the binder) after electrode fabrication (e.g., by casting, drying, and calendaring or by other means). In some designs, it may be advantageous for the deposited surface layer to coat over about 50% of the binder surface. In other designs, it may be advantageous for the deposited surface layer to coat over about 60% of the binder surface (in some designs—over about 70%, in some designs—over about 80%, in some designs—over about 90%, in some designs—over about 95%, in some designs—over about 98%, in some designs—over about 99%, in some designs—over about 99.5%, in some designs—over about 99.9%). In some designs, at least a portion of such an inorganic component may be advantageously incorporated (e.g., infiltrated) into the bulk of the binder within the electrode (e.g., in addition to the surface coating). In many cases, the deposition of suitable interfacial layer on the surface (or in the bulk) of the binder after the electrode formation may be challenging, time consuming and expensive. As a result, such a layer is not used in large scale production facilities and in commercial cell production. Some embodiments of the present disclosure describe routes to reduce or overcome such a limitation.

In some embodiments of the present disclosure, carbon nanotubes (e.g., multiwalled, double-walled, single-walled, etc.), carbon nanofibers and other one dimensional (1D) carbon materials, exfoliated graphite, graphene, graphene oxide (e.g., multiwalled, double-walled, single-walled, etc.) and other two dimensional (2D) carbon materials, carbon black or carbon onions and other zero dimensional (0D) carbon materials as well as various dendritic carbon and other structures three dimensional (3D) carbon materials may be effectively used as conductive carbon additives in electrode construction. In some designs, conductive oxide(s), oxynitride(s), carbide(s) or metal(s) in the form of 0D, 1D and 2D materials (e.g., nanoparticles, nanofibers/nanowires or nanoflakes, respectively) may be successfully utilized as conductive additives. In some designs, conductive additives and active particles may have an opposite charge. In some designs, conductive additives and/or active particles may have functional groups attached to their surface. In some designs, heating of the electrode after casting or calendaring may induce formation of chemical bonds between conductive additives and active particles. While the optimum content may vary greatly, electrodes in accordance with some designs may comprise from around 0.02 wt. % to around 10 wt. % of the conductive additives relative to a total weight of the respective electrode (without considering the weight of the current collector but considering the surface layer or interlayer, if present). In some designs, excessive content of conductive additives in the electrodes (both anodes and cathodes) may undesirably reduce volumetric capacity of the electrodes or increase pore tortuosity or increase first cycle losses, thus negatively affecting energy density or power density or both. Finally, higher content of conductive additives may increase total material costs. Too little conductive additives, however, may provide insufficient electrical connectivity within the electrode, reduce its mechanical stability, and also reduce its power rate and increase electrode resistance in some designs. As such, in some designs, it is generally desirable to reduce the amount of binder and conductive additives to the level where one or more other desired battery characteristics (e.g., sufficiently good mechanical properties, sufficiently good thermal stability, sufficiently small swelling in liquid electrolytes, sufficiently low resistance, sufficiently high power, sufficiently good adhesion to the current collector foils, etc.) are attained for the desired application and application-specific specifications. As such, for each cell (with its specific electrolyte, active material type, electrode thickness and areal loadings, etc.), the amounts of both the binder and conductive additives may be optimized for particular applications.

Unfortunately, in many cell designs, some conductive additives suffer from undesirable interactions with the electrolyte or even binder used. For example, some electrolytes exhibit poor wetting on the surface of some conductive additives. Some conductive additives suffer from oxidation at high cathode potentials. Some conductive additives (e.g., carbon-based) suffer from anion intercalation at high cathode potentials. Some conductive additives (e.g., metal or metal-containing) suffer from dissolution at high cathode potentials. Some conductive additives may induce gas generation on their surface (e.g. in the cathode or anode or both), e.g., gas induced by electrolyte or binder decomposition in certain voltage ranges. Some conductive additives may catalyze undesirable reactions of the electrolyte on their surface (e.g., excessive surface layer formation, etc.). Some conductive additives (e.g., metal-containing) may chemically react with the electrolyte, particularly at elevated temperatures. Some conductive additives may suffer from limited thermal stability or limited oxidation stability when exposed to ambient environment (e.g., air), particularly at elevated temperatures. One or more embodiments of the present disclosure allows one to overcome or mitigate some of such limitations. In some designs, some or all such limitations may be mitigated by the depositing a protective surface layer on the surface of conductive additives that would be exposed to electrolyte after the electrode formation (e.g., by casting, drying and calendaring or by other means) and cell assembling. In some designs, it may be advantageous for the deposited surface layer to coat over about 50% of the surface of conductive additives that otherwise would be exposed to the electrolyte. In some designs, it may be advantageous for the deposited surface layer to coat over about 50% of the surface of conductive additives that otherwise would be very close to the electrolyte (e.g., not covered by more than about 2-5 nm of the polymer binder material). In other designs, it may be advantageous for the deposited surface layer to coat over about 60% of the exposed (e.g., not covered by about 2 nm or more of the binder) conductive additives' surface (in some designs—over about 70%, in some designs—over about 80%, in some designs—over about 90%, in some designs—over about 95%, in some designs—over about 98%, in some designs—over about 99%, in some designs—over about 99.5%, in some designs—over about 99.9%). In many cases, the deposition of suitable interfacial layer on the surface of conductive additives exposed to an ambient gas (e.g., air) after the electrode formation may be challenging, time consuming and expensive. As a result, such a layer is not used in current large scale production facilities and in commercial cell production. Some embodiments of the present disclosure describe routes to reduce or overcome such a limitation.

Copper or copper-containing/copper-based foil or mesh is typically used as a current collector for graphite, carbon or Si-based anodes for Li-ion batteries, and aluminum foil is typically used as a current collector for cathodes for Li-ion batteries and higher voltage anodes (such as LTO, among others). However, other metal current collectors, such as collectors based on titanium, nickel, stainless steel, and other metals may similarly be used in some designs. In some designs, metal foil or mesh may also comprise filler materials (including nanomaterials) in the form of the fibers (or nanofibers), flakes (or nanoflakes), particles (or nanoparticles), dendritic structures and in other forms. In some designs, such filler materials may comprise a polymer or a carbon or a metal or a ceramic material.

In some designs, the direct interactions between the current collectors and electrolyte may induce undesirable side reactions, such as chemical reaction(s) with the formation of insulating phases, corrosion of the current collector (e.g., cathode current collector) at high electrochemical potentials, embrittlement of the current collector (e.g., anode current collected) at low electrochemical potentials, among others. Such undesirable interactions may get more pronounced at elevated temperatures. One or more embodiments of the present disclosure allows one to overcome or mitigate some of such limitations. In some designs, some or all such limitations may be mitigated by depositing a protective surface layer on the surface of current collectors that would be exposed to electrolyte after the electrode formation (e.g., by casting onto the current collector surface, drying and calendaring or by other means) and cell assembling. In some designs, it may be advantageous for such a coating to be relatively uniform in thickness (e.g., within about 10 nm; in some designs—within about 5 nm; in some designs—within about 2 nm; in some designs—within about 1 nm). In some designs (e.g., when a coating does not have high electrical conductivity), it may be advantageous for such a coating to be deposited after the electrode casting so that the contact between the current collector and electrode particles (e.g., the cores of which are mostly inaccessible by the electrolyte) exhibit low contact resistance. In some designs, it may be advantageous for the deposited surface coating layer to coat over about 50% of the surface of current collector that otherwise would be exposed to the electrolyte during cell assembling or cycling. In some designs, it may be advantageous for the deposited surface coating layer to coat over about 60% of such a surface (in some designs—over about 70%; in other designs—over about 80%; in other designs—over about 90%; in other designs—over about 95%; in other designs—over about 99%; in other designs—over about 99.5%; in other designs—over about 99.9%; in yet other designs—over about 99.99%). In many cases, the deposition of suitable interfacial layer on the surface of current collectors while exposed to an ambient gas (e.g., air) after the electrode fabrication may be challenging, time consuming and expensive. As a result, such a layer is not used in large scale production facilities and in commercial cell production. Some embodiments of the present disclosure describe routes to reduce or overcome such a limitation.

In some embodiments of the present disclosure, in order to reduce the relative fraction of inactive materials (e.g., current collector foils, separators, etc.) in electrodes, it may be highly advantageous to produce relatively thick electrodes (e.g., in some designs, with an average thickness in the range from about 60 micron to about 1200.0 micron; in some designs—in the range from about 60 micron to about 800 micron; in some designs—in the range from about 60 micron to about 80 micron; in some designs—in the range from about 80 to about 100 micron; in some designs—in the range from about 100 to about 200 micron; in some designs—in the range from about 200 to about 400 micron; in some designs—in the range from about 400 to about 600 micron; in some designs—in the range from about 600 to about 800 micron; in some designs—in the range from about 800 to about 1,200.0 micron) that are also dense (e.g., with the porosity in the electrode (pores between active (e.g., Li ion storing) material particles, conductive additives and the binder) in the range from about 10 vol. % to about 30 vol. %, or, in some designs, below around 20 vol. % (e.g., about 0 vol. % to about 20 vol. %) or, in some designs, in the range from about 10 vol. % to about 20 vol. % or, in some designs, in the range from about 20 vol. % to about 30 vol. %). In some designs, depending on the volumetric capacity of active particles in the electrodes, relative content of the binder and conductive additives and the porosity, the areal loading of such electrodes may range from about 4.0 to about 1000.0 mAh/cm²; in some designs from about 4.0 to about 6.0 mAh/cm²; in some designs from about 6.0 to about 9.0 mAh/cm²; in some designs from about 9.0 to about 15.0 mAh/cm²; in some designs from about 15.0 to about 30.0 mAh/cm²; in some designs from about 30.0 to about 60.0 mAh/cm²; in some designs from about 60.0 to about 150.0 mAh/cm²; in some designs from about 150.0 to about 300 mAh/cm²; in some designs from about 300.0 to about 1000.0 mAh/cm²). In many cases, the deposition of a suitable coating layer (e.g., conformal, uniform, with proper chemistry and microstructure to reduce or eliminate undesirable reactions with electrolyte, improve electrolyte wetting or stability of the surface layer, reduce charge transfer resistance, improve interactions with binders, improve thermal or mechanical properties of the binders, improve thermal stability or improve other useful electrode or cell properties) may be highly advantageous on the internal surface of thick, dense, high-loading electrodes. Yet, uniform formation of such a later on thick and dense electrodes may be particularly challenging, time consuming and expensive. As a result, such a layer is not used in large scale production facilities and in commercial cell production. Some embodiments of the present disclosure describe routes to reduce or overcome such a limitation. Lower porosity in the electrode may increase volumetric capacity of electrodes and thus battery energy density, which is advantageous in some designs. However, less uniform deposition of a surface coating within dense electrodes may undesirably block ionic pathways and reduce power density of the batteries (rate performance of electrodes) due to slower transport of (e.g., Li) ions during charging or discharging.

In some embodiments of the present disclosure, the application of protective layer coating(s) on the internal surface of the electrodes, electrode particles, current collectors, binder(s), conductive additives, separators (or separator layers) and or other cell components to enhance cell performance may be advantageous. In some designs, such protective surface layer may comprise carbides, oxides or phosphates of one, two, three or more metals and semimetals selected from the following list: carbon, aluminum, zinc, Group IV metals (such as titanium, zirconium, hafnium, etc.), Group V metals (such as vanadium, niobium, tantalum, etc.), rare earth oxides (such as lanthanum, yttrium, cerium, etc.), manganese, molybdenum, lithium, calcium, magnesium, iron, cobalt, nickel, copper, silicon, tin and germanium. In some designs, at least some of such protective surface layer coatings(s) may comprise polymers. In some designs, at least some of such protective surface layer coatings(s) may comprise conductive (e.g., primarily sp² bonded) carbon. In some designs, the surface coatings may be at least partially deposited by using atomic layer deposition (ALD) or chemical vapor deposition (CVD) or physical vapor deposition (PVD) or electrodeposition or electroless deposition or electrophoretic deposition. In some designs, at least some of the protective layer coating(s) may be deposited on the outer surface of individual electrode particles (anode particles or cathode particles) or the outer surface of conductive additives. In some designs, such a surface coating layer(s) on the particles' surfaces may be deposited prior to electrode assembly (e.g., by casting). In some designs, such particle coatings may comprise suitable polymer(s), carbon, metal carbides, metal oxides or phosphates of one, two, three or more metals and semimetals selected from the following list: carbon, aluminum, zinc, Group IV metals (such as titanium, zirconium, hafnium, etc.), Group V metals (such as vanadium, niobium, tantalum, etc.), rare earth metals (such as lanthanum, yttrium, cerium, samarium, etc.), manganese, molybdenum, lithium, calcium, magnesium, iron, cobalt, nickel, copper, silicon, tin, germanium, or a combination thereof. In some designs, the surface coatings on the individual particles may be at least partially deposited by using hydrothermal treatment, solvothermal treatment, atomic layer deposition (ALD), chemical layer deposition (CVD) or physical vapor deposition (PVD).

In some embodiments of the present disclosure, the application of an atomic layer deposition (ALD) technique to deposit protective layer coating(s) on the internal surface of the electrodes, current collectors, binder(s), conductive additives, separators (or separator layers) and or other cell components to enhance cell performance may be advantageous. Such ALD coating(s) may, for example, (i) protect the electrode or electrode components from undesirable interactions with electrolyte (e.g., protect against some irreversible chemical or electrochemical reactions that induce degradation of cell performance, etc.—for example, to reduce gassing or enhancing cycle life or enhancing performance at elevated or reduced temperatures or to enhance calendar life, etc.) or (ii) protect the electrolyte from undesirable oxidation or reduction on the surface of the electrode(s) or cell components or (iii) favorably enhance one or more properties of the interface or interphase between the electrolyte and these electrode or cell components (e.g., reduce interface/interphase resistance or enhance stability, etc.) or (iv) enhance mechanical or thermal properties or improve chemical stability or other properties of various cell components (electrolyte, binder, conductive additives, active materials, etc.) or (v) protect the electrode or electrode components from undesirable chemical (e.g. reaction with water or acid) or electrochemical degradation (e.g. oxygen release from the surface layer of metal oxide cathode materials) and/or (vi) result in multiple favorable performance enhancements. In some designs, the self-limiting nature of the deposition process and the resulting rather unique ability of the ALD to deposit very conformal, dense and uniform coatings with minimal fractions of undesirable defects on various flat and porous substrates at relatively low temperatures (from around −40° C. to around +400° C.; in many cases—from around room temperature to around +200° C.; in some cases—from around room temperature to around +110° C.) may be particularly advantageous for the discussed above applications.

The ALD technique is a surface-controlled process with sequential exposure and purge stages to remove substantially all or all the physisorbed molecule(s) from the system. The gaseous precursors in ALD are supplied one at a time into the reactor and purge stages are applied between reactant introductions. In a typical ALD cycle, a first gaseous precursor introduced into the system forms a chemically-bonded molecule layer on the substrate surface with (ideally) all the physisorbed and gaseous (extra) molecules cleaned off by the following purging process. When a second precursor vapor is introduced, it reacts selectively with the chemisorbed layer of the first precursor, thus creating a monomolecular-level layer of an ALD coating. The excess (physisorbed and gaseous) molecules of the second precursors are similarly purged off with an inert gas. By repeating the process cycles, atomic layer-by-layer growth of the coating may be achieved with a precise control over the thickness governed by the number of ALD cycles. Plasma-assisted ALD (PA-ALD) allows deposition at room temperature and below, which could be particularly attractive for coating deposition on thermally sensitive substrates. Note that in some practical implementations of ALD, multiple pulse-purge sequence sub-steps of the first precursor or multiple pulse-purge sequence sub-steps of the second precursor may be implemented. In some practical implementations of ALD, some of the physisorbed (extra) precursor molecules may still remain attached to the surface in spite of the purge sub-step or step. In some practical implementations of ALD, more than a monomolecular-level growth or less than a monomolecular-level growth may take place in each step. In some practical implementations of ALD, some chemical reaction of one or all of the precursors with the substrate may take place.

However, conventional ALD technique is very slow and expensive and thus not suitable for most commercial applications. Conventional ALD commonly relies on the use of vacuum and the diffusion of the precursors to/from the surface, where reaction should take place. The self-diffusion of gas molecules is a rather slow process (particularly at low temperature and though dense and thick electrodes and other battery components with relatively small pores). As a result, for some of the most attractive battery applications the ALD deposition takes hours, which makes it unsuitably slow. As a result, no large batteries with sufficiently thick, sufficiently dense, sufficiently high-loading electrodes coated by ALD have been reported. Some aspects of the present disclosure enable one to reduce or overcome such limitations.

In some embodiments of the present disclosure, ALD coatings may comprise one, two or more distinct layers. In some designs, at least one of such layers (or the only layer) may comprise metal oxides or metal phosphates or metal halides (e.g., fluorides, etc.) or metal oxy-halides (e.g., oxyfluorides). Illustrative examples of suitable oxide-based ALD coatings may include, but are not limited to aluminum oxide (e.g., Al₂O₃), zinc oxide (e.g., ZnO), oxides comprising Group IV metals (such as titanium oxide, zirconium oxide, hafnium oxide, etc.), oxides comprising Group V metals (such as vanadium oxide, niobium oxide, tantalum oxide, etc.), oxides comprising rare earth metals (such as lanthanum oxide, yttrium oxide, samarium oxide, cerium oxide, gadolinium oxide, etc.), manganese oxide, chromium oxide, molybdenum oxide, niobium oxide, magnesium oxide, iron oxide, cobalt oxide, nickel oxide, copper oxide, silicon oxide, tin oxide, germanium oxide, tin oxide, antimony oxide, cesium oxide, strontium oxide, barium oxide, lithium oxide, lithium phosphate, their various mixtures, alloys and combinations, to name a few. The oxides may be of a broad range of different stoichiometries and have a broad range of metal oxidation states. The exact chemistry, stoichiometry and oxidation states of metal oxides may need to be optimized or tunes for a particular anode or cathode chemistry, surface chemistry, operating electrochemical potential, operating temperature and electrolyte composition, among other factors. In some designs, ALD coatings may include fluorides or oxyfluorides comprising at least one of the following metals: Li, Al, Zn, Ti, Zr, Hf, V, Nb, Ta, La, Y, Sm, Gd, Ce, Cr, Sr, Ga, Bi, Ba, Mn, Mo, Mg, Fe, Co, Ni, Cu, Mo, Nb, Si, Sn, Ge, In, Sb, Cs. In some designs, ALD-deposited oxide or phosphate or fluoride or oxyfluoride layer(s) may be ternary or quaternary or quinary or senary (e.g., comprise two or three or four or five distinct metals with atomic fraction in excess of around 1 at. %, including those described above—Li, Al, Zn, Ti, Zr, Hf, V, Nb, Ta, La, Y, Sm, Gd, Ce, Cr, Sr, Ga, Bi, Ba, Mn, Mo, Mg, Fe, Co, Ni, Cu, Mo, Nb, Si, Sn, Ge, In, Sb, Cs, among others). In some designs, at least one of such layers may comprise lithium (Li). Illustrative examples of lithium-comprising oxides or phosphates may include, but are not limited to lithium titanium oxide or phosphate, lithium lanthanum titanium oxide or phosphate, lithium zirconium oxide or phosphate, lithium lanthanum zirconium oxide or phosphate, lithium tantalum oxide or phosphate, lithium niobium oxide or phosphate, lithium chromium oxide or phosphate, lithium samarium oxide or phosphate, lithium gadolinium oxide or phosphate, lithium aluminum oxide or phosphate, lithium iron phosphate, among others. In some designs, Li may be a part of mixed metal oxides or phosphates or fluorides or oxyfluorides or be in the form of Li₂O or LiOH or Li₂CO₃. In some designs, a subsequent annealing step may be included after an ALD process to form a phase with the desired function rather than a composite of multiple phases.

In some designs, the approximate (e.g., within 5 at. %) formula of a suitable oxide coating or a suitable oxide coating layer may include one of the following illustrative examples: (i) MO, (ii) MO₂, (iii) M₂O₃, (iv) M1M2O; (v) M1M2O₂; (vi) M1M2O₃; (vii) M1M2O₄; (viii) M1M2₂O₄; (ix) M1M2₂O₅; (x) M1M2₂O₆; (xi) M1M2₂O₇; (xii) M1M2₃O₄; (xiii) M1M2₃O₅; (xiv) M1M2₃O₇; (xv) M1M2₃O₈; (xvi) M12M2₃O₈; (xvii) M12M2₃O₁₂; (xviii) M1₂M2₅O₁₂; (xix) M1₃M2₅O₁₂; (xx) M1₄M2₅O₁₂; (xxi) M1M2ₓM3₁₋ₓO₂ (where 0<x<1); (xxii) M1M2ₓM3₁₋ₓO₃ (where 0<x<1); (xxiii) M1M2ₓM3₁₋ₓO₄ (where 0<x<1); (xxiv) M1M2₂ₓM3₂₋₂ₓO₄ (where 0<x<1); (xxv) M1M2₂ₓM3₂₋₂ₓO₅ (where 0<x<1); (xxvi) M1M2₂ₓM3₂₋₂ₓO₆ (where 0<x<1); (xxvii) M1M2₃ₓM3₃₋₃ₓO₄ (where 0<x<1); (xxviii) M1M2₃ₓM3₃₋₃ₓO₅ (where 0<x<1); (where 0<x<1); (xxix) M1M2₃ₓM3₃₋₃ₓO₇ (where 0<x<1); (xxx) M1M2₃ₓM3₃₋₃ₓO₈ (where 0<x<1); (xxxi) M1₂M2₃ₓM3₃₋₃ₓO₈ (where 0<x<1); (xxxii) M1₂M2₃ₓM3₃₋₃ₓO₁₂ (where 0<x<1); (xxxiii) M1₂M2₅ₓM3₅₋₅ₓO₁₂ (where 0<x<1); (xxxiv) M1₃M2₅ₓM3₅₋₅ₓO₁₂ (where 0<x<1); (xxxv) M1₄M2₅ₓM3₅₋₅ₓO₁₂ (where 0<x<1); (xxxvi) M1M2M3₂O₇; (xxxvii) M1₂M2₃M3₅O₁₂; (xxxviii) M1₂M2₃M3₇O₁₂, where M, M1, M2 and M3 are selected among the suitable metals or semimetals (e.g., Li, Al, Zn, Ti, Zr, Hf, V, Nb, Ta, La, Y, Sm, Gd, Ce, Cr, Sr, Ga, Bi, Ba, Mn, Mo, Mg, Fe, Co, Ni, Cu, Mo, Nb, Si, Sn, Ge, In, Sb, Cs, among others). Here, for illustrative purposes, the listed oxide examples include up to three major (>5 at. %) metals or semimetals. However, it should be understood that 4, 5 or more metals or semimetals may be used in some designs, when desired. It should be similarly understood that in some designs, phosphates or fluorides or oxyfluorides may be used instead of or in addition to oxide layers with one, two, three, four or more metals or semimetals may be selected from the following elements: Li, Al, Zn, Ti, Zr, Hf, V, Nb, Ta, La, Y, Sm, Gd, Ce, Cr, Sr, Ga, Bi, Ba, Mn, Mo, Mg, Fe, Co, Ni, Cu, Mo, Nb, Si, Sn, Ge, In, Sb, Cs, among other suitable elements.

In some designs, at least one of the ALD precursors for oxide-based or phosphate-based ALD layer(s) may comprise an oxygen-containing compound (oxidizer), such as water (H₂O), ozone (O₃), oxygen plasma, carbon dioxide, dry air, to name a few.

In some designs, plasma (e.g., local plasma, or remote plasma—when the plasma and material interactions occur at a location remote from the plasma source) may be used to assist the ALD layer deposition.

In some designs, at least one of the ALD layers (or the only ALD layer) may comprise metal nitrides or oxynitrides or fluorides or oxyfluorides or sulfides or selenides or other compounds comprising one, two or more of the O, N, F, S or Se. In case where the protective surface layer or the active material within an electrode comprises F, one of the ALD precursor(s) may comprise a suitable fluorine source, such as NF₃ or F₂ or HF or HF-pyridine or TiF₄ or WF₆ or SF₆ or TaF₅, to name a few. In some designs, the sources of O, N, F, S or Se may comprise metal “dopants” that enhance electrical conductivity of the coating. For example, WF₆ may introduce W dopants into the film, causing an increase in the electronic conductivity relating to concentration of tungsten within the deposited material.

In some designs, metal precursors for the metals, metal oxides, metal nitrides, metal oxynitrides, metal fluorides, metal oxyfluorides, metal sulfides, metal selenides, their various mixtures, and other compounds for other ALD coatings may comprise, but not limited to various metalorganic precursors, such as metal alkoxides (e.g., metal methoxides, metal ethoxides, metal iso-propoxides, butoxides and other alkoxides—e.g., lanthanum isopropoxide, aluminum isopropoxide, among many others), metal 2,2,6,6-tetramethyl-3,5-heptanedionates (e.g., aluminum tris(2,2,6,6-tetramethyl-3,5-heptanedionate, yttrium tris(2,2,6,6-tetramethyl-3,5-heptanedionate), among others), isobutyl-metals (e.g., triisobutylaluminum, among others), methyl-metals (e.g., trimethylaluminum, among others), dimethylamido-metals (e.g., tris(dimethylamido)aluminum, among others), cyclopentadienyl-metals (e.g., bis(cyclopentadienyl)magnesium, tris(cyclopentadienyl)lanthanum, tris(cyclopentadienyl)yittrium, among others); cyclopentadienyl-metal-hydrides (e.g., bis(cyclopentadienyl)zirconium dihydride, among others), methyl-η⁵-cyclopentadienyl-methoxymethyl-metals (e.g., bis(methyl-η⁵-cyclopentadienyl)methoxymethylzirconium, among others); ethyl-metal-hydrides or methyl-metal-hydrides or butyl-metal-hydrides (e.g., triethylgermanium hydride or tributylgermanium hydride, among others); methyl-pentamethylcyclopentadienyl-metals (e.g., dimethylbis(pentamethylcyclopentadienyl)zirconium, among others), dimethylamido-metals (e.g., tetrakis(dimethylamido)zirconium, tetrakis(diethylamido)titanium, among others); metal-(2,2,6,6-tetramethyl-3,5-heptanedionate) or metal-alkoxide-(2,2,6,6-tetramethyl-3,5-heptanedionate) (e.g., zirconium tetrakis(2,2,6,6-tetramethyl-3,5-heptanedionate) or bis(2,2,6,6-tetramethyl-3,5-heptanedionate)zinc or yttrium tris(2,2,6,6-tetramethyl-3,5-heptanedionate) or titanium diisopropoxide bis(2,2,6,6-tetramethyl-3,5-heptanedionate), among others); pentafluorophenyl-metals (e.g., bis(pentafluorophenyl)zinc, among others); ethyl-metals (e.g., diethylzine, among others); methyl-metals (e.g., dimethylzinc, among others); phenyl-metals (e.g., diphenylzinc, among others); N,N-bis(trimethylsilyl)amide-metal (e.g., tris[N,N-bis(trimethylsilyl)amide]yttrium, among others); butylcyclopentadienyl-metals (e.g., tris(butylcyclopentadienyl)yttrium, among others); cyclopentadienyl-metals (e.g., tris(cyclopentadienyl)yttrium, among others); metal halides, including but not limited to metal chlorides or metal borides (e.g., titanium tetrachloride, aluminum chloride, silicon tetrachloride, silicon tetraboride, among others); ethyl-metals (e.g., tetraethylsilane, among others); methyl-metals (e.g., tetramethylsilane, tetramethyldisilane, pentamethyldisilane, among others); tert-butoxy-metals (e.g., tris(tert-butoxy)silanol, among others); tert-pentoxy-metals (e.g., tris(tert-pentoxy)silanol, among others); hexamethyldisilazane and related compounds; to name a few suitable examples of metal precursors.

In some designs, at least one of the ALD layers (or the only ALD layer) may comprise both Li and F or both Al and F or Al, Li and F (e.g., lithium fluoride or LiF, lithium aluminum fluoride or LiAlF₄). In some designs, active material (while integrated as part of a powder or integrated as part of an electrode) may be fluorinated after the ALD layer deposition. For example, lithium oxide may typically be partially fluorinated to form LiF using NF₃ at about 200-600° C. or even lower temperatures. Other metal oxides or metals may be able to be fluorinated via a similar synthesis process.

In some designs, post-ALD deposition annealing or post-fluorination annealing may be utilized at temperatures from around 200° C. to around 1200° C. for a period of time ranging from around 0.1 sec to around 240 hours to further increase ionic conductivity through additional ordering of the material and the formation of higher conductivity crystalline phases.

Illustrative examples of the precursors for the ALD synthesis of lithium aluminum fluoride (LiAlF₄) layer (e.g., material stable at high electrochemical potentials up to ˜5.7V vs Li and exhibiting moderate ionic conductivity of up to 10⁻⁷ S/cm) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) fluorine source(s) (e.g., HF-pyridine, TiF₄, WF₆, SF₆, TaF₅, F₂, NF₃, among others); (iii) aluminum sources(s) (e.g., AlCl₃, TMA, Al(OiPr)₃, among others). In some synthesis methods, multiple thin layers of LiF and AlF₃ may be subsequently ALD-deposited to form lithium aluminum fluoride (e.g., LiAlF₄ or related compositions). In other synthesis methods, Li and Al precursors are used to ALD deposit a thin surface layer comprising both Li and Al, which may be then fluorinated. Such a procedure may be repeated multiple times to increase lithium aluminum fluoride layer thickness. In some procedures, metal sources (e.g., Al source—such as TMA or Al(OiPr)₃, among others) may require a reductant (H₂ or H₂ plasma or other strong reductant) to produce a layer of metal film, which may then be fluorinated.

Illustrative examples of the precursors for the ALD synthesis of lithium aluminum oxide (LiAlO₂) layer (e.g., material also stable at high electrochemical potentials and exhibiting moderate ionic conductivity) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) aluminum source(s) (e.g., AlCl₃, TMA, Al(OiPr)₃, among others); (iii) oxygen source(s) (e.g., H₂O, O₃, oxygen, oxygen plasma, dry air, etc.). In some synthesis methods, the alternative deposition of aluminum oxide (e.g., Al₂O₃) layer (e.g., via introduction of the Al precursor layer followed by the introduction of the 0 precursor and the resulting oxidation of A1) followed by deposition of Li₂O, LiOH, or Li₂CO₃ layers (e.g., via introduction of the Li precursor layer followed by the introduction of the O precursor and the resulting oxidation of Li) may be repeated multiple times to attain the desired thickness. In other designs, Li and Al precursors may be introduced concurrently, followed by oxidation using an oxygen source to convert the respective precursors to lithium aluminum oxide (e.g., this growth method may reduce or prevent formation of LiOH which may hydrate and reduce or prevent self-limited ALD growth on subsequent cycles).

Illustrative examples of the precursors for the ALD synthesis of lithium phosphate (Li₃PO₄) or lithium phosphorousoxynitride (LiPON) (e.g., which are also interesting materials exhibiting moderate ionic conductivity and good stability at both low and high electrochemical potentials) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) phosphorous source(s) (e.g., trimethly phosphate (TMP), diethyl phosphoramidate (DEPA), tris(dimethlyamino)phosphorous (TDMAP), t-butylphosphine (TBP), among others); (iii) oxygen source(s) (e.g., H₂O, O₃, oxygen, oxygen plasma, dry air, etc.); (iv) optional nitrogen source(s) (for LiPON) (e.g., nitrogen plasma, NH₃, etc.). In some designs, ALD-deposited lithium phosphate or lithium phosphorousoxynitride layer(s) may be coated with thin (e.g., between about around 1 nm and around 50 nm) layer(s) of ZnO, Al₂O₃, ZrO₂, HfO₂, Fe₂O₃, CeO₂, lithium titanate, lithium aluminum oxide, lithium aluminum fluoride, lithium lanthanum titanate, lithium lanthanum zirconate, lithium tanatalate, lithium iron phosphate or other suitable (stable in contact with moisture or air) metal or mixed metal oxides or phosphates in order to protect lithium phosphate or lithium phosphorousoxynitride from undesirable interactions with air, O₂, H₂O and/or other compounds present in open air.

Illustrative examples of precursors for the ALD synthesis of lithium iron phosphate (LFP) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) phosphorous source(s) (e.g., trimethly phosphate (TMP), diethyl phosphoramidate (DEPA), tris(dimethlyamino)phosphorous (TDMAP), t-butylphosphine (TBP), among others); (iii) oxygen source(s) (e.g., H₂O, O₃, oxygen, oxygen plasma, dry air, etc.); (iv) iron source(s) (e.g., decamethylferrocene (Fe(Cp)₂), iron pentacarbonyl (Fe(CO)₅) or various other iron carbonyl complexes, Fe(thd)₃, iron chloride (FeCl₃), tert-butylferrocene (TBF) or various other ferrocene complexes, bis(N,N′-di-tert-butylacetamidinato)iron), iron tert-butoxide, bis[bis(trimethylsilyl)amide]iron, bis(N-isopropylketoiminate) iron, iron acetylacetonate, iron hexafluoroacetylacetonate or trifluoroacetylacetonate, among others).

Illustrative examples of precursors for the ALD synthesis of lithium fluoride (LiF) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) fluorine source(s) (e.g., HF-pyridine, TiF₄, WF₆, SF₆, TaF₅, F₂, NF₃, among others).

Illustrative examples of precursors for the ALD synthesis of lithium titanate in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) oxygen source(s) (e.g., H₂O, O₃, oxygen, oxygen plasma, dry air, etc.); (iii) titanium source(s) (e.g., titanium isopropoxide, titanium t-butoxide, titanium methoxide, tetrakis dimethylamido titanium, tetrakis diethlyamido titanium, titanium tetrachloride, among others).

Illustrative examples of precursors for the ALD synthesis of lithium lanthanum titanate (which may exhibit extremely high ionic conductivity) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) oxygen source(s) (e.g., H₂O, O₃, oxygen, oxygen plasma, dry air, etc.); (iii) titanium source(s) (e.g., titanium isopropoxide, titanium t-butoxide, titanium methoxide, tetrakis dimethylamido titanium, tetrakis diethlyamido titanium, titanium tetrachloride, among others); (iv) lanthanum source(s) (e.g., lanthanum cyclopentadienyl (La(Cp)₃), La(thd)₃, La(thd)₃ tetraglyme adduct (or diglyme adduct, etc.), tris(isopropyl-cyclopentadienyl)lanthanum, lanthanum tris(N,N′-diisopropylacetamidinate), among others).

Illustrative examples of precursors for the ALD synthesis of lithium lanthanum zirconate in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) oxygen source(s) (e.g., H₂O, O₃, oxygen, oxygen plasma, dry air, etc.); (iii) zirconium source(s) (e.g., zirconium tert-butoxide (Zr(OtBu)₄), tetrakis(ethylmethylamido) zirconium, tetrakis(dimethylamido) zirconium, zirconium isopropoxide, Zr(thd)₄, ZrCl₄, among others); (iv) lanthanum source(s) (e.g., lanthanum cyclopentadienyl (La(Cp)₃), La(thd)₃, La(thd)₃ tetraglyme (or diglyme) adduct, tris(isopropyl-cyclopentadienyl)lanthanum, lanthanum tris(N,N′-diisopropylacetamidinate), among others).

Illustrative examples of precursors for the ALD synthesis of cerium oxide (e.g., CeO₂, which may exhibit high ionic conductivity and good electrochemical stability) in the temperature range from around room temperature to around 500° C. may include: (i) oxygen source(s) (e.g., H₂O, O₃, oxygen, oxygen plasma, dry air, etc.); (ii) cerium source(s) (e.g., tris(isopropyl-cyclopentadienyl)cerium, Ce(thd)₄, [Ce(hfac)₃(L)] where L is diglyme or glyme, cerium 1-methoxy-2-methyl-2-propanolate [Ce(mmp)₄], among others).

Illustrative examples of precursors for the ALD synthesis of lithium niobium oxide (which may exhibit moderate ionic conductivity and good electrochemical stability) in the temperature range from around room temperature to around 500° C. may include: (i) lithium source(s) (e.g., lithium tetramethylheptanedionate (LiTHD), lithium tert-butoxide (LiOtBu), lithium bis(trimethylsilyl)amide (LiHMDS), lithium cyclopentadienide (LiCp), among others); (ii) niobium source(s) (e.g., niobium ethoxide, niobium chloride, among others); (iii) oxygen source(s) (e.g., H₂O, O₃, oxygen, oxygen plasma, dry air, etc.).

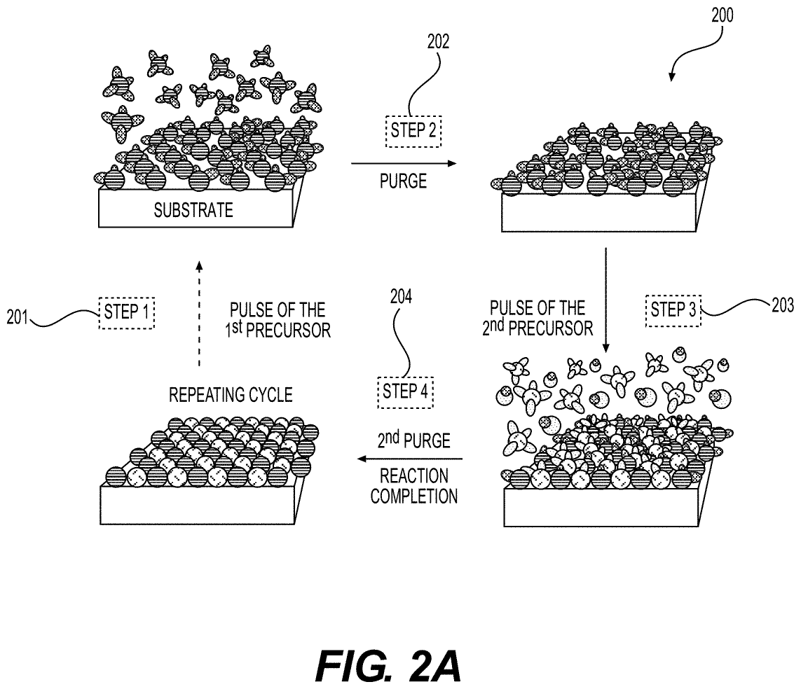

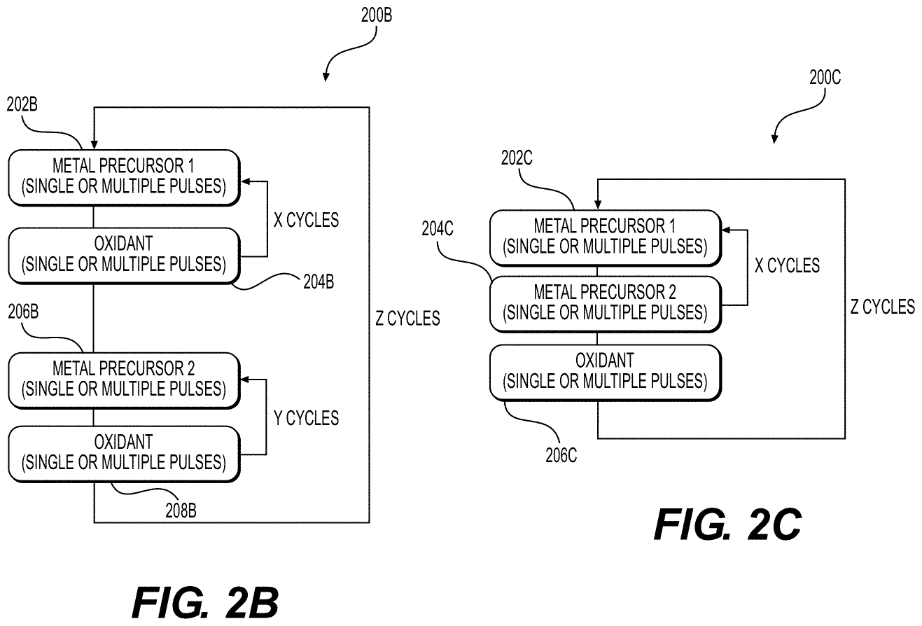

FIG. 2A shows example of steps involved in a single ALD cycle (200). Each cycle may involve 4 or more steps: e.g., a pulse of a first precursor (201)—step 1, a first purge step (202)—step 2, a pulse of a second precursor (203)—step 3, and a second purge step (204)—step 4. During purge steps (202) and (204), undesirable gas molecules may be removed from the system by using vacuum and/or flow of an inert gas (e.g., He or Ar or in some cases N₂ or other inert gases). In some designs, each of the steps (either pulses or purges) may, in turn, comprise additional sub-steps. For example, purge steps (202) or/and (204) may comprise one, two or more sub-steps, such as a vacuum sub-step (or, more generally, reduced average pressure compared to the gas introduction sub-step) and an inert gas introduction sub-step. Such sub-steps may be separated in time or in space, in some designs. In some designs, the vacuum may be pumped continuously, whereas inert gas may be introduced in individual (or discrete) sub-steps. In another example, precursor introduction steps (201) and/or (203) may comprise one, two or more sub-steps of introducing pulses of the precursors and pulses of vacuum drawing (which may be separated in time or in space, in some designs). In some designs, the vacuum may be pumped continuously, whereas the respective precursor gas may be introduced in sub-steps. The use of a vacuum may help to increase the mean free path for the molecules and accelerate diffusion to the interior surface of porous electrodes. In some designs, a wait period after precursor pulse(s) is added before the purge step to increase diffusion to a greater proportion of the substrate, either with or without inert carrier gas or application of dynamic vacuum. The ALD deposition temperature, pressure, and time of an individual step (or sub-step, if each step comprises sub-steps) may be selected so as to reduce or prevent condensation of precursor molecules, while also reducing or avoiding decomposition of the precursor molecules. For most metal organic precursors and common step times, a temperature below about 500° C. (for some precursors, below about 300° C.; for some other precursors, below about 200° C.) may be used.

As previously discussed, in some designs, ALD coatings may comprise two or more metals. FIGS. 2B-2C illustrate exemplary ALD processes 200B-200C, respectively, that may be used for the formation of compounds comprising two metals (e.g., a ternary oxide) in accordance with embodiments of the disclosure. In one example of an ALD cycle as shown in the ALD process 200B of FIG. 2B, the same or different oxidizing precursor(s) (oxidizer(s)) may be introduced after each metal precursor introduction step. For example, at 202B, a first metal precursor may be introduced in one or more pulses, followed by introduction of an oxidant in one or more pulses at 204B. 202B-204B may repeat for x cycles, where x is greater than or equal to 1. At 206B, a second metal precursor may be introduced in one or more pulses, followed by introduction of an oxidant in one or more pulses at 208B. 206B-208B may repeat for y cycles, where y is greater than or equal to 1 and where y may be the same as or different from x. 202B-208B may repeat for z cycles, where z is greater than or equal to 1 and the same as or different from x and/or y.

In another example of an ALD cycle as shown in the ALD process 200C of FIG. 2C, oxidizing precursor(s) (oxidizer(s)) may be introduced after both metal precursors are introduced (to oxidize both of them together). For example, at 202C, a first metal precursor may be introduced in one or more pulses, and a second metal precursor may be introduced in one or more pulses at 204C. 202C-204C may repeat for x cycles, where x is greater than or equal to 1. At 206C, an oxidant is introduced in one or more pulses. 202C-206C may repeat for z cycles, where z is greater than or equal to 1 and the same as or different from x.

In FIGS. 2B-2C, purge steps and/or sub-steps for omitted from illustration for the sake of simplicity. In some designs, there may be an additional annealing step after the ALD deposition (in some designs, after the entire deposition process), where the annealing temperature may range from around the deposition temperature to around 600° C. (depending on the thermal stability of the ALD-coated substrate).

In conventional ALD, individual cycles and individual steps (or individual sub-steps) within each ALD cycle are separated by time and not by space. In conventional ALD, the substrate (e.g., porous electrode or porous separator, etc.) is static during each sub-step and/or during each step and/or during each cycle and/or during the whole multi-cycle deposition process. In some embodiments of the present disclosure, the individual cycles, steps, and/or sub-steps may be separated by space. In other words, each cycle, each step, and/or each sub-step may take place in a different portion of the ALD deposition system (e.g., intermediate stage products may be transported between different parts of the reactor, with different cycles, steps, and/or sub-steps implemented before/after the respective transportation of the intermediate stage product). Furthermore, in some embodiments of the present disclosure, the ALD substrate (e.g., porous electrode or porous separator, etc.) may be moving (e.g., moving horizontally along a plane of the substrate, or moving in oscillations, etc.) during whole multi-cycle deposition process, and/or during each cycle, and/or during each step, and/or during each sub-step. In some designs, such a move may be discontinuous (e.g., move, stop, move, stop, etc.). In other designs, such a move may be continuous. Furthermore, in some embodiments of the present disclosure when certain steps or sub-steps are separated geometrically (e.g., spatially separated, i.e., performed with respect to different parts of a substrate), the respective steps or sub-steps may take place at the same time (in some designs, continuously) on different (e.g., geometrically separated and non-overlapping) areas of the substrate (e.g., porous electrode or porous separator, etc.). In some embodiments of the present disclosure, the ALD deposition may be conducted roll-to-roll (e.g., starting with a roll of a flexible porous electrode, ALD coating it and re-reeling it to create an output roll), continuously or quasi-continuously (e.g., with stops). As a result of the described embodiments, significantly faster ALD deposition rates and more uniform deposition may be attained.

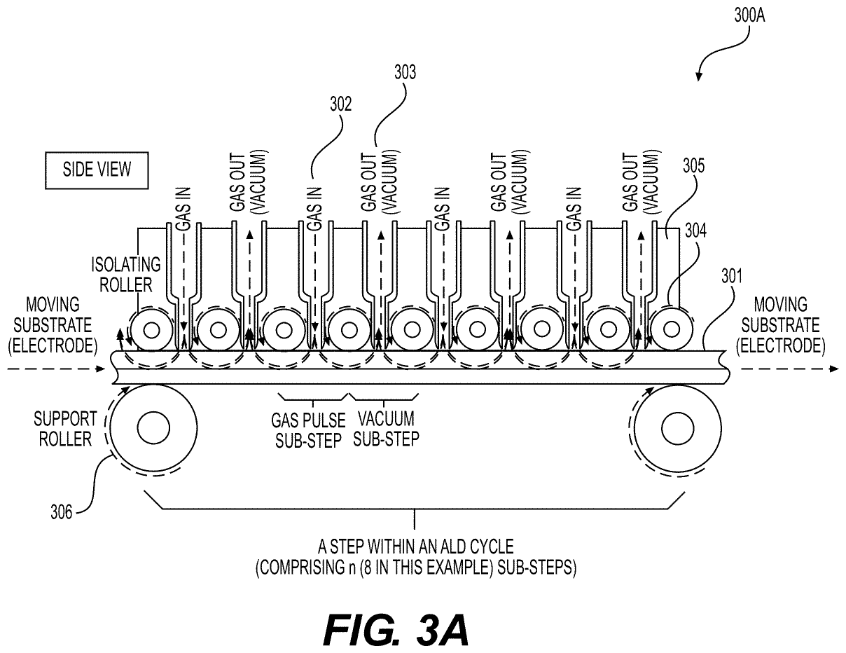

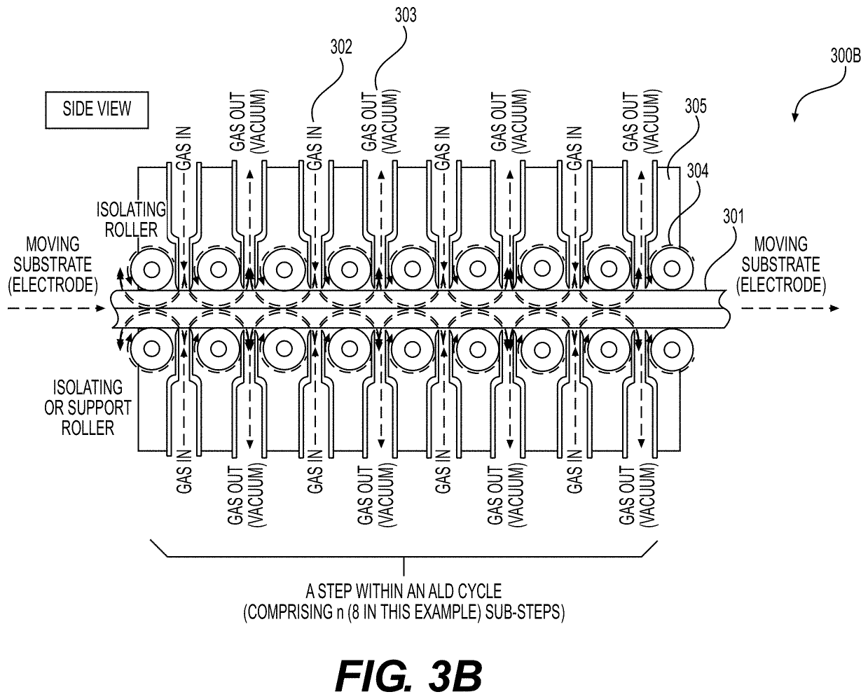

FIG. 3A shows an illustrating example of an individual ALD step 300A (within an ALD cycle) design implementation, where a flexible substrate (e.g., porous electrode or porous separator, etc.) 301 is moving (e.g., roll-to-roll, e.g., via a substrate mover such as a conveyor belt or sheet roller, etc.) within an ALD system and where individual sub-steps are separated geometrically. In this design example, an array of gas nozzles with a flowing gas (e.g., an inert gas in case of a purge step or a precursor gas in case of a pulse step) 302 are geometrically separated from the array of exhaust (e.g., vacuum) nozzles 303. Optional isolating (flow-resisting) rollers 304 and optional flow resistive media 305 may be advantageously used in order to reduce or minimize the flow of the gas outside the substrate (electrode) pores and direct a significant portion of the gas (e.g., about 20-100%) to flow through the interconnected electrode pores. Support rollers 306 are an example of a substrate mover which may direct the movement of the substrate. In this particular illustrating example, 4 arrays of gas nozzles and 4 arrays of exhaust (e.g., vacuum) nozzles (for the total of 8 individual sub-steps in each deposition step) are used. In some designs, the number of gas nozzle arrays and the number of exhaust (e.g., vacuum) nozzle arrays in each step may range from 1 to around 1000 (in some designs, from around 2 to around 100; in some designs, from around 4 to around 40). In some designs, the number of nozzles in each array depends on the width of the substrate (e.g., porous electrode), but may generally range from around 1 to around 2000 (in some designs, from around 1 to around 200). In some designs, the nozzles may be interconnected within the array and/or be a slit-shaped (instead of more commonly used cylindrical). In some designs, instead of using exhaust vacuum nozzles, one may simply use nozzles with lower (relative to gas nozzles) pressure to direct the gas to flow from 302 to 303 through the substrate (electrode) pores. In some designs, the “exhaust” nozzles 303 may operate at near atmospheric pressure (in this case they may not be called “vacuum” nozzles), while the rest of the system (including gas nozzles 302) may operate at higher than atmospheric pressure (be pressurized). In some designs, the pressure difference between the 302 and 303 nozzles may range from around 0.1 atm to around 1000 atm (in some designs, from around 0.5 atm to around 100 atm; in some designs from around 0.9 atm to around 20 atm). In some designs, the spacing between the nozzles and the porous substrate should be carefully selected to reduce or minimize the flow outside the electrode pores on one hand, and to reduce or avoid the direct contact between the nozzles and the porous substrate on the other. In some designs, the spacing between the nozzles and the porous substrate may depend on the mechanical properties of the substrate, e.g., its porosity, its roughness, its uniformity, tension within the substrate and the pressure difference between 302 and 303, among other factors. In most designs though, the spacing between the nozzles and the porous substrate may generally range from around 5 microns to around 1 mm. In some designs, in order to reduce local mechanical bending of the porous substrate 301 by pressurized gas nozzles 302, the porous substrate 301 may be placed on a mechanical support (e.g., belt). In some designs, in order to reduce local mechanical bending of the porous substrate 301 by exhaust (e.g., vacuum) nozzles 303, the mechanical support may be porous and use vacuum suction to firmly attach the porous substrate to its surface. In some designs, the porous substrate 301 may have sufficiently high elastic modulus and be strained to the level that exhaust (e.g., vacuum) nozzles 303 do not touch the porous substrate 301 despite the pressure difference and the resulting force.

FIG. 3B shows another illustrating example of an individual ALD step 300B (within an ALD cycle) design implementation, where a flexible substrate (e.g., porous electrode or porous separator, etc.) 301 is moving (e.g., roll-to-roll, e.g., via a substrate mover such as a conveyor belt or sheet roller, etc.) within an ALD system and where individual sub-steps are separated geometrically. Here again, 8 individual sub-steps (8 nozzle arrays on each side) are depicted for illustrative purposes only, with an understanding that the number of the sub-steps may range from 1 to around 1,000 (more commonly, from around 2 to around 100; in some designs, from around 4 to around 40). In contrast to 300A of FIG. 3A, the ALD deposition in 300B of FIG. 3B takes place from both sides of the substrate. The rollers 304 may provide both mechanical support and help with directing the gas flow through substrate pores. In some designs, the symmetric design shown in this example can balance the forces on the substrate since the forces of the flowing gas nozzles from each size may compensate each other and the forces of the exhaust (e.g., vacuum) nozzles may similarly compensate each other, this helping the substrate to remain flat.

While the FIG. illustrates the horizontal orientation of the substrate and the ALD sub-system (for 1 step), it will be appreciated that the substrate may be oriented vertically or at various angles in different designs.

It will also be appreciated that while ALD cycles may involve 4 steps per cycle as depicted in FIG. 2B (one pulse step to introduce precursor-1, one purge step to remove excess of the precursor-1 molecules, one pulse step to introduce precursor-2, one purge step to remove excess of the precursor-2 molecules), more than 4 steps per cycle may be used in some designs (e.g., 5, 6, 7 or 8 steps for more complex ALD reactions).

It will also be appreciated that while common ALD exposes substrate to the same temperature during each of the cycles and each of the steps and each of the sub-steps, in some embodiments of the present disclosure it may be advantageous for the temperature of the substrate (or heaters or both) in some steps (or even in sub-steps) to be slightly different. For example, in some designs, it may be advantageous for the average temperature of the substrate during a purging step to be slightly different than the average temperature of the substrate in one of the precursor introduction steps. In some designs, such a temperature of the substrate difference may vary from around −100° C. to +100° C. (in some designs, from around −50° C. to +50° C.; in some designs, from around −20° C. to +20° C.; in some designs, from around −5° C. to +5° C.). In other designs, it may be advantageous for the average temperature of the substrate during one of the precursor introduction steps to be slightly different than the average temperature of the substrate in another one of the precursor introduction steps. In some designs, such a temperature of the substrate difference may vary from around −100° C. to +100° C. (in some designs, from around −50° C. to +50° C.; in some designs, from around −20° C. to +20° C.; in some designs, from around −5° C. to +5° C.). In some designs, higher temperature of the substrate in one of the precursor introduction steps may be desired, for example, to reduce or prevent precursor condensation or to reduce or minimize chemical vapor deposition (CVD)-like reactions that are not self-limited (when desired). In some designs, higher temperature of the substrate during one or two or more of the purging steps may be desired to accelerate the removal of extra reactive molecules from the electrode. In some designs, the temperature difference between the heaters positioned in different steps may range from around 10° C. to around 1000° C. (note that the heaters may be much hotter compared to the electrodes). In some designs, it may be advantageous for the average temperature of the substrate (or heaters or both) during different “cycles” to vary. In some designs, lower temperature, for example, may induce ALD deposition of more amorphous structures. In some designs, lower temperature may also exhibit higher deposition rates. In contrast, in some designs higher temperatures may induce deposition of more crystalline and higher purity structures. In some designs, higher temperature, however, may reduce thinner layers deposited in each cycle. In some designs, it may be preferable to deposit coatings at lower temperatures of the substrate during initial ALD “cycles” and at higher temperatures of the substrate during later ALD “cycles”. In other designs, the opposite may be preferable—deposit coatings at higher temperatures during initial ALD “cycles” and at lower temperatures during later ALD “cycles”.

In some designs, the number of ALD cycles to deposit a suitable coating thickness on the surface of porous electrodes depends on the deposition conditions (e.g., temperature, pressure, flow, time, etc.) and chemistry of the precursors, the final desired coating chemistry and the desired final coating thickness. In most designs though, the number of cycles may range from around 1 to around 1000 (in some designs, from around 2 to around 40; in some designs, from around 40 to around 100; in some designs, from around 100 to around 300; in some designs, from around 300 to around 1000). The total number of steps (or sections if each step is geometrically separated) in the ALD system may range from around 4 to around 1600 (in some designs, from around 4 to around 160). The total number of sub-steps in the ALD system may range from around 4 to around 1,600,000 (in some designs, from around 40 to around 8,000).

Conventional ALD on the electrode surface is conducted after the electrodes are fully densified (calendared). However, in some embodiments of the present invention, it may be advantageous for the ALD deposition to take place before electrode densification (or at least before the final densification). This is because larger and less torturous pores (which are reduced by electrode densification) may enable much faster gas diffusion, lower resistance to flow and thus faster deposition of the surface coating layer. In some designs, the ALD may be conducted on the electrodes with a pore volume in the range from around 10 vol. % to around 80 vol. % (in some designs—from around 12 vol. % to around 70 vol. %). In some designs, electrodes may be substantially densified after the ALD. In some designs, the ALD and subsequent (optional) densification may reduce pore volume by more than about 10% (relative to the electrode pore volume before the ALD) (in some designs, by more than about 30%; in some designs—by more than about 50%; in some designs—by more than about 75%; in some design—by more than around 83%). In one example, if an electrode before ALD comprised 60 vol. % of pores, after the ALD and subsequent (optional) densification the electrode may comprise only, e.g., between about 10-54 vol. % of pores.

In some designs, it may be particularly advantageous for the electrode surface coating to cover majority of its accessible internal surface (e.g., excluding closed pores that are totally closed off or inaccessible to any inter-pore pathway to an open surface pore). In some designs, it may be advantageous to use surface coatings to close internal (to the individual particles) pores (if some of such pores remain open prior to the surface coating deposition). In this case, pores that are closed by the deposition of the surface coating itself may comprise some amount of surface coating on the inside of such closed pores. In some designs, it may be preferable or highly important for at least 70% of the internal electrode surface or internal electrode particle surface to be surface-coated (in other designs, at least 80%; in other designs, at least 90%; in other designs, at least 95%; in other designs, at least 98%; in yet other designs, at least 99.5%). This is because reduced surface coating may not provide sufficient protection against side reactions or reduced electrolyte wetting to undesirable levels or provide other insufficiently good performance improvements. In some designs, it may be preferable for at least 90% of the active electrode particles (not counting conductive additive particles) to be at least partially coated by the surface layer (in other designs, at least 95%; in other designs, at least 98%; in other designs, at least 99%; in yet other designs, at least 99.9%). In some designs, it may be preferable for at least 90% of the active electrode particles (not counting conductive additive particles) to have at least 90% of the outer surface area (in some designs, at least 95% of the outer surface area; in yet other designs, at least 99% of the surface area) being coated by (encased in) the surface layer (in other designs, at least 95% of the electrode particles; in other designs, at least 98%; in other designs, at least 99%; in yet other designs, at least 99.9%). In some designs, the surface coating may be deposited on the electrode particles after the electrode particles are made part of a casted electrode. In this case, the surface of some or all of the electrode particle may comprise a first inaccessible part where the electrode particle contacts adjacent electrode particle(s) and a second accessible part upon which the surface coating may be deposited. The direct contact between the electrode particles may enable good electrical connection within the electrode even if the coating is electrically insulative. In some designs, the % of the outer surface area of the electrode particles on which the surface coating is deposited is relative to the second accessible part. In other designs, the % of the outer surface area of the electrode particles on which the surface coating is deposited is relative to a total outer surface area of the electrode particles inclusive of both the first inaccessible part and the second accessible part. In yet other designs, the surface coating may be deposited on the electrode particles while the electrode particles are in a powder form before being made part of a casted electrode. In this case, the % of the outer surface area of the electrode particles on which the surface coating is deposited is relative to a total outer surface area of the electrode particles since the entire outer surface area of the electrode particles is generally accessible to ALD deposition while the electrode particles are in powder form.

In some designs, it may be particularly advantageous for the electrode surface coating to be highly uniform. Too thick of the coating may reduce charging or discharging rate or induce undesirable mechanical behavior of the electrodes (e.g., internal cracking or coating delamination during cycling) or increase fabrication costs, etc. Too thin of the coating may not provide sufficient protection or desired functionality. In some designs, the top 20% of the electrode (the part that touches a separator or a separator layer) may preferably have an average coating thickness of no more than 2 times higher (in some designs, of no more than 30% higher) than the bottom 20% of the electrode (the part that touches a current collector). In some designs, a standard deviation of the same electrode particle-to-particle surface layer thickness (e.g., for all electrode particles taken from the top 20% of the electrode or for all electrode particles taken from the bottom 20% of the electrode) may preferably not exceed the mean layer thickness value (in some designs, not exceed ½ of the mean value). In some designs, a standard deviation of the on-particle surface layer thickness may preferably not exceed the mean layer thickness value on the same particle (in some designs, not exceed 12 of the mean value) for about 50-100% of all particles in the electrode. For example, if an individual particle has an about 4 nm average coating layer on its (accessible) surface, the standard deviation of the coating thickness on such a particle may preferably not exceed 4 nm (in some designs, not exceed about 2 nm). In some designs, the electrode surface coating may exhibit an average thickness in the range from around 0.3 nm to around 50 nm (e.g., from around 0.3 nm to around 3 nm or from around 3 nm to around 5 nm or from around 5 nm to around 10 nm or from around 10 nm to around 20 nm or from around 20 nm to around 50 nm, depending on the conformal layer chemistry, morphology, electrode composition and overall cell chemistry and operational conditions) across at least part of the electrode (e.g., top 20% of the electrode, bottom 20% of the electrode, or across all of the electrode from current collector to separator). In some designs, the electrode particle surface coating may exhibit an average thickness in the range from around 0.3 nm to around 50 nm on the internal electrode particle surface(s).

In some designs, in addition to the average thickness being kept within the range from around 0.3 nm to around 50 nm (e.g., from around 0.3 nm to around 3 nm or from around 3 nm to around 5 nm or from around 5 nm to around 10 nm or from around 10 nm to around 20 nm or from around 20 nm to around 50 nm, depending on the conformal layer chemistry, morphology, electrode composition and overall cell chemistry and operational conditions) across at least part of the internal surface(s) of the electrode and/or electrode particle(s), the actual thickness may also be kept within the range from around 0.3 nm to around 50 nm. In other words, in some designs, the thickness may be substantially uniform across the application area (e.g., an interior electrode area or electrode particle area that is at least initially accessible via pore channels, although some of the initially accessible pore space may become inaccessible if sealed/closed by the surface coating deposition).

It will also be appreciated that while in some designs ALD may be preferable for the deposition on porous substrates (e.g., porous electrodes) in terms of very uniform and tightly controlled thickness of the deposited layer, in other designs CVD processes may be used instead of (or in addition to) ALD in order to increase deposition rates while providing sufficient coating uniformity. The advantage of the disclosed approach compared to the conventional (“static”) CVD is faster deposition rate because the diffusion of the precursor molecules to the deposition sites may be reduced or minimized. In some designs when CVD is used instead of ALD and when a single precursor is used or when multiple precursors may be introduced concurrently, the individual “steps” may generally be the same. So, in case of the illustrating examples of 300A and 300B of FIG. 3 being implemented with respect to CVD, the flexible substrate (e.g., porous electrode or porous separator, etc.) 301 may move (e.g., roll-to-roll) within a CVD system and arrays of precursor gas nozzles 302 are geometrically separated from the array of exhaust (e.g., vacuum) nozzles 303. Optional isolating (flow-resisting) rollers 304 and optional flow resistive media 305 may be advantageously used in order to reduce or minimize the flow of the gas outside the substrate (electrode) pores and direct a significant portion of the gas (e.g., about 20-100%) to flow through the interconnected electrode pores. Support rollers 306 are an example of a substrate mover which may direct the movement of the substrate. In this illustrating CVD example, 4 arrays of gas nozzles and 4 arrays of exhaust (e.g., vacuum) nozzles (for the total of 8 individual sub-steps in each deposition step) are depicted. However, if the individual steps in CVD are identical, the whole CVD system could be considered as a single “large” step with the total number of precursor gas nozzle arrays and the number of exhaust (e.g., vacuum) nozzle arrays ranging from 4 to around 40,000 (in some designs, from around 4 to around 100; in some designs, from around 100 to around 1000; in some designs, from around 1000 to around 40,000). In some designs, the number of nozzles in each array depends on the width of the substrate (e.g., porous electrode), but may generally range from around 1 to around 2000 (in some designs, from around 1 to around 200). In some designs, the nozzles may be interconnected within the array and/or be a slit-shaped (instead of more commonly used cylindrical). In some designs, instead of using exhaust vacuum nozzles, one may simply use nozzles with lower (relative to gas nozzles) pressure to direct the gas to flow from 302 to 303 through the substrate (electrode) pores.

Conventional electrodes utilize nonporous electrically conductive metal foil current collectors that are largely impermeable to gas diffusion. In the context of one or more embodiments of the present disclosure, higher performance electrodes may be produced by utilizing a combination of (i) a porous electrically conductive current collector with open pores that allow a gas penetration (in some designs, via an insertion direction that is substantially perpendicular to a plane the porous electrically conductive current collector) with a porous electrode layer deposited on one or both of sides of the porous electrically conductive current collector, and (ii) an ALD coating layer deposited on an internal surface of a porous electrode (and porous current collector). In some embodiments, a pressure gradient may be applied across such a porous electrode in order to direct a high flux (a rapid flow) of the precursor molecules or purging gas molecules (or atoms) into the electrode pores and onto the internal surface of the electrode (in order to form a chemically-bonded molecule layer on the electrode/substrate surface during precursor introduction step or remove/cleaned off excess physisorbed molecules during the purging process step). In some designs of the present disclosure, the use of porous current collectors with open porosity and directing the flux of precursor molecules through the electrode may greatly accelerate the ALD deposition to the level when the process may become commercially viable or enable formation of a significantly more uniform surface coating layer.

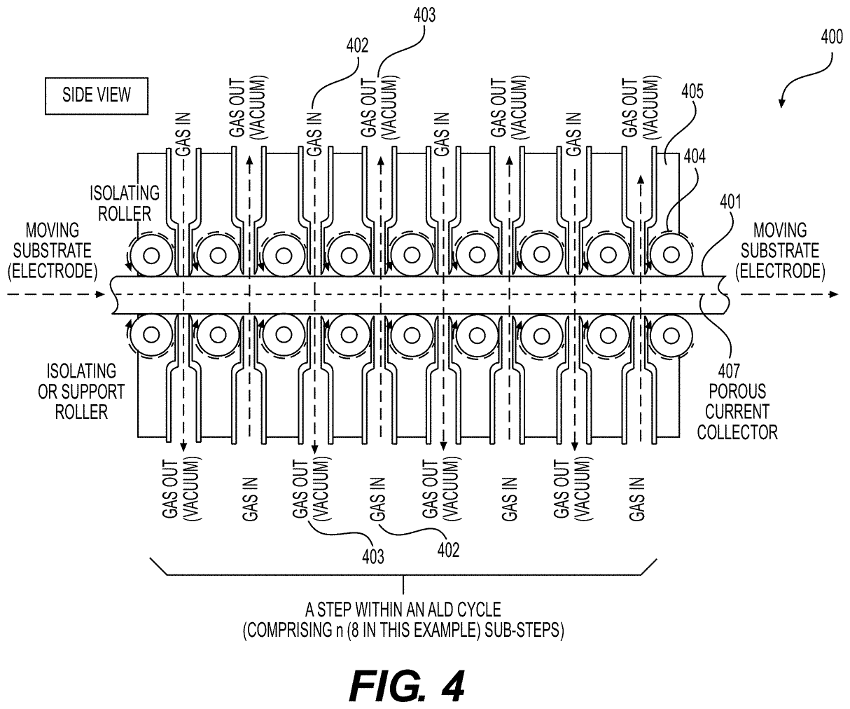

FIG. 4 shows an illustrating example of an individual ALD step 400 (within an ALD cycle) design implementation, where a flexible porous substrate (e.g., porous electrode or porous separator, etc.) 401 is moving (e.g., roll-to-roll) within an ALD system and where individual sub-steps are separated geometrically. In this design example, an array of gas nozzles with a flowing gas (e.g., an inert gas in case of a purge step or a precursor gas in case of a pulse step) 402 are geometrically separated from the array of exhaust (e.g., vacuum) nozzles 403 on each side of the flexible porous substrate (e.g., porous electrode or porous separator, etc.). Here, the porous substrate has pores propagating through the substrate (e.g., porous electrode layer(s) deposited on a porous current collector 407). Optional isolating (flow-resisting) rollers 404 and optional flow resistive media 405 may be advantageously used in order to reduce or minimize the flow of the gas outside the substrate (electrode) pores and direct a significant portion of the gas (e.g., about 20-100%) to flow through the interconnected electrode pores. In this particular illustrating example, 4 arrays of gas nozzles and 4 arrays of exhaust (e.g., vacuum) nozzles (for the total of 8 individual sub-steps in each deposition step) are depicted. In some designs, the number of gas nozzle arrays and the number of exhaust (e.g., vacuum) nozzle arrays in each step may range from 1 to around 1000 (in some designs, from around 2 to around 100; in some designs, from around 4 to around 40). Note in this design the gas nozzles with a flowing gas (e.g., an inert gas in case of a purge step or a precursor gas in case of a pulse step) 402 on one side of the porous substrate (electrode) are positioned across the exhaust (e.g., vacuum) nozzles 403 on the other side of the flexible porous substrate (electrode) so that the gas flows across the electrode in each of the sub-steps. In some designs, somewhere from around 10% to around 100% of the gas flow is directed across the electrode (in some designs—from around 20% to around 99.5%; in some designs—from around 40% to around 98%). Similarly to the previously described examples, the average heater or substrate temperature in different steps (or sub-steps or cycles) may vary in some designs. In some designs, similarly to the previously described examples, the pressure difference between the 402 and 403 nozzles may range from around 0.1 atm to around 1000 atm (in some designs, from around 0.5 atm to around 100 atm; in some designs from around 0.7 atm to around 20 atm).

It will also be appreciated that while in some designs ALD may be preferable for the deposition on porous substrates (e.g., porous electrodes) in terms of very uniform and tightly controlled thickness of the deposited layer, in other designs CVD processes may be used instead of ALD in order to increase deposition rates while providing sufficient coating uniformity. One advantage of the disclosed approach compared to the conventional (“static”) CVD is faster deposition rate because the diffusion of the precursor molecules to the deposition sites may be reduced or minimized. In some designs when CVD is used instead of ALD and when a single precursor is used or when multiple precursors may be introduced simultaneously, the individual “steps” may be identical. In some designs, a single system may be used for both ALD and CVD processes. In case of the illustrating example of FIG. 4, a section of the CVD system 400 is shown, where a flexible porous substrate (e.g., porous electrode or porous separator, etc.) 401 is moving (e.g., roll-to-roll) within a CVD system and where individual sub-steps are separated geometrically. In this design example, arrays of gas nozzles with a flowing precursor gas 402 are geometrically separated from the array of exhaust (e.g., vacuum) nozzles 403 on each side of the flexible porous substrate (e.g., porous electrode or porous separator, etc.) 401. Here, the porous substrate 401 has pores propagating through the substrate (e.g., porous electrode layer(s) deposited on a porous current collector 407). In this illustrating example, 4 arrays of gas nozzles and 4 arrays of exhaust (e.g., vacuum) nozzles (for the total of 8 individual sub-steps) are depicted. In some designs, the number of gas nozzle arrays and the number of exhaust (e.g., vacuum) nozzle arrays in the whole CVD system may range from 1 to around 40,000 (in some designs, from around 1 to around 100; in some designs, from around 100 to around 1000; in some designs, from around 1000 to around 40,000). Note in this design the gas nozzles with a flowing gas (e.g., an inert gas in case of a purge step or a precursor gas in case of a pulse step) 402 on one side of the porous substrate (electrode) are positioned across the exhaust (e.g., vacuum) nozzles 403 on the other side of the flexible porous substrate (electrode) so that the gas flows across the electrode in each of the sub-steps. In some designs, somewhere from around 10% to around 100% of the gas flow is directed across the electrode (in some designs—from around 20% to around 99.5%; in some designs—from around 40% to around 98%).

In some embodiments of the present disclosure, it may be advantageous for the majority (e.g., about 50-100 vol. %) of the pores in the porous current collector to be open and connected to both sides of the current collector, thus enabling the passage of gas (e.g., air) or liquid (e.g., electrolyte) across the current collector thickness upon the application of a pressure or concentration gradient. In some designs, the porous current collector discussed above may have a total porosity in the range from around 0.1 vol. % to around 99.9 vol. % (in some designs, from around 0.1 vol. % to around 5 vol. %; in other designs, from around 5 vol. % to around 20 vol. %; in yet other designs, from around 20 vol. % to around 50 vol. %; in yet other designs, from around 50 vol. % to around 99.9 vol. %; in yet other designs from around 0.25 vol. % to around 80 vol. %; in yet other designs, from around 1 vol. % to around 30 vol. %). In some designs, it may be advantageous for open pore volume in the porous current collector to range from around 0.1 vol. % to around 70 vol. % (in some designs, from around 0.1 vol. % to around 1 vol. %; in other designs, from around 1 vol. % to around 5 vol. %; in other designs, from around 5 vol. % to around 20 vol. %; in yet other designs, from around 20 vol. % to around 50 vol. %; in yet other designs, from around 50 vol. % to around 70 vol. %). In some designs, too small pore volume may block the gaseous transport across current collector, while too large pore volume may make it too weak mechanically.

In some embodiments of the present disclosure, the porous current collector may comprise straight (e.g., cylindrically-shaped or slit-shaped or conically-shaped) pores. In some designs, at least a portion of the pores (e.g., about 1-100 vol. %) may be straight.

In some embodiments of the present disclosure, current collectors used in the described designs (including, but not limited to the porous current collectors) may comprise fibers (or nanofibers). In some designs, at least some of such fibers (or nanofibers) may comprise carbon (e.g., about 1-100 at. % in case of carbon atom-containing materials (e.g., such as carbides or carbo-nitrides or carbon oxides or carbon-based polymers, etc.) or about 1-100 wt. % in case of carbon-containing composite fibers). In some designs, carbon-comprising fibers or nanofibers may be in the form of carbon fibers or carbon whiskers or carbon nanotubes. In some designs, at least some of the fibers (or nanofibers) may comprise a polymeric material. In some designs, polymer-comprising fibers (or nanofibers) may comprise about 1-100 wt. % polymers. In some designs, at least some of the polymers may be natural or biopolymers (e.g., polyesters, cellulose, chitin, chitosan, proteins, etc.). In some designs, at least some of the fibers (or nanofibers) may comprise metals or metal alloys (e.g., about 1-100 wt. %). In some designs, current collectors (e.g., porous current collectors) may comprise bonded or fused or welded together metal fibers (metal wires) or metal nanofibers (metal nanowires). In some designs, porous current collectors may comprise ceramic (e.g., oxide—e.g., aluminum oxide, magnesium oxide, zinc oxide, zirconium oxide, copper oxide, mixed metal oxides, etc.) fibers or nanofibers.

In some embodiments of the present disclosure, current collectors used in the described designs (including, but not limited to the porous current collectors) may comprise flake-shaped particles. In some designs, at least some of such particles may comprise carbon (e.g., about 1-100 at. % or about 1-100 wt. %). In some designs, carbon-comprising particles may be in the form of exfoliated graphite or carbon ribbons or multi-layered graphene or single-layered graphene or multi-layered graphene oxide or single-layered graphene oxide or layered carbides (including exfoliated carbides) or layered carbo-nitrides (including exfoliated carbonitrides). In some designs, at least some of the flake-shaped particles may comprise a polymeric material. In some designs, polymer-comprising particles may comprise about 1-100 wt. % of polymer(s). In some designs, the porous current collector may comprise porous particles. In some designs, at least some of the particles may comprise metals or metal alloys (e.g., about 1-100 wt. %). In some designs, at least some of the particles may comprise ceramic material (e.g., about 1-100 wt. %). In some designs, at least some of the particles may comprise metal oxides or metal carbides or metal oxy-carbides or metal oxy-nitrides. In some designs, at least some of the particles may comprise clay. In some designs, porous current collector may comprise bonded or fused or welded together flake-shaped metal particles. In some designs, porous current collector may comprise porous fibers (or porous nanofibers) or porous flake-shaped particles.

In some embodiments of the present disclosure, the overall thickness of the porous current collector for battery electrodes may range from around 2.5 am to around 500 am (in some designs, from around 2.5 am to around 5 μm; in other designs, from around 5 am to around 20 μm; in yet other designs, from around 20 am to around 50 μm; in other designs, from around 50 am to around 500 am). In some designs, thickness substantially smaller than around 2.5 am may lead to undesirably weak mechanical properties, making the electrode coating and cell assembling challenging. In some designs, thickness substantially larger than around 500 am may be unnecessary and undesirably contribute to excessive mass and volume of the cell (in such designs the overall electrode resistance may become limited by the ionic rather than by the electronic resistance). In some designs (e.g., when active particle change significant volume during charge or discharge or when certain level of mechanical properties within the current collectors should be maintained during cycling or when the pore volume within the current collector is relatively small or in some other considerations), it may be advantageous for the porous current collector to comprise little or no active particles in its pores (e.g., have less than about 20% of its pore volume occupied by active material particles). It may further be advantageous for this and other designs to have a thickness of the porous current collector not to exceed half of the thickness of the electrode coating layer. In some designs, it may be advantageous for the thickness of the porous current collector not to exceed around 50 micron (in some designs, not to exceed around 30 micron, in other designs—not to exceed around 20 micron; in other designs not to exceed around 15 micron; in yet other designs—not to exceed around 10 micron). In some designs, too large thickness may undesirably reduce volumetric and gravimetric characteristics of the cell. In some designs, the optimal thickness of the porous current collector may be determined by the combination of cell size, electrode capacity loading, expected charge-discharge rates, operational temperature, electrical conductivity of the electrodes, porosity (pore volume) of the current collector, whether significant amount of active electrode material is impregnated within the porous structure of the current collector, and other factors.

In some embodiments of the present disclosure, a vast majority of the active material (e.g., about 80-100 wt. %) may be located outside the pores of the porous current collector (e.g., casted on its outer surface(s)). In such designs, it may be preferable for the porous current collector thickness to range from around 2.5 μm to around 50 μm (in some designs, from around 5 am to around 20 am). In some designs, too thin current collectors may exhibit insufficient electrical conductivity or insufficient mechanical strength, while too thick current collectors may undesirably take too much of the volume of the cells, thus reducing its volumetric energy density. In some of such designs, the areal density of the current collector may preferably range from around 3 mg/cm² to around 45 mg/cm² for the anode current collector (e.g., comprising copper, titanium, nickel, iron and other suitable metals, among other suitable components) and from around 1 mg/cm² to around 15 mg/cm² for the cathode current collector (e.g., comprising aluminum and other suitable metals, among other suitable components). In some designs, the porous current collector mass may range from around 2% to around 80% of the total mass of the current collector and the electrode (in some designs, from around 5 wt. % to around 65 wt. %). In some designs, too small mass may often reduce the current collector mechanical properties, electrical and thermal conductivity to undesirably low levels (for most applications). In some designs, too large mass, on the other hand, may undesirably reduce specific energy density of the cell to the unacceptably low levels.

In some embodiments of the present disclosure, it may be advantageous for the electrode current collectors (including but not limited to the porous current collectors) to exhibit certain mechanical properties. For example, this is partially because local stresses (taking place while directing the gaseous streams through nozzles or sucking vacuum at different steps and sub-steps of the ALD cycling, etc.) may (undesirably) repeatedly bend and eventually crack or otherwise irreversibly deform current collectors, forming defects and reducing yield in the eventually built cells. While overall mechanical properties of the current collectors may depend on their areal density, their thickness and pore structure, in many suitable designs some important area- or mass-normalized properties of the current collectors may be advantageously fit within some suitable ranges. In some designs, for example, it may be advantageous for the current collectors to exhibit ultimate tensile strength from around 200 MPa to around 2.0 GPa (in some designs, from around 200 MPa to around 400 GPa; in some designs, from around 400 MPa to around 800 MPa; in some designs, from around 800 MPa to around 2,000 MPa). In some designs, too low strength may undesirably lead to the formation of mechanical defects after the application of surface (e.g., ALD) coatings according to some embodiments of the present disclosure. In some designs, too high strength may correlate with inferior electrical conductivity, which may be particularly undesirable in large cells (e.g., cells with total energy in the range from around 10 Wh to around 1000 Wh). In some designs, for example, it may be advantageous for the current collectors to exhibit modulus of elasticity in the range from around 50 GPa to around 500 GPa. In some designs, too low modulus may undesirably lead to significant elastic deformations, while too high modulus may lead to the material being too brittle. In some designs, for example, it may be advantageous for the current collectors to exhibit fracture toughness in the range from around 20 MPa mm² to around 500 MPa mm². In some designs, for example, it may be advantageous for the current collectors to exhibit endurance limit in excess of around 50 MPa (in some designs, in excess of around 100 MPa; in some designs, in excess of around 200 MPa; in some designs, in excess of around 300 MPa). In some designs too low endurance limit may induce undesirable damages in the current collectors after the application of surface (e.g., ALD) coatings according to some embodiments of the present disclosure.

In some embodiments of the present disclosure, it may be advantageous for the free-standing electrode (not attached to a current collector or not coated onto the current collector) to be coated by ALD (or CVD) (e.g., prior to the current collector attachment). Such electrodes may be prepared, for example, by so-called “dry” deposition where the polymer binder is mixed with active (ion-storing) electrode material (and often conductive additives) in a dry state rather than in a polymer binder solution. In some designs, electrostatic spray deposition on a temporary substrate may be utilized for dry electrode coating formation. After optional densification (e.g., by calendaring) the electrode coating may be ALD coated according one of the embodiments of the present disclosure. In some designs, the porous electrode during the ALD deposition may be positioned on a porous, gas permeable substrate (e.g., flexible) to support the electrode and enable the porous electrode to withstand a higher pressure gradient (and thus higher flow) without damage (e.g., fractures, excessive deformations, etc.). In some designs, the porous support may be placed on each side of the electrode (that is electrode being sandwiched between porous substrates) during the ALD deposition. In some designs the porous substrate may have porosity in the range from around 1 vol. % to around 99 vol. % (in some designs, from around 5 vol. % to around 95 vol. %; in other designs, from around 5 vol. % to around 20 vol. %; in other designs, from around 20 vol. % to around 40 vol. %; in other designs, from around 40 vol. % to around 60 vol. %; in other designs, from around 60 vol. % to around 80 vol. %; in other designs, from around 80 vol. % to around 95 vol. %). In some designs, too small porosity (e.g., <1 vol. %) may undesirably restrict the flow, while too large porosity (e.g., >99.9 vol. %) may undesirably reduce substrate's mechanical properties.

In some embodiments of the present disclosure, it may be advantageous for the electrode to be coated by a porous layer comprising ceramic nanofibers (including porous nanofibers) or flakes or nanoflakes (including porous flakes or nanoflakes) or nanoparticles (e.g., Al₂O₃ or SiO₂ or MgO or other metal oxides and their mixtures or other ceramic nanofibers or flakes or particles that are sufficiently electrochemically stable in contact with the electrode surface during battery operation) or their various combinations prior to ALD coating deposition. In some designs, such nanofibers or flakes or particles may comprise Li or Na. In some designs, such nanofibers or flakes or particles may be porous (e.g., with pores in the range from around 0.3 nm to around 100 nm). In some designs, such nanofibers or flakes or particles may exhibit high Li ionic conductivity more than 10⁻⁵ S cm⁻¹ at room temperature (e.g., either because they become filled with a liquid electrolyte or because they are intrinsically conductive). In some designs, a ceramic nanofiber or flake or particle layer may also comprise some amount of a polymer binder (e.g., to improve their mechanical connectivity to each other) or other functional additives. In some designs, such a highly porous nanofiber-based or flake-based or particle-based coating may not only act as a thin (in some designs, e.g., from around 0.2 micron to around 12 micron in thickness) and highly ionically conductive separator layer (ionically conductive and electronically insulative layer), but may also adsorb some of the excess binder in the top electrode layer to prevent (or significantly reduce) formation of the dense, ion transport blocking layer in the top portion of the electrode during calendaring. In some designs, instead of (or in additional to) nanofibers one may use porous or ionically conductive (and thus permeable to electrolyte) particles of other shapes (e.g., spherical, elliptical, random shape, dendritic, planar, etc.). In some designs, at least some of such ceramic particles may be porous. In some designs, at least some of such ceramic nanofibers or particles may be electrically conductive or exhibit mixed (electronic and ionic) conductivity (in this case, a separator or a separator layer would still be needed to electrically separate anode in cathode). In some designs, at least some of such particles may comprise carbon (e.g., about 20-100 at. %). In some designs, at least some of such particles may not be ceramic, but may be based on soft materials (polymers), metals, semimetals, carbon (e.g., as carbon nanofibers or carbon nanotubes or graphene oxide or graphene, etc.). In some designs, such particles may be based on polymers or comprise significant amount of polymers (e.g., about 50-100 wt. %). In some designs, such polymer particles may be in the form of fibers, including (nano)fibers.

In some embodiments of the present disclosure, it may be advantageous for the electrode (e.g., before or after ALD coating) to exhibit sufficient thermal stability (e.g., lose less than about 5 wt. % of its mass when heated at the rate of 1° C./min to around 200° C. in inert environment or exposed to his temperature for about 30 min; in some designs—when heated at the rate of 1° C./min to around 300° C. in inert environment or exposed to his temperature for about 30 min).

In some embodiments of the present disclosure, it may be advantageous for the electrode to be patterned (perforated) with holes prior to ALD coating deposition. Such a procedure may reduce diffusion time for the ALD precursors and purge gas in/out of the electrodes. In some designs, such an electrode design may be particularly valuable for high (e.g., about 4-6 mAh/cm²) and even more so ultra-high loadings (e.g., about 6-1000 mAh/cm²; in some designs from about 6.0 to about 9.0 mAh/cm²; in some designs from about 9.0 to about 15.0 mAh/cm²; in some designs from about 15.0 to about 30.0 mAh/cm²; in some designs from about 30.0 to about 60.0 mAh/cm²; in some designs from about 60.0 to about 150.0 mAh/cm²; in some designs from about 150.0 to about 300 mAh/cm²; in some designs from about 300.0 to about 1000.0 mAh/cm²). In some designs, the average spacing between the centers of such holes may range from around 0.1 mm to around 10 mm. In some designs, the holes may propagate from around 50% to around 100% of the electrode thickness. In some designs, the holes may exhibit near-cylindrical or near-conical shape. In some designs, the average diameter (or thickness) of the holes may range from around 0.01 mm to around 0.5 mm. In some designs, the pattern of holes may be regular (e.g., hexagonal or cubical or rectangular, in some designs). In some designs, such holes may be induced (machined) mechanically. In other designs, such holes may be induced (machined) by using lasers.

In conventional ALD, the overall system may comprise a chamber, where a substrate is placed into, and where gas/vacuum delivery lines connected to such a chamber. The whole substrate in conventional ALD is exposed to the same steps or sub-steps. The individual cycles and individual steps (or individual sub-steps) within each ALD cycle are separated by time and not by space, in conventional ALD system. In conventional ALD, the substrate (e.g., porous electrode or porous separator, etc.) is static during each sub-step and/or during each step and/or during each cycle and/or during the whole multi-cycle deposition process. In conventional ALD, the gas lines (for introduction of precursors or neutral “purge” gases, such as N₂ or Ar or He, to name a few examples) and vacuum introduction lines are connected to the “ALD chamber” and are also static and do not move during the ALD multi-step, multi-cycle deposition process. In some embodiments of the present disclosure, the individual cycles, steps, and/or sub-steps may be separated by space. In other words, individual cycles, individual steps (or sub-steps) may take place in a different portion of the ALD deposition system or in a different portion of the substrate. Furthermore, in some embodiments of the present disclosure, the “ALD chamber” may comprise a separate “ALD head”, which may move relative to the substrate during the deposition process. In some designs, the substrate may be static and the “ALD head” may move during the deposition process. In other designs, the “ALD head” may be static and the substrate may move during the deposition process. In other designs, both the “ALD head” and “ALD substrate” may move during the deposition during the deposition process. In some designs, more than one head may be used in an ALD chamber. The ALD head may be designed to space-separate individual steps within an ALD cycle (for example, introduction of precursor 1 (step 1), purge (step 2), introduction of precursor 2 (step 3), purge (step 4) or, for example, purge (step 1) introduction of precursor 1 (step 2), purge (step 3), introduction of precursor 2 (step 4), purge (step 5) or, for example, introduction of precursor 1 (step 1), purge (step 2), introduction of precursor 2 (step 3), etc.) of the ALD process. In some designs, each step “area” within the head (e.g., the area of the head that is engaged in performing a particular set of steps or sub-steps) may comprise (or be used to perform) 1, 2, 3, 4, 5 or more individual sub-steps. In some designs, the number of individual sub-steps may differ for different step areas. In some designs, the ALD head may be designed to incorporate a single cycle. In other designs, the ALD head may be designed to incorporate multiple (e.g., about 1-100) space-separated cycles (e.g., to cover larger electrode area at a given time). In some designs, the ALD chamber (where both substrate and ALD head are placed) may be continuously purged. The overall design of such an ALD system may be compared to that of a printer or a plotter but is unique for the ALD (or CVD) system.

It will also be appreciated that while in some designs ALD may be preferable for the deposition on porous substrates (e.g., porous electrodes) in terms of very uniform and tightly controlled thickness of the deposited layer, in other designs CVD processes may be used instead of or in addition to ALD in order to increase deposition rates while providing sufficient coating uniformity. It will further be appreciated that while in some designs “ALD head” may be positioned on one side of the porous substrate (e.g., porous electrode), in other designs two ALD heads may be positioned on each side of the porous substrate.

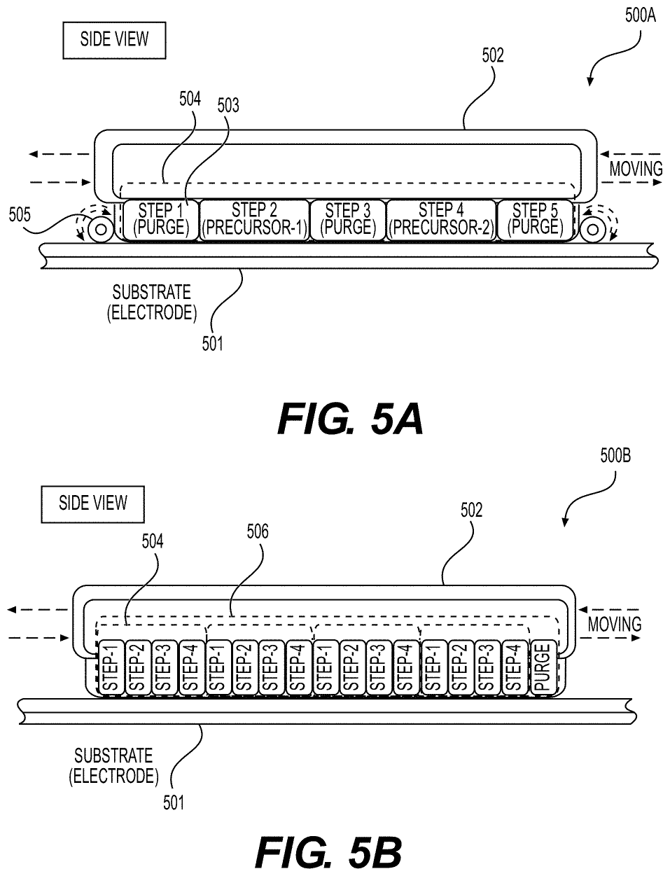

FIG. 5A shows an illustrating example of an “ALD printer” system 500A design implementation, where a substrate (e.g., porous electrode or porous separator, etc.) 501 is moving relatively to the “ALD head” 502 during the ALD deposition. In some designs, a porous substrate 501 may be static, while the ALD head 502 may be moving. In other designs, the substrate 501 may be moving, while the ALD head 502 may be static. In yet other designs, both the substrate 501 and the head 502 may be moving (e.g., at the same or at different time within the ALD deposition). In some designs, such a move may be discontinuous (e.g., move, stop, move, stop, etc.). In other designs, such a move may be continuous. The ALD head 502 may comprise multiple sections 503 that separate individual ALD steps geometrically. The totality of such step sections 503 completes the ALD cycle 504. In some designs, by moving the ALD head relative to the substrate, the same substrate areas become exposed to all the steps of the ALD cycle, thus ALD depositing a coating layer. In some designs, more than 1 gas line (nozzle) and more than 1 exhaust line (nozzle) may be included in each step section 503. In some designs, multiple nozzles may be arranged into nozzle arrays. In some designs, within each step section 503, arrays of gas nozzles with a flowing gas (e.g., an inert gas in case of a purge step or a precursor gas in case of a pulse step) may be geometrically separated from the arrays of exhaust (e.g., vacuum) nozzles, similarly as previously shown in FIGS. 3 and 4. Such arrays of gas nozzles and exhaust nozzles are not shown expressly in FIG. 5 for simplicity. In some designs, rollers 505 may be used to control the distance between the top of the substrate 501 and the bottom of the ALD head 502.

FIG. 5B shows another illustrating example of an “ALD printer” system 500B design implementation. The “ALD printer” system 500B is similar to the previously discussed system 500A, except that the ALD head 502 comprises multiple ALD cycle sections 504. The totality of the ALD cycle sections 504 form an ALD “shower head” deposition system 506. In some designs, the individual cycle sections 504 may have a strip (elongated) shape.

In some designs, the surface of the electrodes or electrode particles may be advantageously functionalized to increase uniformity and accelerate formation of the initial surface layer of the ALD. Indeed, the ALD deposition of metal oxides and other discussed coatings typically rely on the availability of oxygen at the surface to react with a precursor during the deposition step or sub-step (within a cycle). Deposition of metal oxides and other polar ceramic coatings on the (e.g., nonpolar or less polar) surfaces of many carbon additives, some polymer binders and even some active particles (e.g., particularly if carbon coated) may be challenging, particularly in cases where polar moieties (or surface dipoles) are absent on such surfaces. With reduced nucleation sites, the ALD coatings may not be fully continuous and free from undesirable defects (e.g., uncoated areas or pinholes). To reduce or overcome such a limitation, the surface of carbon additives, polymer binder and/or active particles may be treated to introduce more polar (e.g., oxygen-containing) functional groups at their surfaces. In case of carbon functionalization, many suitable techniques could be utilized, such as the use of aryl diazonium salts (e.g., where the aryl group contains a carboxylic acid), alcohol groups, carboxylic groups, or other polar functional group. In other process designs, such surfaces may be treated with oxygen plasma, ozone, or oxidizing acids.

In some designs, initial cycles of a different ALD chemistry (than the one being used to form the bulk of the coating) may be beneficially utilized. In some cases, such an initial layer of different chemistry (which may be called an “interlayer” between the interior porous electrode surface and the “bulk” ALD coating) may represent a much better adhesion layer to help the desired coating material better bond to the substrate. In some cases, such an initial layer of different chemistry may increase nucleation site density. In some cases, such an initial layer of different chemistry may increase wettability of the desired coating phase. In some cases (e.g., when small internal pores could preferentially be blocked by ALD), such an initial layer of different chemistry may block the entrance of smaller ALD precursor molecules from entering the small pores (and thus avoid depositing the bulk of the ALD coating within such pores).

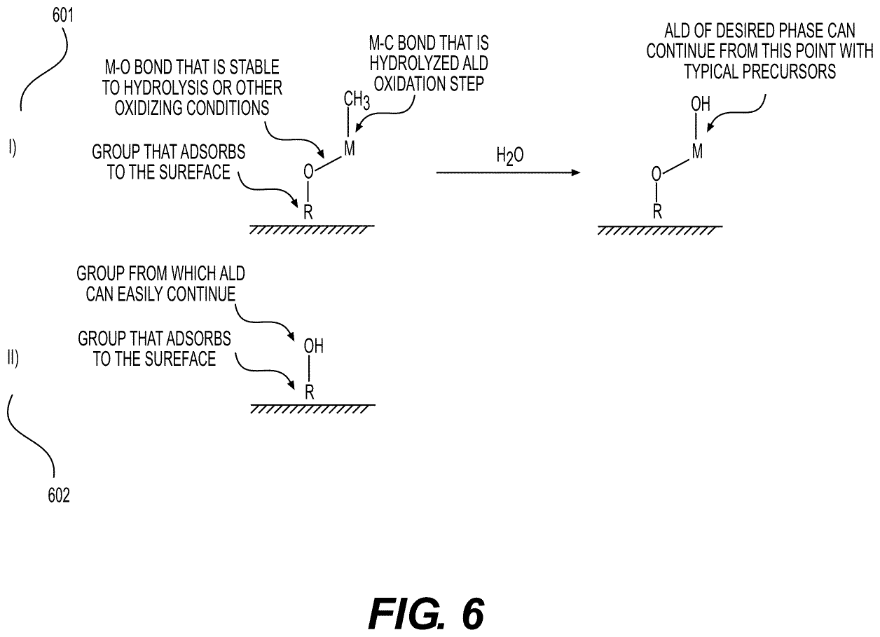

FIG. 6 illustrates example embodiments, where a precursor for an interlayer may include a nonpolar section that can readily physisorb to the nonpolar (e.g., carbon) surface, and a polar group that provides a site for another ALD precursor to chemisorb. In some designs, the respective interlayer sections may comprise organometallic (Scheme, Type I, 601) or organic (Scheme, Type II, 602) molecules. One illustrated example of Type II is naphthol, which has a polycyclic aromatic hydrocarbon moiety which may adsorb to the carbon, an —OH group from which ALD can start, and is sublimable at temperatures and pressures accessible by most ALD systems. In some designs, molecules with multiple —OH groups (and sufficiently low vapor pressure to be used in ALD) may be used to introduce more functionality early in the cycle. Rather than using an initial cycle with H₂O, which may add one —OH group where water adsorbs, in some designs molecules with multiple —OH may be used during the initial cycle (and/or on subsequent cycles), thus forming more reactive surface groups available for subsequent reactions. For example, glycerol (which contains three —OH groups) may be used in some designs. In some designs, if the glycerol reacts with the surface during a pulse (step), then two more reaction sites of glycerol remain available for the reaction with the metal precursor on the next cycle.

In some designs, it may be advantageous to use ALD to block (or seal) some small (e.g., about 0.3-10 nm) internal pores within the electrode particles. To accomplish this, it may be advantageous to deposit a pore-blocking layer on the outer surfaces of such particles. If such molecules deposit on the outer surface of the porous particles and block pore entrances, this may reduce or prevent subsequent smaller precursor molecules from diffusing into the small pores. Since very large molecules capable of sterically blocking some of the pore entrances may be less volatile, a right balance may need to be identified between selecting the larger and more effective (for pore blocking) molecules, yet sufficiently volatile to be delivered to the surface. In some designs, such molecules should not be too reactive to have excessive gas phase reactions and not be able to diffuse into all particles within the electrode (or bed of particles). In some designs, the blocking surface layer may be deposited by chemical vapor deposition (CVD) or physical vapor deposition (PVD).

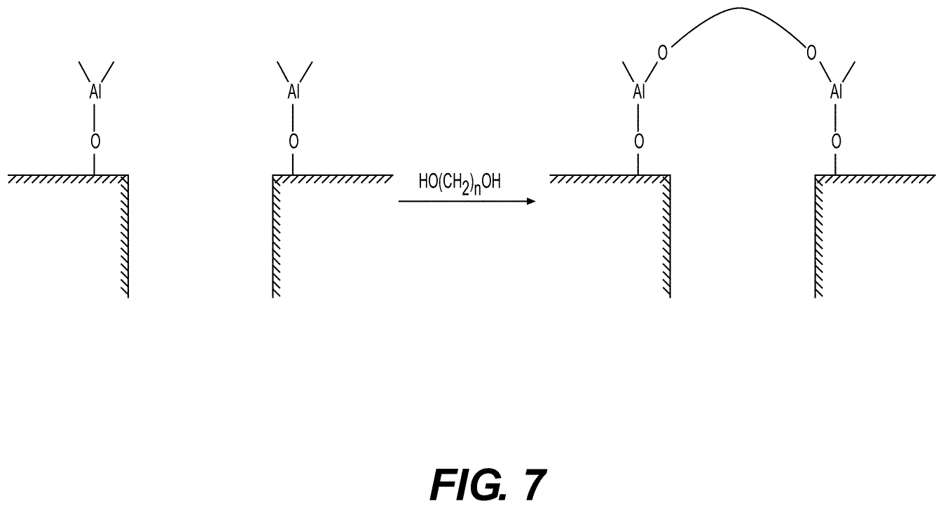

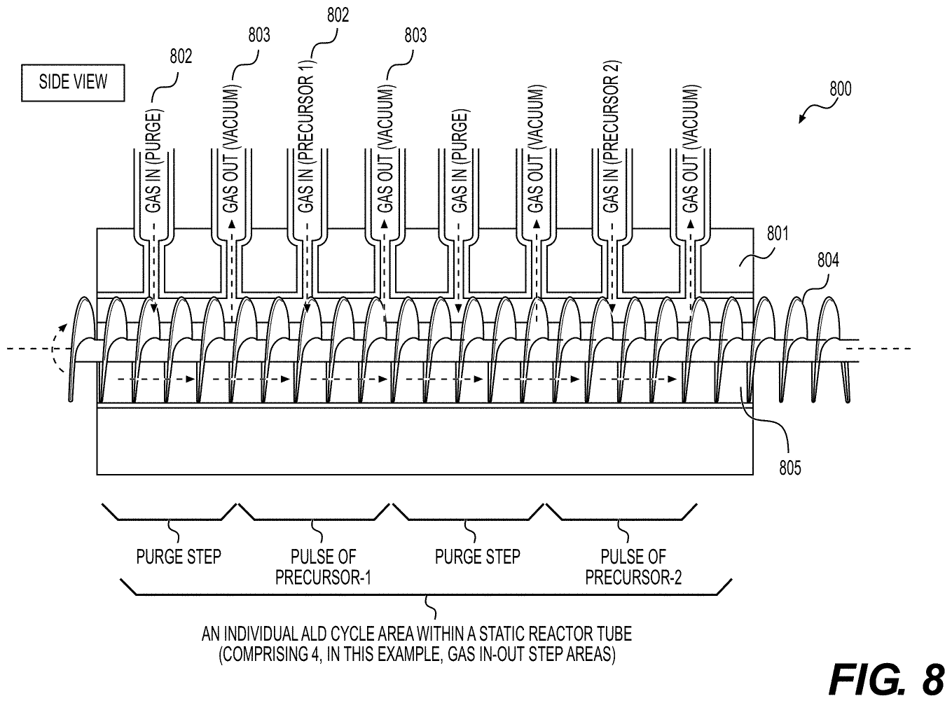

In some designs, adding polar molecules to the oxidizing pulse step (or replacing an oxidizing pulse step with such molecules) in the beginning of the ALD may be utilized to seal at least some of the small pores. FIG. 7 shows an example embodiment, where large molecules (and thus having a smaller mobility within small nanopores or sub-nano pores) may be used as a precursor for the initial ALD deposition to close bottleneck pores. While in this illustrative example, larger molecules with two or more —OH groups (e.g., such as HO(CH₂)ₙOH molecules) are shown, but other molecules with multiple —OH or other polar functional groups may similarly be utilized. Care should be taken in such an approach though because some of such molecules may react with all available surface sites in some applications, effectively ending an ALD-type growth process, since all reactive surface sites may get blocked from further deposition. In some designs, such molecules may be used together with water vapors to help close pores without completely blocking all functionality from further reaction.

In some designs, individual particles of active (e.g., anode or cathode) materials (or composite particles comprising active material(s)) may be advantageously coated with a functional surface layer instead of (or in addition to) the coating of porous electrodes. In some designs, it may be particularly advantageous for the powder surface coating to be highly uniform. Too thick of the coating may reduce charging or discharging rate or induce undesirable mechanical behavior of the particles (e.g., internal cracking or coating delamination during cycling) or increase resistance or increase fabrication costs, etc. Too thin of the coating may not provide sufficient protection or desired functionality. In some designs, a standard deviation of the particle-to-particle surface layer thickness may preferably not exceed the mean layer thickness value (in some designs, not exceed ½ of the mean value). In some designs, a standard deviation of the on-particle surface layer thickness may preferably not exceed the mean layer thickness value (in some designs, not exceed ½ of the mean value). In some designs, the coating thickness may range from around 0.3 nm to around 100 nm (in some designs, from around 0.3 nm to around 1 nm; in some designs, from around 1 nm to around 2 nm; in some designs, from around 2 nm to around 4 nm; in some designs, from around 4 nm to around 10 nm; in some designs, from around 10 nm to around 20 nm; in some designs, from around 20 nm to around 100 nm).

In some designs, individual particles of active (e.g., anode or cathode) materials (or composite particles comprising active material(s)) may be advantageously ALD coated with a functional surface layer instead of (or in addition to) the ALD coating of porous electrodes. Traditional ALD on powders utilizes either rotating tube designs (to agitate powders and accelerate the gas diffusion to/from the individual particle surfaces within each step of the ALD process) or simple packed bed designs (the slower of the two due to the need of the gasses to propagate through the bed thickness). Both of such approaches suffer from high cost and very slow deposition rates. Some embodiments of the present disclosure offer methods and ALD tool designs to reduce or overcome such limitations.

In some embodiments of the present disclosure, the individual powder ALD cycles, steps, and/or sub-steps may be separated by space. In other words, each cycle, each step, and/or each sub-step may take place in a different portion of the ALD deposition system. Furthermore, in some embodiments of the present disclosure, the powder (dense or porous particles, including composite particles) may be moving during whole multi-cycle deposition process, and/or during each cycle, and/or during each step, and/or during each sub-step. In some designs, such a move may be discontinuous (e.g., move, stop, move, stop, etc.). In other designs, such a move may be continuous. Furthermore, in some embodiments of the present disclosure when steps or sub-steps are separated geometrically, the respective steps or sub-steps may take place at the same time (in some designs, continuously) on different (geometrically separated) parts of the powder. In some embodiments of the present disclosure, the ALD deposition on powders may be conducted continuously or quasi-continuously (e.g., with stops). As a result of the described embodiments, significantly faster ALD deposition rates and more uniform deposition on powders may be attained.

FIG. 8 shows an illustrating example of a part of the continuous powder ALD system 800, where the powder (e.g., anode or cathode particles) are exposed to a full ALD cycle as it moves through the tube reactor 801. In some designs, the individual anode or cathode particles may be assembled into temporary granules (e.g., from around 0.1 mm to about 20 mm in diameter; in some designs, from around 0.1 to around 0.5 mm; in other designs, from around 0.5 to around 5 mm; in yet other designs, from around 5 to around 10 mm; in yet other designs, from around 10 to around 20 mm) for ALD deposition. in some designs, such granules may greatly assist in the faster formation of more uniform coatings and may be broken back into individual (or near-individual) particles prior to using for battery electrode formulations. In some designs, such granules may be elongated (e.g., have average aspect ratio in the range from around 1.1 to around 20). In FIG. 8, only a section of a reactor 801 is shown. In some designs, the total number of individual ALD cycle areas may typically range from around 5 to around 1000 (which may be optimized, depending on the desired thickness of the coating, temperature and the chemistry of the deposition layer and precursors used). In some designs, from around 5 to around 50 cycles; in other designs from around 50 to around 250 cycles; in yet other designs from around 250 to around 1000 cycles may be used. In some designs, the total length of such a continuous reactor may range from around 1 m to around 100 m (depending on the diameter of the tubular reactor, ALD chemistry, desired thickness, and other parameters). In some designs, longer reactors may also be utilized, but may become too expensive for many applications. In some designs, shorter reactors may also be used, but may offer too limited deposition thickness. The ALD system 800 comprises the reactor 801 (tubular in this example, although other reactor geometries may be suitable in some designs) connected with multiple gas inlets 802 (higher pressure) and outlets 803 (lower pressure or vacuum). In some designs, the total number of gas inlets and outlets may range from around 40 to around 8,000. In some designs, the gas inlets may deliver purge gases (e.g., commonly inert N₂, Ar, He, etc.) and precursor gases. In some designs, the gas inlets 802 are separated from each other by gas outlets 803. In some designs, the gas inlets 802 and outlets (exhausts) 803 may be positioned on the top of the reactor tube, although other arrangements (e.g., at an angle or even on the bottom, if a filter is used to prevent particle from clogging the inlets or outlets) may also be successfully utilized. In some designs, the gas inlets may comprise the repeated sequence of: (i) purge gas inlet, (ii) precursor-1 gas inlet; (iii) purge gas inlet; (iv) precursor-2 gas inlet. In some designs, 1, 2, 3 or more inlets for the same gas may be used within a single cycle area (e.g., (i) purge gas inlet, (ii) another purge gas inlet; (iii) precursor-1 gas inlet; (iv) another precursor-1 gas inlet; (v) purge gas inlet, (vi) another purge gas inlet; (vii) precursor-2 gas inlet; (viii) another precursor-3 gas inlet—in case of two inlets of the same gas in series). In some designs, the reactor tube 801 may be static and the powder 805 may be moved through the tube (e.g., left to right, as shown in this figure or in the opposite direction) using a powder mover (e.g., in this case, a rotating auger (screw) 804). The dimensions of the auger 804 may be selected to closely match the inner tube diameter to minimize the portion of the inlet gas from leaving to the exhaust outlet without passing though the powders to be coated. In some designs, it may be preferable that such dimensions are selected to ensure that about 50-100% of the incoming gas passes through the particles before leaving to the exhaust. In some designs, the particles may be assembled into large granules (e.g., 0.5-20 mm in diameter). In some designs, the large granules may be assembled into multi-granule chunks (e.g., 5-100 mm in diameter). The agitation of particles (or granules or chunks) as they move through the reactor helps to accelerate the gas access to the particle surfaces and additionally insures superior coating uniformity. In some designs, the reactor tube 801 may be heated (e.g., to temperature in the range from around 50 to around 500° C.). In some designs, 2, 3 or more reactor tubes may be housed within a single heater of the reactor 801. In some designs, the temperature of the majority of individual step areas may be the same or similar (within ±5° C.). In other designs, average temperature of the individual step areas may vary by more than 5° C. In some designs, nearly all cycle areas within the reactor 801 may be exposed to approximately the same heater temperature (within about 5° C.). In other designs, the average heater temperature of cycles may differ (e.g., be lower for initial cycles and higher for later cycles or the opposite). In some designs, the system may be used for depositing a single ALD layer. In other designs, the system may be used to deposit 2, 3 or more distinct layers. In this case the precursors for different cycle areas may vary. In some designs, the gas inlets may continuously deliver gases during the deposition and the gas outlets may continuously such exhaust gases during the deposition. In other designs, the gas delivery may occasionally be stopped. In some designs, precursor delivery lines may be occasionally cleaned with a purge gas. In some designs, the flow of gases may be reversed during the depositions.

In some embodiments of the present disclosure, the powder (e.g., dense or porous particles, including composite particles) may not move significantly during the whole multi-cycle deposition process, and/or during each cycle, and/or during each step, and/or during each sub-step. Yet, in some designs, the pressure gradient between the inlet gas lines (maintained at a higher pressure) and the outlet exhaust lines (maintained at a lower pressure) may force the gas diffusion through the powder beds. In some designs, vibrations may be used to agitate the powder (or granules or chunks) during the ALD deposition. In some designs, arrays of porous inlet and outlet gas lines may be inserted into the bulk of the reactor volume filled with a powder (or granules or chunks) to reduce or minimize diffusion distance through the powder across the pressure gradient. In some designs, the pore sizes in such gas lines should be sufficiently small to prevent (or at least reduce) the power (or granules or chunks) from getting into these lines. In some designs, the distance between the nearest gas lines may range from around 1 mm to around 20 cm (in some designs, from around 1 mm to around 1 cm; in other designs, from around 1 cm to around 2 cm; in other designs, from around 2 cm to around 10 cm; in yet other designs from around 10 cm to around 20 cm). In some designs, the same gas lines (at different times) may be used for introduction of the input gases (e.g., inert gases during purge or precursor gases/vapors during deposition) and for the evacuation of the exhaust. In some designs, the gas lines may be utilized to heat the powders to the desired temperature (e.g., via contact heating). The gas lines, turn, may be heated for example, resistively (by passing the current through them) in some designs.

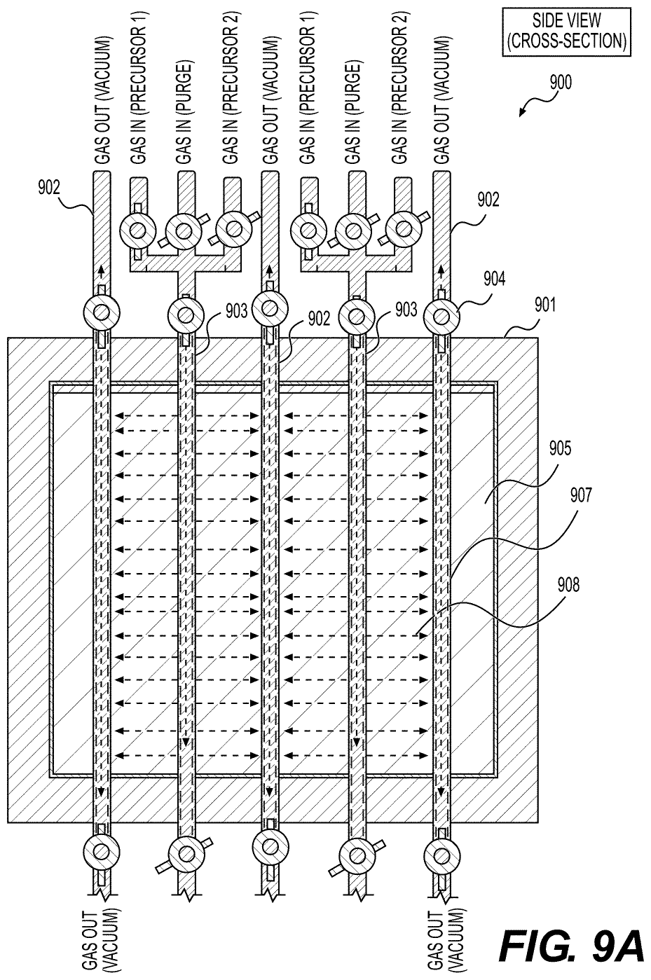

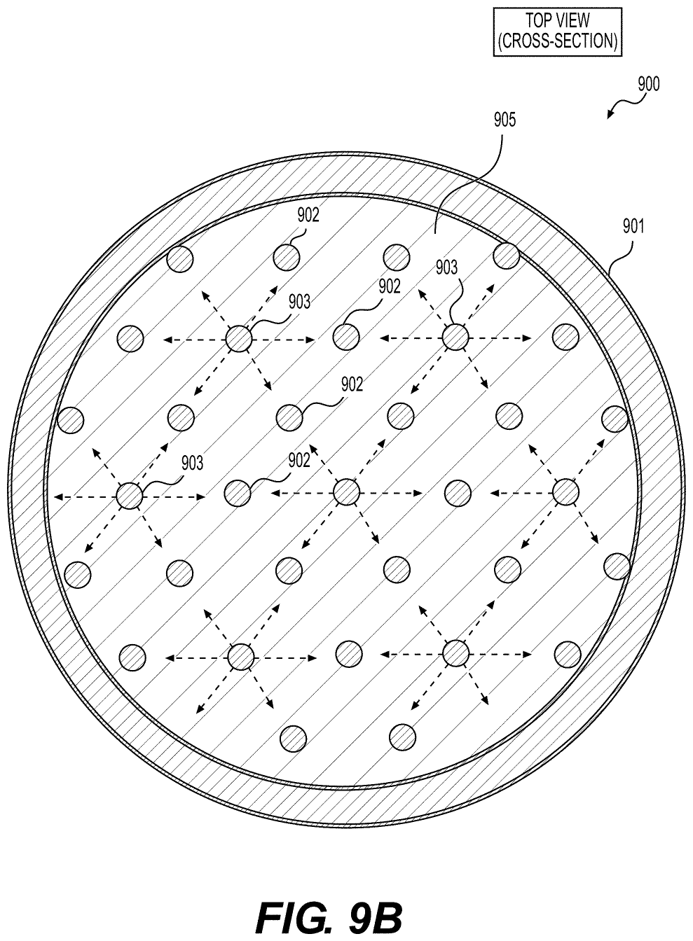

FIG. 9A shows an illustrating example of a side cross-section of a powder bed ALD system 900, where porous tubes 902 and 903 (each connected to either exhaust (vacuum) outlet lines 907 or lines for the inlet gases 908 (e.g., purge or precursors) or both through one or multiple valves 904) are inserted into the reactor chamber 901 before it is filled with powder 905 (e.g., anode or cathode particles). Such an arrangement may significantly reduce the diffusion distance from the gas delivery system to the bulk of the powder and from the bulk of the powder to the exhaust system. In some designs, some of the tubes (e.g., 902) act as output (exhaust) lines and other tubes (e.g., 903) act as input lines. In some designs, the gas (inert or one of the precursors) may pass from the (e.g., pressurized) input tubes to the output (e.g., reduced pressure) tubes through the porous pore walls and through the powder beds between the tubes to accelerate the gas diffusion by the application of the pressure gradient. In some designs, different tubes may be used as input and output at different ALD cycles to ensure more homogeneous coatings. FIG. 9B illustrates a top cross-section of the powder bed ALD system 900 (in this example with the reactor chamber 901 being cylindrical) and porous tubes 902 and 903 inserted into the powder 905. The gas may pass from the input tubes 909 to the output (exhaust) tubes 903 though the powder bed 905. At different ALD cycles, different tubes may serve as input and output to increase or maximize ALD coating uniformity on the powder surfaces.

In some embodiments of the present disclosure, the electrode anode or cathode powder (e.g., dense or porous particles, including composite particles) may be coated by using a physical vapor deposition (PVD) technique. In some designs, the PVD-deposited surface layer may form a favorable interface between the electrode surface and electrolyte. In some designs (e.g., when porous composite particles are used, where pores may provide space for expansion of active material during ion absorption (e.g., lithiation)), PVD may close internal pores. Compared to CVD and ALD, PVD in some designs may close internal pores with a smaller fraction of deposited material, thus increasing or maximizing the internal (closed) pore volume for the expansion of active material. In some designs, PVD is also a low temperature process, thus reducing or minimizing possible thermal damages to various powder materials. In addition, in some designs, PVD may offer a relatively high yield and (commonly) no liquid or gaseous exhausts (wastes). In some designs, a broad range of various materials may be deposited by PVD by selecting appropriate (e.g., magnetron) targets and deposition conditions. In some designs, to ensure powder coatings on all sides and covering a majority (e.g., about 50% or more) outer surface area of the majority (e.g., about 50 wt. % or more) of the particles, the powder may be agitated (mixed) during PVD deposition.

In some designs, porous composite particles may comprise Si. In some designs, by closing some or all of the internal pores of such particles, the PVD layer may form an electrolyte solvent-impermeable barrier (shell) on the outer surface of the anode material particles to reduce or prevent electrolyte interaction with Si, which in turn may decrease irreversible Li losses during cell cycling.

In some designs, the average PVD coating thickness may range from around 0.3 nm to around 100 nm (in some designs, from around 0.3 nm to around 2 nm; in some designs, from around 2 nm to around 10 nm; in some designs, from around 10 nm to around 20 nm; in some designs, from around 20 nm to around 100 nm).

In some designs, the PVD layer may be electrically conductive and comprise about 50-100 at. % conductive (e.g., mostly sp²-bonded) carbon or other electrically conductive material.

In some embodiments of the present disclosure, the electrode anode or cathode powder (e.g., dense or porous particles, including composite particles) may be coated by a thin (e.g., about 0.3-100 nm; in some designs from about 0.3 nm to about 1 nm; in some designs, from around 1 nm to around 2 nm; in some designs, from around 2 nm to around 4 nm; in some designs, from around 4 nm to around 10 nm; in some designs from about 10 nm to about 20 nm; in some designs from about 20 nm to about 100 nm) layer (or multiple layers) comprising ionically conductive (e.g., Li-ion conductive) polymer(s) (e.g., about 10-100 wt. % of the total layer composition). In some designs, the conductivity for Li⁺ ions in such a polymer may range from about 10⁻⁹ S/cm to about 10⁻¹ S/cm at room temperature (in some designs, from about 10⁻⁹ S/cm to about 10⁻⁷ S/cm; in some designs, from about 10⁻⁷ S/cm to about 10⁻⁵ S/cm; in some designs, from about 10⁻⁵ S/cm to about 10⁻³ S/cm; in some designs, from about 10⁻³ S/cm to about 10⁻² S/cm; in some designs, from about 10⁻² S/cm to about 10⁻¹ S/cm). In some designs, the ionically conductive polymer layer(s) may be single-ion conductors. In other designs, the ionically conductive polymer layer(s) may be dual-ion conductors (e.g., comprise a dissolved Li-ion salt). In some designs, the molar ratio of the salt to the monomer unit may exceed about 0.01 (in some designs, exceed about 0.05). In some designs, a high Li transference number (T+) of the ionically conductive polymer may exceed about 0.1 (in some designs, exceed about 0.3; in some designs exceed about 0.5; in some designs exceed about 0.7; in some designs exceed about 0.9). In some designs, a polymer layer may exhibit a low glass transition temperature (Tg) (in some designs, below room temperature; in some designs, below minus (−) about 25° C. In some designs, the polymer electrolyte layer may exhibit stability against decomposition (or, at least form a passivating interphase) in contact with the electrode material during battery cycling. In some designs, a polymer electrolyte layer may exhibit a low degree of crystallinity (in some designs, below about 30% at operating temperatures; in some designs below about 10% at room temperature). In some designs, a polymer layer may exhibit sufficient mechanical stability, thermal stability and adhesion to the particles to avoid cracking or delamination during electrode slurry mixing, coating and electrode calendaring (densification).

In some designs, a polymer electrolyte layer may comprise one or more polymer. In some designs, a polymer electrolyte layer may comprise one or more Li salt(s). In some designs, a polymer electrolyte layer may comprise one or more inorganic component (e.g., a filler in the form of inorganic nanoparticles or clusters). In some designs, a polymer electrolyte layer may comprise one or more small molecule plasticizers or anion trap(s) or conductivity enhancer(s). In some examples, it may be beneficial to decrease the Tg of the polymer electrolyte system or decrease the crystallinity of the polymer electrolyte to increase the Li+ conductivity. Suitable ways to do so include but are not limited to copolymerization a polymer of lower Tg or lower crystallinity content such as some low Tg polycarbonates or polysiloxanes or rubbers, adding a small amount of plasticizer such as phthalates, sebacates, adipates, terephthalates, dibenzoates, and other specialty blends or high boiling point solvents that may be remaining from the processing of the films or added on purpose. In some designs, the polymer electrolyte layer might be a physical blend of several components. In some other designs, two or more of these components may be covalently attached. In some designs, polymer and inorganic components may be covalently attached or chemically bonded. In some other designs, the polymer electrolyte system might be a physical blend of covalently and non-covalently attached components. In some examples, it may be beneficial for the polymer-comprising layer to comprise a polymer or a copolymer or a polymer network or any mixture thereof that can self-assemble and create preferential pathways for Li+ ions while maintaining or enhancing some properties of the polymer electrolyte system. Suitable examples of such systems include but are not limited to block copolymers that can self-assemble into cylinders, lamellae, gyroid or any other suitable geometry; a polymer that exhibits a helical conformation in the bulk and may trap salt-rich regions inside the helixes or between helixes while maintaining mechanical and thermal stability; a liquid crystal polymer or any other suitable means.

In some designs, polymer components of the polymer-comprising layer(s) may include, but are not limited to: O-containing polymers such as polyethers (such as poly(ethylene oxide) (PEO), poly(propylene oxide) (PPO), poly(phenylene oxide)), polyesters (such as poly(ε-caprolactone), poly(butyrolactone), polyesters from malonate, succinate, sebacate, adipate derivatives such as poly(ethylene malonate), poly(ethylene succinate), poly(ethylene sebacate), poly(1,4-butylene adipate)), polycarbonates (such as poly(trimethylene carbonate), poly(ethylene carbonate)), and their derivatives, poly(meth)acrylates such as poly(methacrylate), poly(methyl methacrylate), poly(n-butyl acrylate), poly(t-butyl methacrylate), poly(n-butyl methacrylate), poly(acrylic acid) and poly(methacrylic acid) and their derivatives, poly(meth)acrylates exhibiting pendant oligo(ethylene glycol) or cyclic and non-cyclic esters or cyclic and non-cyclic carbonate groups such as poly(di(ethylene glycol)methyl ether acrylate), poly(di(ethylene glycol)methyl ether methacrylate), poly(oligo(ethyleneglycol) methyl ether acrylate), poly(oligo(ethyleneglycol) methyl ether methacrylate) and their derivatives; N-containing polymers such as polyimides, polyacrylamides and polynitriles and their derivatives (such as poly(acrylonitrile) (PAN) and poly(methacrylonitrile) (PMAN)), polyamides, polyurethanes and polyureas; H-bonding polymers such as poly(alcohols) (such as poly(vinyl alcohol) (PVA)) and poly(amines) (such as poly(ethyleneimine)) and their derivatives; poly(siloxanes) or poly(carboxysilanes) and their derivatives.

In some designs, polymer components of the polymer-comprising layer(s) may include, but are not limited to: poly(acrylics) and poly(methacrylics) (such as poly(methyl methacrylate), poly(ethyl acrylate), poly(n-butyl acrylate), poly(t-butyl acrylate), poly(n-butyl methacrylate), poly(t-butyl methacrylate), poly(hexyl acrylate), poly(hexyl methacrylate), poly(cyclohexyl acrylate), poly(cyclohexyl methacrylate), poly(benzyl acrylate), poly(benzyl methacrylate), poly(perfluorobenzyl acrylate), poly(perfluorobenzyl methacrylate), poly((1H,1H,2H,2H-perfluorodecyl)acrylate), poly((1H,1H,2H,2H-perfluorodecyl)methacrylate), poly(methacrylic acid), poly(acrylic acid), poly(2-hydroxyethyl acrylate), poly(2-hydroxyethyl methacrylate), poly(glycidyl acrylate), poly(glycidyl methacrylate), poly(ethylene glycol acrylate), poly(ethylene glycol methacrylate), poly(acrylamido-) and poly(methacrylamido-) (such as poly(N-isopropylacrylamide),), poly(acrylonitrile), poly(1-vinyl-2-pyrrolidone), styrenics (such as poly(styrene), poly(dimethylaminomethyl styrene)), or any of the electron-conducting or Li+-conducting polymers described in the following embodiments or any mixture thereof. In some examples, multifunctional monomers such as ethylene glycol dimethacrylate, ethylene glycol diacrylate, divinylbenzene, 1,3,5-trivinyl,trimethyl trisiloxane, N,N′-methylenebisacrylamide, may be used in combination with the linear polymers describe in this embodiment or by themselves to produce a crosslinked polymeric shell material. In some examples, resin forming monomers or prepolymers may be used by themselves or in combination with the polymers described in this embodiment. Suitable resins may include but are not limited to: urea-formaldehyde resins, maleimide resins, epoxy resins, polybenzoxazine resins, polyurethane resins, phenol resins or any combination thereof.

In some designs, some polymer-comprising layers may comprise a gradient, statistical, alternating, graft or block copolymer. For example, in some designs it may be beneficial to copolymerize a synthon which has a low Tg and good Li+ conductivity with a synthon which has higher mechanical stability or to copolymerize a synthon which has high Tg and high Li+ conductivity with a synthon which has low Tg to finely tune the properties of the polymer electrolyte system.

In some designs, the polymer might have a linear, branched, star or dendritic architecture.

In some designs, polymers or copolymers in the polymer or polymer-comprising layer may be prepared by polycondensation, polyaddition, ring opening polymerization of cyclic monomers, copolymerization of epoxides with CO₂, anionic polymerization, ring-opening metathesis polymerization (ROMP) or radical initiated polymerization such as free radical polymerization, atomic transfer radical polymerization (ATRP), reversible addition-fragmentation chain transfer (RAFT), nitroxide-mediated radical polymerization (NMP) and other suitable means. In some designs, the most suitable polymerization technique may be defined by the chemical nature of the polymer or copolymer.

In some designs, one or more polymers in the polymer or polymer-comprising layer might be chemically or physically crosslinked so as to form a polymer network or a mixture of interpenetrating polymer networks or a polymer network swollen with polymer or any other suitable combination containing a polymer network. Suitable chemistries to do so include but are not limited to: ring opening reaction such as amines or alcohols on epoxides, reaction of aldehydes or ketones with alcohols or amines, nucleophilic additions such as amines on maleimide derivatives, amidation, esterification or transesterification or etherification.

In some designs, Li salts in the polymer electrolyte may comprise salts with weakly coordinating anions, such as lithium trifluoromathane sulfonate (LiCF₃SO₃), lithium tetrafluoroborate (LiBF₄), lithium bis(pentafluoroethanesulfonyl)Imide (LiBETI), lithium bis(trifluoromethanesulfonyl)imide (LiTFSI), lithium bis(fluorosulfonyl)imide (LiFSI), lithium hexafluorophosphate (LiPF₆), lithium perchlorate (LiClO₄), LiSbF₆, lithium iodide (LiI), lithium bis(oxalatoborate) (LiBOB), their various derivatives, among others (including those previously mentioned). In some designs, an organic anion of the Li salt may be immobilized by covalent attachment to a polymer or covalent attachment or coordination to an inorganic filler or an anion trap. Suitable examples of anion traps include but are not limited to boron derivatives such as boron trifluoride (BF₃) or tris(pentafluorophenyl)borane (B(C₆F₅)₃).

In some designs, polymer electrolyte may comprise polyanions. Suitable examples of such polyanions may include but are not limited to styrenics or (meth)acrylatics, polyphosphazene, polysiloxanes, polycarboxysilanes, PEI, PEO derivatives with pendant carboxylate, sulfonate (such as benzenesulfonate, trifluorobutanesulfonate, perfluoroether sulfonate) or sulfonimide and sulfamide (such as trifluoromethanesulfamide, bis(perfluoroalkanesulfonyl)imide, (trifluoromethane(S-trifluoromethanesulfonylimino)-sulfonyl)imide ((—SO₂N(−)SO—(═NSO₂CF₃)CF₃), or borate or phosphate. In some examples, the anions may be pendant groups, in some other examples, the anions may be only decorating the chain ends of the polymer. In some examples, the anion and the main polymer chain may be separated by a spacer. In some examples, the anionic polymer or copolymer may be prepared from a charged monomer by anionic or radical polymerization and in some other examples, the anionic polymer or copolymer may be prepared by post-polymerization modification of a charged or uncharged polymer or copolymer. In some examples, the anions may be part of the main chain of the polymer instead of being pendant groups.

In some designs, the inorganic component of the polymer-comprising layer may include one of the following materials: alumina (Al₂O₃), silica (SiO₂), magnesium oxide (MgO), titania (TiO₂, rutile or anatase), LiAlO₂, zirconium dioxide (ZrO₂), zinc oxide (e.g., ZnO), hafnium oxide, vanadium oxide, niobium oxide, tantalum oxide, rare earth oxides (such as lanthanum oxide, yttrium oxide, cerium oxide, etc.), manganese oxide, molybdenum oxide, iron oxide, cobalt oxide, nickel oxide, copper oxide, tin oxide, germanium oxide, lithium oxide, lithium phosphate, iron phosphate, aluminum phosphate, titanium phosphate, zinc phosphate, zirconium phosphate, phosphate of rare earth metals, their various mixtures and combinations, a clay or kaolin. In some designs, the surface of the inorganic fillers may be functionalized with one or multiple polymers or one or multiple anionic species or any combinations thereof such as lithium [(4-methylphenyl)-sulfonyl(trifluoromethane)sulfonyl]imide or poly(ethylene glycol) chains or a combination of both.

In some designs, it may be beneficial for the polymer or polymer-comprising layer(s) to exhibit enhanced electronic conductivity (e.g., electronic conductivity >about 0.001 S/cm; in some designs >about 0.05 S/cm). To achieve such a design goal, in some designs, the polymer layer may chemically or physically incorporate one or more electron-conducting polymer or one or more electron-conducting additive or any mixture thereof. In some of these examples, one or more electron-conducting polymer may be n-doped or p-doped. Suitable examples of such polymers include but are not limited to: poly(3,4-ethylenedioxythiophene) (PEDOT), poly(thiophene), poly((3-alkyl)thiophene), poly ((3-hexyl)thiophene) (P3HT), poly(acetylene), poly(paraphenylene), poly(paraphenylene vinylene), poly((2,5 dialkoxy)paraphenylene vinylene), poly(heptadiyne), poly(paraphenylene sulphide), poly(aniline) (PANI) or poly(pyrrole) (PPy). Suitable examples of electron-conducting additives include but are not limited to: metallic nanowires, multi-walled carbon nanotubes (MWCNTs), single-walled carbon nanotubes (SWCNTs). carbon nanofibers, or various other carbon powders such as carbon black, carbon onions, graphite, graphene and others or various mixtures thereof.

Suitable means to deposit the polymeric layer (shell) material may include, but are not limited to: spray-drying, hydrothermal treatment, solvethermal treatment, various dispersed media polymerization methods such as precipitation polymerization or emulsion polymerization, electrospray, microfluidics, dry blending, self-assembly of one or more preformed polymer at the surface of the particle favored by chemical interactions or initiated chemical vapor deposition (iCVD).

In some designs, it may be advantageous or highly desirable to deposit polymer-comprising shells around porous particles with open, interconnected pores without filling significant amount of the pore volume (e.g., without filling more than 50 vol. % of the initial pores; in some designs without filling more than 20 vol. % of the initial pores; in some designs without filling more than 10 vol. % of the initial pores). The remaining pores may be used, for example, for expansion of active material during lithiation (or, more generally, ion insertion). Conversion-type (including alloying-type) active materials exhibit particularly large volume changes and may thus significantly benefit from the remaining pores to accommodate volume expansion during lithiation in some designs. Examples of suitable means to achieve the deposition of a polymeric shell material on the outer surface of the porous particles (containing the active/Li-storing materials/ingredients) without clogging some of the pores may include but are not limited to: using one or more polymers exhibiting a gyration radius or one or more polymers that self-assembled into objects bigger than the remaining pores of the particle containing the active ingredient; controlling the amount of monomer or growing chains or initiator in the remaining pores of particle containing the active ingredient while using a dispersing media by choosing appropriate ratio of monomer/initiator/catalyst/surfactant, reaction temperature and method of feeding the monomers, initiators, catalysts or any other additive; controlling the flow and delivery method of initiator, radicals and monomer vapors, the pressure, the temperature of the array of resistively heated filament wires if used, the rate of diffusion and adsorption of primary radicals and of monomers from the vapor phase onto the surface of the particle containing the active ingredient and the temperature of the chambers if using an initiated chemical vapor deposition method; using a monomer which experiences side reactions so that the concentration of active chains decreases overtime; impregnating the pores with a molecule that would quench the polymerization or any combination thereof.

In some designs, one or more pre-polymers with reactive moieties and a molar mass between around 200 g/mol and around 2,000,000 g/mol, may be deposited as part of the polymer-comprising layer (shell) material on the surface of the electrode particles. In some designs, such reactive moieties may be used at a later stage (e.g., after an initial shell is formed while the particle(s) are arranged as a powder, after electrode casting, etc.), in combination with one or more other molecules, to either install some other chemical functionalities at the surface of the particle containing the active ingredient or to increase the crosslinking density of the shell. In some designs, intermolecular and/or intramolecular crosslinking reactions involving one or more prepolymer may be used to increase the crosslinking density of the polymeric shell material. Suitable means to deposit one or more prepolymer may include, but are not limited to: spray-drying, solvothermal treatment, hydrothermal treatment, various dispersed media polymerization such as precipitation polymerization or emulsion polymerization, dry blending or self-assembly of one or more preformed polymer at the surface of the particle favored by chemical interactions. Suitable means to induce the reaction of the reactive moieties may include but are not limited to: chemical triggers such as the addition of an acid or a base or an oxidizer or a reducer or a radical and/or physical triggers such as temperature or exposure to UV light or a combination thereof such as the release of radicals triggered by temperature or the release of radicals, bases or acids triggered by UV-light. In some process designs, the reaction of the reactive moieties may be triggered before the electrode is coated, for instance, using a solvent as a dispersing media or in an agitated or fluidized bed while in some other examples, the reaction of the reactive moieties is triggered after the electrode has been coated. In some designs, the polymeric shell material may be deposited, cured, or modified using a hydrothermal or a solvothermal process. In some designs, the polymeric shell material may be deposited, cured, or modified or any combination thereof, using a polymeric or molecular stabilizer or surfactant. In some designs, the stabilizer or surfactant may be chemically incorporated in the polymer shell material.

In some designs, it may be beneficial for the polymers or mixture of polymers used in the polymer-comprising shell material deposited on the surface of the individual electrode particles to exhibit a Tg sufficiently low (e.g., below around 100° C.; in some designs below around 80° C.; in some designs below around 50° C.; in some designs below around 20° C.) so that after the electrode coating has been prepared, the electrode may be heated and/or calendared above that Tg (e.g., by hot pressing) to allow for the re-localization of the polymer shell material (e.g., in some designs, squeezed out from between neighboring particles to enhanced their electrical connection, if needed; in other designs, to re-distribute to concentrate more to the areas near particle's contact to enhance their bonding; in other designs, to relieve some of the built-in mechanical stresses, etc.). In some designs, the packing density of the electrode may be improved and the distance between the particles containing the active ingredient and/or the conductive additive may be optimized.

In some designs, conductive carbon shell may be deposited on the surface of the individual electrode particles instead of or in addition to the polymer coating. In some designs, CVD, hydrothermal synthesis, solvothermal synthesis, polymer shell carbonization, electrophoretic deposition, layer-by-layer deposition, and other suitable methods may be used to deposit a conductive carbon shell layer.

In some designs, a polymeric shell material may be coated on the electrode coating after drying the electrode. In some designs, it may be beneficial to heat and/or calendar the polymeric shell coating to allow for the polymer shell material coated at the surface of the electrode coating to impregnate the electrode coating deeper.

In some designs, depositing suitable surface coatings (layers or shells) around the individual electrode particles by suitable means may be advantageously used in combination with the coating the suitable surface layer(s) on the internal surface of the dried electrodes of suitable composition by suitable means. In some designs, the surface coated electrodes or the surface coated electrode particles within the electrode may be used in combination with solid electrolytes. In some designs, such solid electrolytes may comprise polymer electrolytes. In some designs, the polymer electrolytes may be selected from the same group as those that may be advantageously used on the electrode particle surfaces and previously described. In some designs, the polymer electrolyte may exhibit sufficiently low Tg (e.g., below around 100° C.; in some designs below around 80° C.; in some designs below around 50° C.; in some designs below around 20° C.; in some designs below around 0° C.; in some designs below around minus (−) 20° C.; in some designs below around minus (−) 30° C.) to ensure penetration into the pores of the porous cathode and anode electrodes. In some designs, the polymer electrolyte may be polymerized after the liquid prepolymer (polymer precursors) are infiltrated into the electrodes (or electrode/separator stack or jelly roll). In some designs, such electrodes may be advantageously pre-coated by ALD or CVD surface layer(s) of suitable composition, as previously described.

Some aspects of this disclosure may also be applicable to electrodes with medium capacity loadings (e.g., in the range from around 2 to around 4 mAh/cm²).

In some designs, high capacity, high energy batteries (e.g., cells with energy density in excess of around 10 watt-hours (Wh); preferably in excess of about 15 Wh; in some designs, in excess of about 30 Wh; in some designs, in excess of about 100 Wh; in some designs, in excess of about 200 Wh) may particularly benefit from various aspects of this disclosure because such batteries are typically more sensitive to side reactions between the electrode and electrolyte and may suffer particularly strongly from the above-discussed limitations of certain conventional methodologies.

In some designs, high-energy density Li-ion batteries (e.g., cells with energy density in excess of about 600 Wh/L; in some designs in excess of about 700 Wh/L; in other designs in excess of about 800 Wh/L; in other designs in excess of about 900 Wh/L; in other designs in excess of about 1000 Wh/L) with high-areal loading electrodes may particularly benefit from various aspects of this disclosure because such batteries are typically more sensitive to side reactions between the electrode and electrolyte and may suffer particularly strongly from the above-discussed limitations of certain conventional methodologies.

In some designs, high-power density Li-ion batteries (e.g., cells with power density in excess of about 1000 W/L; in some designs in excess of about 1600 W/L; in other designs in excess of about 3000 W/L, when measured at around 40° C.) particularly with high (e.g., above around 4 mAh/cm²) and very high areal loading electrodes (in some designs, from about 6.0 to about 9.0 mAh/cm²; in some designs from about 9.0 to about 15.0 mAh/cm²; in some designs from about 15.0 to about 30.0 mAh/cm²; in some designs from about 30.0 to about 60.0 mAh/cm²; in some designs from about 60.0 to about 150.0 mAh/cm²; in some designs from about 150.0 to about 300 mAh/cm²; in some designs from about 300.0 to about 1000.0 mAh/cm²) may particularly benefit from various aspects of this disclosure because such batteries are typically harder to produce and because these batteries may suffer particularly strongly from the above-discussed limitations of certain conventional methodologies.

In some designs, Li-ion battery cells that require fast charging (e.g., wherein the cell may be charged from around 10% state of charge to around 80% state of charge within about 20-30 min or less (in some designs within about 10-15 min or less) when charged at around 40° C.) particularly with high-areal loading electrodes (e.g., above 4 mAh/cm²; in some designs, from about 6.0 to about 9.0 mAh/cm²; in some designs from about 9.0 to about 15.0 mAh/cm²; in some designs from about 15.0 to about 30.0 mAh/cm²; in some designs from about 30.0 to about 60.0 mAh/cm²; in some designs from about 60.0 to about 150.0 mAh/cm²; in some designs from about 150.0 to about 300 mAh/cm²; in some designs from about 300.0 to about 1000.0 mAh/cm²) may particularly benefit from various aspects of this disclosure because such batteries are typically more sensitive to side reactions between the electrode and electrolyte and may suffer particularly strongly from the above-discussed limitations of certain conventional methodologies.

In some designs, Li-ion batteries comprising conversion-type or alloying-type or Li metal-type anode materials or conversion-type cathode materials, may particularly benefit from various aspects of this disclosure because such batteries are particularly sensitive to side reactions between the anodes and electrolyte and may suffer particularly strongly from the above-discussed limitations of certain conventional methodologies. In some designs, Si may advantageously be a part of the composite anode particles. In some designs, the weight fraction of Si may range from around 5 wt. % to around 80 wt. % as compared to the total weight of the electrolyte-free electrode (e.g., anode) coating (not counting the weight of the current collector). In some designs, it may be advantageous for the anode to comprise carbon in order to enhance its electrical conductivity, enhance its mechanical properties or provide other benefits. In some designs, the electrode (e.g., anode) may comprise silicon (Si), carbon (C), or a combination of Si and C. In some designs, the electrode (e.g., anode) may comprise Si-containing composite (e.g., nanocomposite) particles.

In some designs, Li-ion batteries comprising dense electrodes (e.g., anodes with porosity of less than around 30-40 vol. %; in some designs less than around 20 vol. %; in some designs less than around 15 vol. %; or cathodes with porosity of less than around 20 vol. %; in some designs less than around 15 vol. %; in some designs less than around 10 vol. %) particularly with high-areal loading electrodes (e.g., above around 4 mAh/cm²) may particularly benefit from various aspects of this disclosure because diffusion of electrolyte in such electrodes is slow and the nonuniform electrode lithiation and the resulting side reactions between the electrolyte and electrodes may induce irreparable damages and because such batteries may suffer particularly strongly from the above-discussed limitations of certain conventional methodologies.

In some designs, Li-ion batteries comprising thick electrodes (e.g., wherein the average thickness of the one side of the densified electrode coating ranges from around 60 to around 800 microns (e.g., in some designs, from around 60 to around 100 microns, in other designs, from around 100 to around 200 microns, in yet other designs from around 200 to around 800 microns), not considering the thickness of the current collector) may particularly benefit from various aspects of this disclosure because such batteries may suffer particularly strongly from the above-discussed limitations of certain conventional methodologies.

In some designs, Li-ion batteries comprising cathodes that are exposed to high maximum voltage during charging (e.g., above around 4.3V vs. Li/Li⁺; in some designs, from around 4.3V to around 4.4V vs. Li/Li⁺; in other designs, from around 4.4V to around 4.5V vs. Li/Li⁺; in yet other designs, from around 4.5V to around 4.6V vs. Li/Li⁺; in yet other designs, from around 4.6V to around 4.7V vs. Li/Li⁺; in yet other designs, above around 4.7V vs. Li/Li⁺) may particularly benefit from various aspects of this disclosure because such batteries may suffer particularly strongly from the above-discussed limitations of certain conventional methodologies (e.g., electrolyte oxidation, formation of gaseous species, cathode dissolution, etc.).

In some designs, Li-ion batteries that are exposed to high maximum voltage during charging (e.g., above around 4.3V; in some designs, from around 4.3V to around 4.4V; in other designs, above around 4.4V; for examples, in some designs, from around 4.4V to around 4.5V; in yet other designs, from around 4.5V to around 4.6V; in yet other designs, from around 4.6V to around 4.7V; in yet other designs, above around 4.7V) may particularly benefit from various aspects of this disclosure because such batteries may suffer particularly strongly from the above-discussed limitations of certain conventional methodologies (e.g., electrolyte oxidation, formation of gaseous species, cathode dissolution, etc.).

In some designs, Li-ion batteries that may be exposed to high maximum temperature (e.g., above around 50° C.; in some designs, from around 50° C. to around 60° C.; in other designs, above around 60° C., for example, in some designs, from around 60° C. to around 65° C.; in yet other designs, from around 65° C. to around 75° C.; in yet other designs, from around 75° C. to around 85° C.; in yet other designs, from around 85° C. to around 95° C.; in yet other designs, above around 95° C.) for a prolonged time (e.g., overall over 10 h during their manufacturing, quality control and lifetime use including storage, charging and operation) may particularly benefit from various aspects of this disclosure because such batteries may suffer particularly strongly from the above-discussed limitations of certain conventional methodologies (e.g., electrolyte oxidation, formation of gaseous species, reduced calendar life, reduced cycle life, etc.).

In some designs, Li-ion batteries that need to be produced with a long calendar life (e.g., above around 5 years; in some designs, from around 5 to around 10 years; in other designs, above around 10 years; for example, in some designs, from around 10 years to around 15 years; in yet other designs, from around 15 years to around 20 years; in yet other designs, from around 20 years to around 25; in yet other designs, from around 25 years to around 30 years; in yet other designs, above around 30 years) may particularly benefit from various aspects of this disclosure because such batteries may suffer particularly strongly from the above-discussed limitations of certain conventional methodologies (e.g., excessive rates of undesirable electrode-electrolyte interactions, particularly at elevated temperatures or when exposed to high charging voltages, etc.)

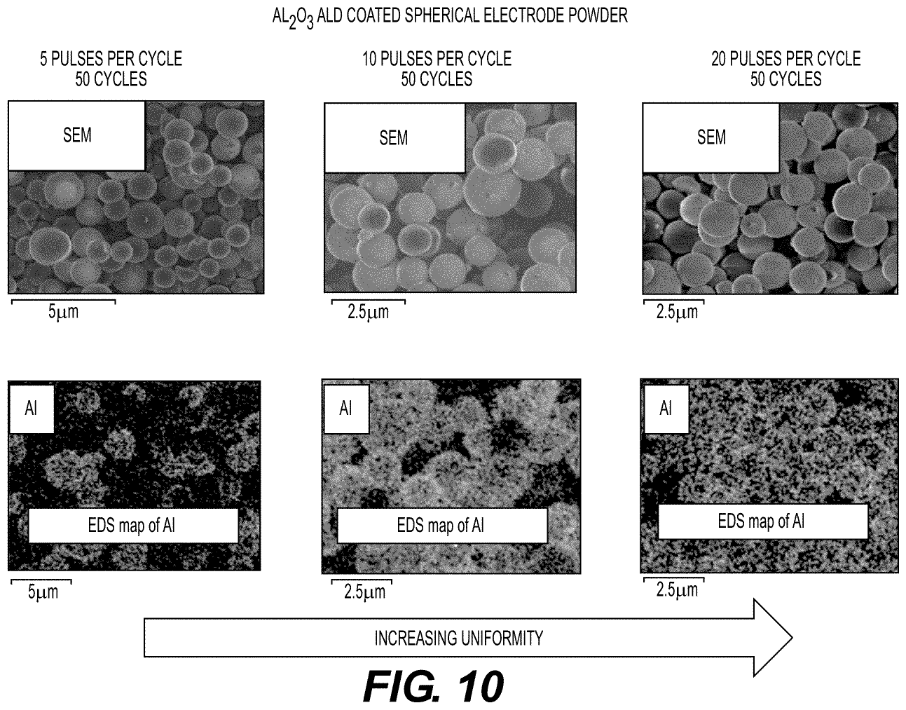

FIG. 10 shows illustrative examples of near-spherical electrode powders at least partially being coated with Al₂O₃ surface layer by means of ALD, according to different aspects of the present disclosure. In particular, scanning electron microscope (SEM) images and Al energy dispersive spectroscopy (EDS) maps are depicted at different pulses per cycle. Note that substantial particle-to-particle nonuniformity of the ALD coatings may take place if insufficient amount of the precursor is provided in each ALD cycle. More precursor gas pulses per cycle (e.g., increasing from 5 to 10 and to 20, in this illustrative example) increases the total amount of the precursor available in each cycle, which may increase particle-to-particle uniformity.

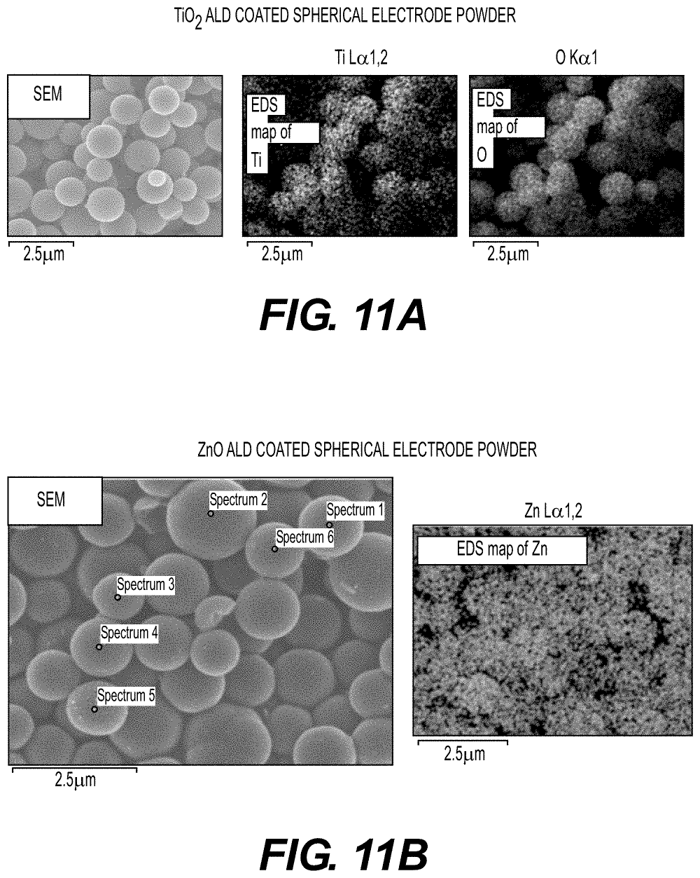

FIG. 11A shows an illustrative example SEM image, Ti EDS map, and O EDS map of near-spherical electrode powders at least partially being coated with TiO₂ surface layer by means of ALD, according to different aspects of the present disclosure.

FIG. 11B shows an illustrative example of an SEM image and Zn EDS map of near-spherical electrode powders at least partially being coated with ZnO surface layer by means of ALD, according to different aspects of the present disclosure.

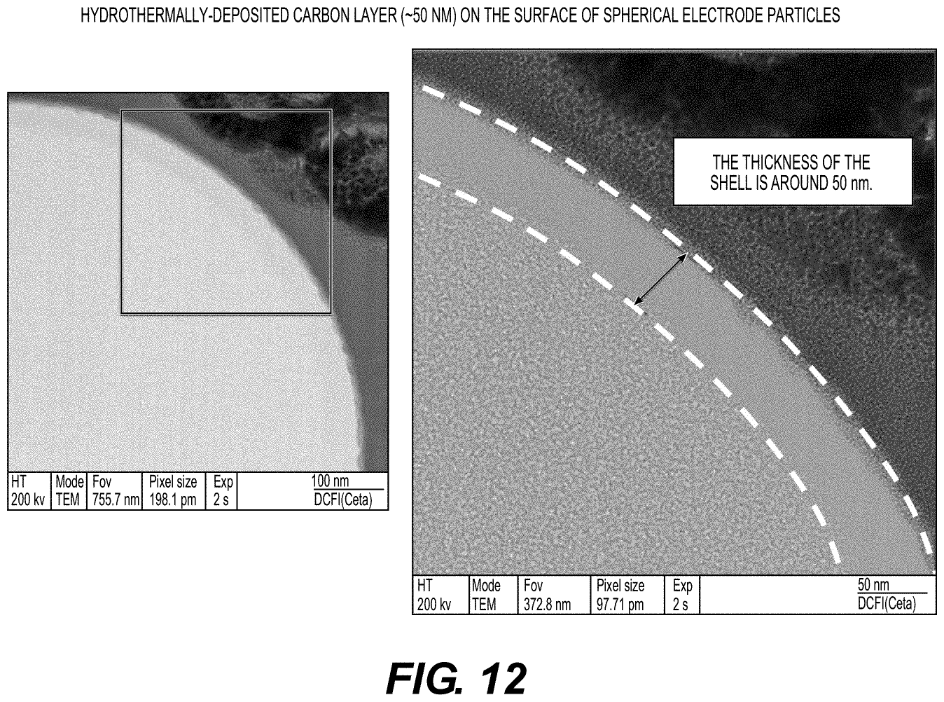

FIG. 12 shows an illustrative example of near-spherical electrode particle at least partially being coated with ˜50 nm carbon-based surface layer deposited by means of hydrothermal carbonization, according to different aspects of the present disclosure.

In some designs, fabrication of Li-ion battery cells according to various aspects of this disclosure may enable fabrication of improved Li-ion battery modules or packs. Such modules or packs may be easier or cheaper to produce, lighter, smaller, and/or safer. At the module or pack levels, in some designs, the assembled battery may enable faster charging and/or more stable operation at different (e.g., low, near-room and/or high) temperatures, enhanced safety, longer calendar and/or longer cycle life and/or other important features. In some designs, better cell-level performance may simplify the pack designs and reduce their weight and volume. In some designs, such performance benefits may be further translated into the better battery-powered or battery pack-powered devices, significantly improving their performance, operational time and/or enabling more or improved features compared to state of the art (in some designs, at the same or even lower cost). As such, in some designs, the improved (and sufficiently differentiated) electronic devices, electric scooters, electric bicycles, electric cars, electric trucks, electric buses, electric ships, electric planes and, more broadly, electric and hybrid electric ground, sea, and aerial (flying) vehicles (including heavy vehicles, autonomous vehicles, unmanned vehicles, planes, space vehicles, satellites, submarines, etc.), battery-powered robots, stationary home or stationary utility energy storage units and improved other end products may be enabled with different aspects of the disclosed technologies. In other words, one or more aspects of the present disclosure may enable one or more major improvements in such devices.

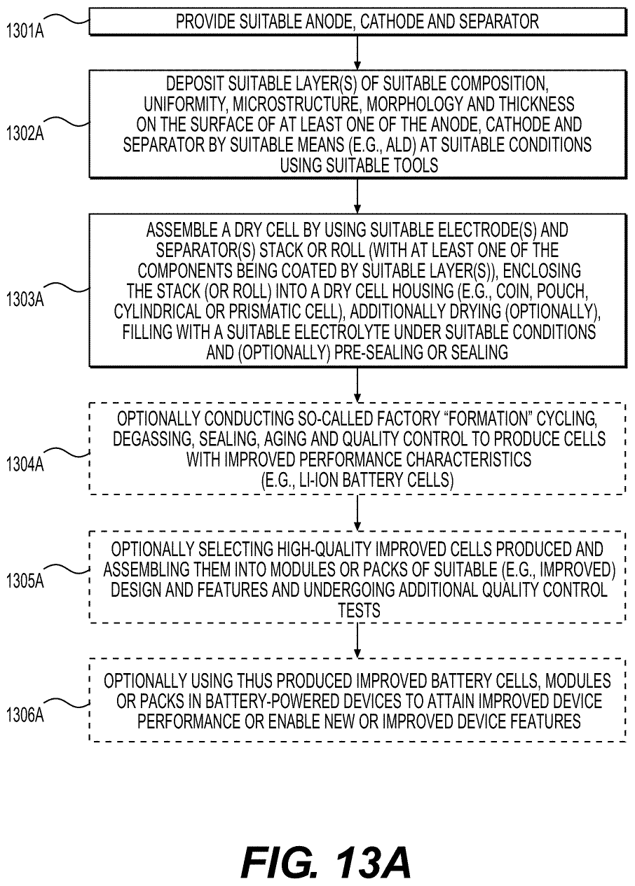

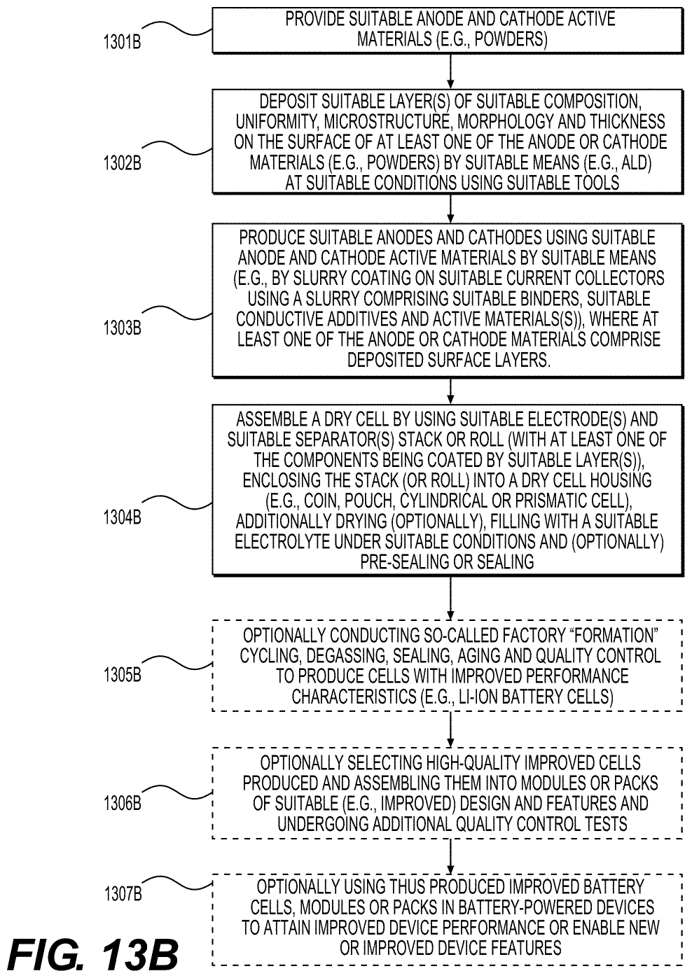

FIGS. 13A and 13B show illustrative examples of methods that may be involved in the fabrication of improved battery (e.g., Li-ion battery) cell or module or pack or battery-powered device, according to various embodiments. In some designs, the various steps depicted in FIGS. 13A-13B may be performed sequentially (i.e., one after the other). In other designs, at least some of the various steps depicted in FIGS. 13A-13B may be performed concurrently, at least in part.

According to the illustrative method shown in FIG. 13A, once the desired cell chemistry is identified and once the suitable anode (e.g., with Si- or C-containing active anode material), suitable cathode (e.g., with Ni- or Mn- or Fe- S- or Cu- or Co-containing active cathode material) and suitable separator (e.g., polymer- and/or ceramic-containing (e.g., Al₂O₃-containing) separator) are provided (step 1301A), a suitable layer(s) is (are) deposited on the surface of at least one of the anode, cathode, and separator by suitable means at 1302A (e.g., as described in different respects of the present disclosure). Note that in some designs, the areal capacity loading of the anode and/or cathode may exceed around 4 mAh/cm². In some designs, the average thickness of the active cathode layer (e.g., on each side of the current collector foil) may exceed around 60 microns. Also note that in some designs, the anode current collector and/or cathode current collector may be porous or be a (nano)composite or an alloy. Also note that the ALD (and CVD) deposited coatings could be easily distinguished from those deposited by physical vapor deposition (PVD), electrodeposition, electroless deposition, electrophoretic deposition, sol-gel deposition, hydrothermal and other known deposition techniques by analyzing their structural features, morphology and the degree of uniformity. Once at least one of the electrodes and/or separator are coated with a suitable internal surface layer (e.g., a ceramic surface layer with previously disclosed composition and an average thickness in the range from about 0.5 nm to about 5 nm), a dry cell may be assembled and filled with a suitable electrolyte (e.g., liquid or solid electrolyte of suitable or desired composition) (step 1303A). Various form factors may be utilized in various designs, including multi-layered stacked or rolled coin cells, multi-layered stacked or rolled pouch or prismatic cells, or (typically rolled) cylindrical cells. Note that in some designs pouch cells may be particularly sensitive to gas generation during heating and/or cycling because they may get “ballooned” under such conditions. Therefore, the deposited surface layer on at least one of the electrodes may not only improve performance in pouch cells, but may also prevent or dramatically reduce electrolyte decomposition and gas generation on such electrode(s) and thus drastically reduce gassing-induced volume expansion in pouch cells. In some designs, thus produced cells of the desired form-factor, size, capacity and total energy (e.g., with cell energy in the range from around 10 Wh to around 1000 Wh) may then be subjected to the so-called “formation” cycle(s) at the factory, degassing, sealing, other procedures and/or additional quality control tests to produce improved battery cells (step 1304A). Such cells may then be assembled into battery modules or packs (typically with the improved designs and features) (step 1305A). Finally, the produced improved battery, battery module(s) and/or battery pack(s) may be used for the formation of improved battery-powered devices (1306A).

The illustrative method shown in FIG. 13B is similar to FIG. 13A, except that after 1301B (which corresponds to 1301A of FIG. 13A), a suitable coating (e.g., a ceramic surface layer with previously disclosed composition and an average thickness in the range from about 0.2 nm to about 2 nm in case of poorly electrically conductive ceramics or from about 0.5 nm to about 5 nm in case of electrically conductive ceramics or an electrically conductive carbon surface layer with an average thickness from about 1 nm to about 50 nm) is deposited on anode or cathode powders (step 1302B) before they are used to produce anode or cathode electrode(s) (step 1303B) by suitable means. Such electrodes are then used for the dry cell assembling and electrolyte filling (step 1304B). The next steps generally correspond to 1303A-1306A of FIG. 13A, and comprise cell processing (e.g., formation, degassing, sealing, aging, etc.) (step 1305B), module or pack assembling (step 1306B) and using cells, modules or packs to produce improved devices (step 1307B).

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electric insulator and an electric conductor). Furthermore, it is also intended that aspects of a clause can be included in any other independent clause, even if the clause is not directly dependent on the independent clause.

Implementation examples are described in the following numbered clauses:

Clause 1. A method of forming a functional, conformal surface layer coating on an internal surface of pores of a porous substrate, comprising: (A1) supplying a first gas stream of first precursor molecules to a porous substrate at a first region in an atomic-layer deposition (ALD) reactor, a portion of the first precursor molecules forming a chemically-bonded layer on the internal surface, another portion of the first precursor molecules becoming physisorbed first precursor molecules; (A2) moving the porous substrate from the first region to a second region in the ALD reactor, the second region being spatially separated from the first region; and (A3) purging the physisorbed first precursor molecules from the porous substrate at the second region; (A4) moving the porous substrate from the second to a third region in the ALD reactor, the third region being spatially separated from the first region and the second region; (A5) supplying a second gas stream of second precursor molecules to the porous substrate at the third region, a portion of the second precursor molecules reacting with the first precursor molecules in the chemically-bonded layer to form at least a portion of the functional, conformal surface layer coating, another portion of the second precursor molecules becoming physisorbed second precursor molecules; (A6) moving the porous substrate from the third region to a fourth region in the ALD reactor, the fourth region being spatially separated from the first region, the second region, and the third region; and (A7) purging the physisorbed second precursor molecules from the porous substrate at the fourth region.

Clause 2. The method of clause 1, wherein: (A3) comprises supplying a first inert gas stream to the porous substrate at the second region; and (A7) comprises supplying a second inert gas stream to the porous substrate at the fourth region.

Clause 3. The method of clause 2, wherein the supplying of the gas stream in one or more of (A1), (A3), (A5), and (A7) comprises supplying the gas stream from one or more supply nozzles such that the gas stream flows from the one or more supply nozzles through the porous substrate to one or more exhaust nozzles, the one or more exhaust nozzles removing the gas stream from the ALD reactor, a spacing between (a) the one or more supply nozzles and the one or more exhaust nozzles and (b) the porous substrate ranging from around 5 microns to around 1 mm, a pressure gradient between the one or more supply nozzles and the one or more exhaust nozzles ranging between around 0.1 atm to around 1000 atm.

Clause 4. The method of any of clauses 1 to 3, wherein (A1) through (A7) are repeated.

Clause 5. The method of any of clauses 1 to 4, wherein the first precursor molecules and/or the second precursor molecules are selected from: metal alkoxides, metal 2,2,6,6-tetramethyl-3,5-heptanedionates, isobutyl-metals, methyl-metals, dimethylamido-metals, cyclopentadienyl-metals, cyclopentadienyl-metal-hydrides, methyl-η⁵-cyclopentadienyl-methoxymethyl-metals, ethyl-metal-hydrides, methyl-metal-hydrides, butyl-metal-hydrides, methyl-pentamethylcyclopentadienyl-metals, metal-alkoxide-(2,2,6,6-tetramethyl-3,5-heptanedionate), pentafluorophenyl-metals, ethyl-metals, phenyl-metals, N,N-bis(trimethylsilyl)amide-metals, butylcyclopentadienyl-metals, metal halides, tert-butoxy-metals, tert-pentoxy-metals, and hexamethyldisilazane.

Clause 6. The method of any of clauses 1 to 5, wherein the first precursor molecules and/or the second precursor molecules comprise one or more of the following: reductants, lithium sources, fluorine sources, aluminum sources, oxygen sources, phosphorous sources, nitrogen sources, iron sources, titanium sources, lanthanum sources, zirconium sources, cerium sources, and niobium sources.

Clause 7. The method of any of clauses 1 to 6, further comprising: (A8) fluorinating the porous substrate, after formation of at least one portion of the functional, conformal surface layer coating.

Clause 8. The method of any of clauses 1 to 7, further comprising: (A9) annealing the porous substrate, after formation of at least one portion of the functional, conformal surface layer coating.

Clause 9. The method of any of clauses 1 to 8, wherein the porous substrate comprises a current collector and a porous electrode coating on the current collector.

Clause 10. The method of clause 9, wherein the current collector is porous.

Clause 11. The method of any of clauses 9 to 10, wherein the current collector comprises Cu or Al.

Clause 12. The method of any of clauses 1 to 11, wherein the porous substrate corresponds to at least part of an anode electrode for a Li-ion battery cell.

Clause 13. The method of any of clause 12, wherein the anode electrode comprises silicon and/or carbon.

Clause 14. The method of any of clauses 1 to 13, wherein the porous substrate corresponds to at least part of a cathode electrode for a Li-ion battery cell.

Clause 15. A method of forming a functional surface layer coating on particles of a particle powder, comprising the steps of: (B1) supplying a first gas stream of first precursor molecules to the particles of the particle powder at a first region in a tubular atomic-layer deposition (ALD) reactor, a portion of the first precursor molecules forming a chemically-bonded layer on the particles of the particle powder, another portion of the first precursor molecules becoming physisorbed first precursor molecules; (B2) moving the particle powder from the first region to a second region in the tubular ALD reactor, the second region being spatially separated from the first region; (B3) purging the physisorbed first precursor molecules from the particle powder at the second region; (B4) moving the particle powder from the second to a third region in the tubular ALD reactor, the third region being spatially separated from the first region and the second region; (B5) supplying a second gas stream of second precursor molecules to the particle powder at the third region, a portion of the second precursor molecules reacting with the first precursor molecules in the chemically-bonded layer to form at least a portion of the functional surface layer coating, another portion of the second precursor molecules becoming physisorbed second precursor molecules; (B6) moving the particle powder from the third region to a fourth region in the tubular ALD reactor, the fourth region being spatially separated from the first region, the second region, and the third region; and (B7) purging the physisorbed second precursor molecules from the particle powder at the fourth region.

Clause 16. The method of clause 15, wherein the particle powder is moved from the first region to the second region at (B2), from the second region to the third region at (B4), and from the third region to the fourth region at (B6) via a rotating auger inside the tubular ALD reactor.

Clause 17. The method of any of clauses 15 to 16, wherein: (B3) comprises supplying a first inert gas stream to the particle powder at the second region; and (B7) comprises supplying a second inert gas stream to the particle powder at the fourth region.

Clause 18. The method of clause 17, wherein the supplying of the gas stream in one or more of (B1), (B3), (B5), and (B7) comprises supplying the gas stream from one or more supply nozzles such that the inert gas stream flows from the one or more supply nozzles through the particle powder to one or more exhaust nozzles, the one or more exhaust nozzles removing the gas stream from the tubular ALD reactor, a pressure gradient between the one or more supply nozzles and the one or more exhaust nozzles ranging between around 0.1 atm to around 1000 atm.

Clause 19. The method of any of clauses 15 to 18, wherein steps (B1) through (B7) are repeated.

Clause 20. The method of any of clauses 15 to 19, wherein the first precursor molecules and/or the second precursor molecules are selected from: metal alkoxides, metal 2,2,6,6-tetramethyl-3,5-heptanedionates, isobutyl-metals, methyl-metals, dimethylamido-metals, cyclopentadienyl-metals, cyclopentadienyl-metal-hydrides, methyl-η⁵-cyclopentadienyl-methoxymethyl-metals, ethyl-metal-hydrides, methyl-metal-hydrides, butyl-metal-hydrides, methyl-pentamethylcyclopentadienyl-metals, metal-alkoxide-(2,2,6,6-tetramethyl-3,5-heptanedionate), pentafluorophenyl-metals, ethyl-metals, phenyl-metals, N,N-bis(trimethylsilyl)amide-metals, butylcyclopentadienyl-metals, metal halides, tert-butoxy-metals, tert-pentoxy-metals, and hexamethyldisilazane.

Clause 21. The method of any of clauses 15 to 20, wherein the first precursor molecules and/or the second precursor molecules comprise one or more of the following: reductants, lithium sources, fluorine sources, aluminum sources, oxygen sources, phosphorous sources, nitrogen sources, iron sources, titanium sources, lanthanum sources, zirconium sources, cerium sources, and niobium sources.

Clause 22. The method of any of clauses 15 to 21, further comprising: (B8) fluorinating the particle powder, after formation of at least one portion of the functional surface layer coating.

Clause 23. The method of any of clauses 15 to 22, further comprising: (B9) annealing the particle powder, after formation of at least one portion of the functional surface layer coating.

Clause 24. The method of any of clauses 15 to 23, wherein the particles of the particle powder comprise anode particles or cathode particles.

Clause 25. An atomic-layer deposition (ALD) system for forming a functional, conformal surface layer coating on an internal surface of pores of a porous substrate, comprising: an ALD reactor comprising a plurality of regions, each one of the regions being spatially separated from others of the regions, the plurality of regions including a first region, a second region, a third region, and a fourth region; a substrate mover configured to move the porous substrate in the ALD reactor including moving the porous substrate from the first region to the second region, from the second region to the third region, and from the third region to the fourth region; one or more first gas supply nozzles at the first region for supplying a first gas stream of first precursor molecules to the porous substrate, a portion of the first precursor molecules forming a chemically-bonded layer on the internal surface, another portion of the first precursor molecules becoming physisorbed first precursor molecules; one or more first gas exhaust nozzles at the first region for removing the first gas stream from the ALD reactor, the first gas stream flowing from the first gas supply nozzles through the porous substrate to the first gas exhaust nozzles; one or more first inert gas supply nozzles at the second region for supplying a first inert gas stream to the porous substrate; one or more first inert gas exhaust nozzles at the second region for removing the first inert gas stream from the ALD reactor, the first inert gas stream flowing from the first inert gas supply nozzles through the porous substrate to the first inert gas exhaust nozzles, the physisorbed first precursor molecules being purged from the porous substrate by the first inert gas stream; one or more second gas supply nozzles at the third region for supplying a second gas stream of second precursor molecules to the porous substrate, a portion of the second precursor molecules reacting with the first precursor molecules in the chemically-bonded layer to form at least a portion of the functional, conformal surface layer coating, another portion of the second precursor molecules becoming physisorbed second precursor molecules; one or more second gas exhaust nozzles at the third region for removing the second gas stream from the ALD reactor, the second gas stream flowing from the second gas supply nozzles through the porous substrate to the second gas exhaust nozzles; one or more second inert gas supply nozzles at the fourth region for supplying a second inert gas stream to the porous substrate; and one or more second inert gas exhaust nozzles at the fourth region for removing the second inert gas stream from the ALD reactor, the second inert gas stream flowing from the second inert gas supply nozzles through the porous substrate to the second inert gas exhaust nozzles, the physisorbed second precursor molecules being purged from the porous substrate by the second inert gas stream.

Clause 26. The atomic-layer deposition (ALD) system of clause 25, wherein: for one or more of (1) the first gas supply nozzles and the first gas exhaust nozzles, (2) the first inert gas supply nozzles and the first inert gas exhaust nozzles, (3) the second gas supply nozzles and the second gas exhaust nozzles, and (4) the second inert gas supply nozzles and the second inert gas exhaust nozzles, a spacing between (a) the respective gas supply nozzles and the respective gas exhaust nozzles and (b) the porous substrate ranges from around 5 microns to around 1 mm; and a pressure gradient between the respective gas supply nozzles and the respective gas exhaust nozzles ranges between around 0.1 atm to around 1000 atm.

Clause 27. An atomic-layer deposition (ALD) system for forming a functional, surface layer coating on individual particles of a particle powder, comprising: a tubular ALD reactor comprising a plurality of regions, each one of the regions being spatially separated from others of the regions, the plurality of regions including a first region, a second region, a third region, and a fourth region; a powder mover inside the tubular ALD reactor configured to move the powder in the tubular ALD reactor including moving the powder from the first region to the second region, from the second region to the third region, and from the third region to the fourth region; one or more first gas supply nozzles at the first region for supplying a first gas stream of first precursor molecules to the powder, a portion of the first precursor molecules forming a chemically-bonded layer on the particles, another portion of the first precursor molecules becoming physisorbed first precursor molecules; one or more first gas exhaust nozzles at the first region for removing the first gas stream from the tubular ALD reactor, the first gas stream flowing from the first gas supply nozzles through the powder to the first gas exhaust nozzles; one or more first inert gas supply nozzles at the second region for supplying a first inert gas stream to the powder; one or more first inert gas exhaust nozzles at the second region for removing the first inert gas stream from the tubular ALD reactor, the first inert gas stream flowing from the first inert gas supply nozzles through the powder to the first inert gas exhaust nozzles, the physisorbed first precursor molecules being purged from the powder by the first inert gas stream; one or more second gas supply nozzles at the third region for supplying a second gas stream of second precursor molecules to the powder, a portion of the second precursor molecules reacting with the first precursor molecules in the chemically-bonded layer to form at least a portion of the functional, surface layer coating, another portion of the second precursor molecules becoming physisorbed second precursor molecules; one or more second gas exhaust nozzles at the third region for removing the second gas stream from the tubular ALD reactor, the second gas stream flowing from the second gas supply nozzles through the powder to the second gas exhaust nozzles; one or more second inert gas supply nozzles at the fourth region for supplying a second inert gas stream to the powder; and one or more second inert gas exhaust nozzles at the fourth region for removing the second inert gas stream from the tubular ALD reactor, the second inert gas stream flowing from the second inert gas supply nozzles through the powder to the second inert gas exhaust nozzles, the physisorbed second precursor molecules being purged from the powder by the second inert gas stream.

Clause 28. The ALD system of clause 27, wherein for one or more of (1) the first gas supply nozzles and the first gas exhaust nozzles, (2) the first inert gas supply nozzles and the first inert gas exhaust nozzles, (3) the second gas supply nozzles and the second gas exhaust nozzles, and (4) the second inert gas supply nozzles and the second inert gas exhaust nozzles, a pressure gradient between the respective gas supply nozzles and the respective gas exhaust nozzles ranges between around 0.1 atm to around 1000 atm.

Clause 29. The atomic-layer deposition (ALD) system of any of clauses 27 to 28, wherein the powder mover comprises a rotating auger.

Clause 30. A porous electrode for use in an Li-ion battery cell, comprising: a current collector; an active material-comprising coating; and one or more functional, conformal surface layer coatings at least partially deposited on an internal surface of pores of the porous electrode, wherein the one or more functional, conformal surface layer coatings exhibit an average thickness in the range from around 0.3 nm to around 50 nm on at least part of the internal surface, and wherein the porous electrode exhibits an areal capacity loading of more than about 4 mAh/cm².

Clause 31. The porous electrode of clause 30, wherein the standard deviation of the surface layer coating thickness is less than or equal to 4 nm.

Clause 32. The porous electrode of any of clauses 30 to 31, wherein the porous electrode is integrated into the Li-ion battery cell, further comprising: electrolyte filling pores of the electrode and ionically coupling the porous electrode with another porous electrode; and a separator electrically separating the porous electrode from the another porous electrode.

Clause 33. The porous electrode of any of clauses 30 to 32, wherein the porous electrode corresponds to an anode electrode for use in the Li-ion battery cell.

Clause 34. The porous electrode of clause 33, wherein the anode electrode comprises silicon (Si) or carbon (C) or both.

Clause 35. The porous electrode of any of clauses 30 to 34, wherein the porous electrode corresponds to a cathode electrode for use in the Li-ion battery cell.

Clause 36. The porous electrode of any of clauses 30 to 35, wherein the active material-comprising coating comprises electrode particles, and wherein the one or more functional, conformal surface layer coatings are at least partially deposited at least upon outer surfaces of the electrode particles that are accessible via the pores of the porous electrode.

Clause 37. The porous electrode of any of clauses 30 to 36, wherein the one or more functional, conformal surface layer coatings exhibit the average thickness in the range from around 0.3 nm to around 50 nm: across a bottom 20% part of the active material-comprising coating that is on a first side of the active material-comprising coating adjacent to the current collector, or across a top 20% part of the active material-comprising coating that is on a second side of the active material-comprising coating away from the current collector, or across an entirety of the active material-comprising coating.

Clause 38. A Li-ion battery cell, comprising the porous electrode of any of clauses 30-37.

Clause 39. The Li-ion battery cell of clause 38, wherein the Li-ion battery cell is capable of charging to above about 4.4 V during operation, or wherein the Li-ion battery cell is capable of exhibiting a calendar life in excess of about 10 years, or wherein the Li-ion battery cell is capable of remaining operable in response to exposure to over about 60° C. for over about 10 hours during manufacturing, operation or storage, or any combination thereof.

Clause 40. A Li-ion battery module or Li-ion battery pack, comprising: the Li-ion battery cell of any of clauses 38-39.

Clause 41. A battery electrode composition for use in an Li-ion battery cell, comprising: an electrode particle comprising an active material and internal pores, wherein one or more functional, conformal surface layer coatings are at least partially deposited on an internal surface of the internal pores of the electrode particle, and wherein the one or more functional, conformal surface layer coatings exhibit an average thickness in the range from around 0.3 nm to around 50 nm on at least part of the internal surface.

Clause 42. The battery electrode composition of clause 41, wherein the electrode particle is an anode particle or a cathode particle.

Clause 43. The battery electrode composition of any of clauses 41 to 42, wherein the electrode particle comprises one or more closed internal pores that are inaccessible via the internal pores and upon which no functional, conformal surface layer coating is deposited.

Clause 44. A Li-ion battery cell, comprising: the battery electrode composition of any of clauses 41-43.

Clause 45. The Li-ion battery cell of clause 44, wherein the Li-ion battery cell is capable of charging to above about 4.4 V during operation, or wherein the Li-ion battery cell is capable of exhibiting a calendar life in excess of about 10 years, wherein the Li-ion battery cell is capable of remaining operable in response to exposure to over about 60° C. for over about 10 hours during manufacturing, operation or storage, or any combination thereof.

Clause 46. A Li-ion battery module or Li-ion battery pack, comprising: the Li-ion battery cell of any of clauses 44-45.

This description is provided to enable any person skilled in the art to make or use embodiments of the present invention. It will be appreciated, however, that the present invention is not limited to the particular formulations, process steps, and materials disclosed herein, as various modifications to these embodiments will be readily apparent to those skilled in the art. That is, the generic principles defined herein may be applied to other embodiments without departing from the spirit or scope of the invention.

1. A method of forming a functional, conformal surface layer coating on an internal surface of pores of a porous substrate, comprising:
(A1) supplying a first gas stream of first precursor molecules to a porous substrate at a first region in an atomic-layer deposition (ALD) reactor, a portion of the first precursor molecules forming a chemically-bonded layer on the internal surface, another portion of the first precursor molecules becoming physisorbed first precursor molecules;
(A2) moving the porous substrate from the first region to a second region in the ALD reactor, the second region being spatially separated from the first region; and
(A3) purging the physisorbed first precursor molecules from the porous substrate at the second region;
(A4) moving the porous substrate from the second to a third region in the ALD reactor, the third region being spatially separated from the first region and the second region;
(A5) supplying a second gas stream of second precursor molecules to the porous substrate at the third region, a portion of the second precursor molecules reacting with the first precursor molecules in the chemically-bonded layer to form at least a portion of the functional, conformal surface layer coating, another portion of the second precursor molecules becoming physisorbed second precursor molecules;
(A6) moving the porous substrate from the third region to a fourth region in the ALD reactor, the fourth region being spatially separated from the first region, the second region, and the third region; and
(A7) purging the physisorbed second precursor molecules from the porous substrate at the fourth region.

2. The method of claim 1, wherein:
(A3) comprises supplying a first inert gas stream to the porous substrate at the second region; and
(A7) comprises supplying a second inert gas stream to the porous substrate at the fourth region.

3. The method of claim 2, wherein the supplying of the gas stream in one or more of (A1), (A3), (A5), and (A7) comprises supplying the gas stream from one or more supply nozzles such that the gas stream flows from the one or more supply nozzles through the porous substrate to one or more exhaust nozzles, the one or more exhaust nozzles removing the gas stream from the ALD reactor, a spacing between (a) the one or more supply nozzles and the one or more exhaust nozzles and (b) the porous substrate ranging from around 5 microns to around 1 mm, a pressure gradient between the one or more supply nozzles and the one or more exhaust nozzles ranging between around 0.1 atm to around 1000 atm.

4. The method of claim 1, wherein (A1) through (A7) are repeated.

5. The method of claim 1, wherein the first precursor molecules and/or the second precursor molecules are selected from: metal alkoxides, metal 2,2,6,6-tetramethyl-3,5-heptanedionates, isobutyl-metals, methyl-metals, dimethylamido-metals, cyclopentadienyl-metals, cyclopentadienyl-metal-hydrides, methyl-η⁵-cyclopentadienyl-methoxymethyl-metals, ethyl-metal-hydrides, methyl-metal-hydrides, butyl-metal-hydrides, methyl-pentamethylcyclopentadienyl-metals, metal-alkoxide-(2,2,6,6-tetramethyl-3,5-heptanedionate), pentafluorophenyl-metals, ethyl-metals, phenyl-metals, N,N-bis(trimethylsilyl)amide-metals, butylcyclopentadienyl-metals, metal halides, tert-butoxy-metals, tert-pentoxy-metals, and hexamethyldisilazane.

6. The method of claim 1, wherein the first precursor molecules and/or the second precursor molecules comprise one or more of the following: reductants, lithium sources, fluorine sources, aluminum sources, oxygen sources, phosphorous sources, nitrogen sources, iron sources, titanium sources, lanthanum sources, zirconium sources, cerium sources, and niobium sources.

7. The method of claim 1, further comprising:
(A8) fluorinating the porous substrate, after formation of at least one portion of the functional, conformal surface layer coating.

8. The method of claim 1, further comprising:
(A9) annealing the porous substrate, after formation of at least one portion of the functional, conformal surface layer coating.

9. The method of claim 1, wherein the porous substrate comprises a current collector and a porous electrode coating on the current collector.

10. The method of claim 9, wherein the current collector is porous.

11. The method of claim 9, wherein the current collector comprises Cu or Al.

12. The method of claim 1, wherein the porous substrate corresponds to at least part of an anode electrode for a Li-ion battery cell.

13. The method of claim 12, wherein the anode electrode comprises silicon and/or carbon.

14. The method of claim 1, wherein the porous substrate corresponds to at least part of a cathode electrode for a Li-ion battery cell.

15. A method of forming a functional surface layer coating on particles of a particle powder, comprising the steps of:
(B1) supplying a first gas stream of first precursor molecules to the particles of the particle powder at a first region in a tubular atomic-layer deposition (ALD) reactor, a portion of the first precursor molecules forming a chemically-bonded layer on the particles of the particle powder, another portion of the first precursor molecules becoming physisorbed first precursor molecules;
(B2) moving the particle powder from the first region to a second region in the tubular ALD reactor, the second region being spatially separated from the first region;
(B3) purging the physisorbed first precursor molecules from the particle powder at the second region;
(B4) moving the particle powder from the second to a third region in the tubular ALD reactor, the third region being spatially separated from the first region and the second region;
(B5) supplying a second gas stream of second precursor molecules to the particle powder at the third region, a portion of the second precursor molecules reacting with the first precursor molecules in the chemically-bonded layer to form at least a portion of the functional surface layer coating, another portion of the second precursor molecules becoming physisorbed second precursor molecules;
(B6) moving the particle powder from the third region to a fourth region in the tubular ALD reactor, the fourth region being spatially separated from the first region, the second region, and the third region; and
(B7) purging the physisorbed second precursor molecules from the particle powder at the fourth region.

16. The method of claim 15, wherein the particle powder is moved from the first region to the second region at (B2), from the second region to the third region at (B4), and from the third region to the fourth region at (B6) via a rotating auger inside the tubular ALD reactor.

17. The method of claim 15, wherein:
(B3) comprises supplying a first inert gas stream to the particle powder at the second region; and
(B7) comprises supplying a second inert gas stream to the particle powder at the fourth region.

18. The method of claim 17, wherein the supplying of the gas stream in one or more of (B1), (B3), (B5), and (B7) comprises supplying the gas stream from one or more supply nozzles such that the inert gas stream flows from the one or more supply nozzles through the particle powder to one or more exhaust nozzles, the one or more exhaust nozzles removing the gas stream from the tubular ALD reactor, a pressure gradient between the one or more supply nozzles and the one or more exhaust nozzles ranging between around 0.1 atm to around 1000 atm.

19. The method of claim 15, wherein steps (B1) through (B7) are repeated.

20. The method of claim 15, wherein the first precursor molecules and/or the second precursor molecules are selected from: metal alkoxides, metal 2,2,6,6-tetramethyl-3,5-heptanedionates, isobutyl-metals, methyl-metals, dimethylamido-metals, cyclopentadienyl-metals, cyclopentadienyl-metal-hydrides, methyl-η⁵-cyclopentadienyl-methoxymethyl-metals, ethyl-metal-hydrides, methyl-metal-hydrides, butyl-metal-hydrides, methyl-pentamethylcyclopentadienyl-metals, metal-alkoxide-(2,2,6,6-tetramethyl-3,5-heptanedionate), pentafluorophenyl-metals, ethyl-metals, phenyl-metals, N,N-bis(trimethylsilyl)amide-metals, butylcyclopentadienyl-metals, metal halides, tert-butoxy-metals, tert-pentoxy-metals, and hexamethyldisilazane.

21. The method of claim 15, wherein the first precursor molecules and/or the second precursor molecules comprise one or more of the following: reductants, lithium sources, fluorine sources, aluminum sources, oxygen sources, phosphorous sources, nitrogen sources, iron sources, titanium sources, lanthanum sources, zirconium sources, cerium sources, and niobium sources.

22. The method of claim 15, further comprising:
(B8) fluorinating the particle powder, after formation of at least one portion of the functional surface layer coating.

23. The method of claim 15, further comprising:
(B9) annealing the particle powder, after formation of at least one portion of the functional surface layer coating.

24. The method of claim 15, wherein the particles of the particle powder comprise anode particles or cathode particles.

25. An atomic-layer deposition (ALD) system for forming a functional, conformal surface layer coating on an internal surface of pores of a porous substrate, comprising:
an ALD reactor comprising a plurality of regions, each one of the regions being spatially separated from others of the regions, the plurality of regions including a first region, a second region, a third region, and a fourth region;
a substrate mover configured to move the porous substrate in the ALD reactor including moving the porous substrate from the first region to the second region, from the second region to the third region, and from the third region to the fourth region;
one or more first gas supply nozzles at the first region for supplying a first gas stream of first precursor molecules to the porous substrate, a portion of the first precursor molecules forming a chemically-bonded layer on the internal surface, another portion of the first precursor molecules becoming physisorbed first precursor molecules;
one or more first gas exhaust nozzles at the first region for removing the first gas stream from the ALD reactor, the first gas stream flowing from the first gas supply nozzles through the porous substrate to the first gas exhaust nozzles;
one or more first inert gas supply nozzles at the second region for supplying a first inert gas stream to the porous substrate;
one or more first inert gas exhaust nozzles at the second region for removing the first inert gas stream from the ALD reactor, the first inert gas stream flowing from the first inert gas supply nozzles through the porous substrate to the first inert gas exhaust nozzles, the physisorbed first precursor molecules being purged from the porous substrate by the first inert gas stream;
one or more second gas supply nozzles at the third region for supplying a second gas stream of second precursor molecules to the porous substrate, a portion of the second precursor molecules reacting with the first precursor molecules in the chemically-bonded layer to form at least a portion of the functional, conformal surface layer coating, another portion of the second precursor molecules becoming physisorbed second precursor molecules;
one or more second gas exhaust nozzles at the third region for removing the second gas stream from the ALD reactor, the second gas stream flowing from the second gas supply nozzles through the porous substrate to the second gas exhaust nozzles;
one or more second inert gas supply nozzles at the fourth region for supplying a second inert gas stream to the porous substrate; and
one or more second inert gas exhaust nozzles at the fourth region for removing the second inert gas stream from the ALD reactor, the second inert gas stream flowing from the second inert gas supply nozzles through the porous substrate to the second inert gas exhaust nozzles, the physisorbed second precursor molecules being purged from the porous substrate by the second inert gas stream.

26. The atomic-layer deposition (ALD) system of claim 25, wherein:
for one or more of (1) the first gas supply nozzles and the first gas exhaust nozzles, (2) the first inert gas supply nozzles and the first inert gas exhaust nozzles, (3) the second gas supply nozzles and the second gas exhaust nozzles, and (4) the second inert gas supply nozzles and the second inert gas exhaust nozzles,
a spacing between (a) the respective gas supply nozzles and the respective gas exhaust nozzles and (b) the porous substrate ranges from around 5 microns to around 1 mm; and
a pressure gradient between the respective gas supply nozzles and the respective gas exhaust nozzles ranges between around 0.1 atm to around 1000 atm.

27. An atomic-layer deposition (ALD) system for forming a functional, surface layer coating on individual particles of a particle powder, comprising:
a tubular ALD reactor comprising a plurality of regions, each one of the regions being spatially separated from others of the regions, the plurality of regions including a first region, a second region, a third region, and a fourth region;
a powder mover inside the tubular ALD reactor configured to move the powder in the tubular ALD reactor including moving the powder from the first region to the second region, from the second region to the third region, and from the third region to the fourth region;
one or more first gas supply nozzles at the first region for supplying a first gas stream of first precursor molecules to the powder, a portion of the first precursor molecules forming a chemically-bonded layer on the particles, another portion of the first precursor molecules becoming physisorbed first precursor molecules;
one or more first gas exhaust nozzles at the first region for removing the first gas stream from the tubular ALD reactor, the first gas stream flowing from the first gas supply nozzles through the powder to the first gas exhaust nozzles;
one or more first inert gas supply nozzles at the second region for supplying a first inert gas stream to the powder;
one or more first inert gas exhaust nozzles at the second region for removing the first inert gas stream from the tubular ALD reactor, the first inert gas stream flowing from the first inert gas supply nozzles through the powder to the first inert gas exhaust nozzles, the physisorbed first precursor molecules being purged from the powder by the first inert gas stream;
one or more second gas supply nozzles at the third region for supplying a second gas stream of second precursor molecules to the powder, a portion of the second precursor molecules reacting with the first precursor molecules in the chemically-bonded layer to form at least a portion of the functional, surface layer coating, another portion of the second precursor molecules becoming physisorbed second precursor molecules;
one or more second gas exhaust nozzles at the third region for removing the second gas stream from the tubular ALD reactor, the second gas stream flowing from the second gas supply nozzles through the powder to the second gas exhaust nozzles;
one or more second inert gas supply nozzles at the fourth region for supplying a second inert gas stream to the powder; and
one or more second inert gas exhaust nozzles at the fourth region for removing the second inert gas stream from the tubular ALD reactor, the second inert gas stream flowing from the second inert gas supply nozzles through the powder to the second inert gas exhaust nozzles, the physisorbed second precursor molecules being purged from the powder by the second inert gas stream.

28. The ALD system of claim 27, wherein for one or more of (1) the first gas supply nozzles and the first gas exhaust nozzles, (2) the first inert gas supply nozzles and the first inert gas exhaust nozzles, (3) the second gas supply nozzles and the second gas exhaust nozzles, and (4) the second inert gas supply nozzles and the second inert gas exhaust nozzles, a pressure gradient between the respective gas supply nozzles and the respective gas exhaust nozzles ranges between around 0.1 atm to around 1000 atm.

29. The ALD system of claim 27, wherein the powder mover comprises a rotating auger.

30. A porous electrode for use in an Li-ion battery cell, comprising:
a current collector;
an active material-comprising coating; and
one or more functional, conformal surface layer coatings at least partially deposited on an internal surface of pores of the porous electrode,
wherein the one or more functional, conformal surface layer coatings exhibit an average thickness in the range from around 0.3 nm to around 50 nm on at least part of the internal surface, and
wherein the porous electrode exhibits an areal capacity loading of more than about 4 mAh/cm².

31. The porous electrode of claim 30, wherein the standard deviation of the surface layer coating thickness is less than or equal to 4 nm.

32. The porous electrode of claim 30, wherein the porous electrode is integrated into the Li-ion battery cell, further comprising:
electrolyte filling pores of the porous electrode and ionically coupling the porous electrode with another porous electrode; and
a separator electrically separating the porous electrode from the another porous electrode.

33. The porous electrode of claim 30, wherein the porous electrode corresponds to an anode electrode for use in the Li-ion battery cell.

34. The porous electrode of claim 33, wherein the anode electrode comprises silicon (Si) or carbon (C) or both.

35. The porous electrode of claim 30, wherein the porous electrode corresponds to a cathode electrode for use in the Li-ion battery cell.

36. The porous electrode of claim 30,
wherein the active material-comprising coating comprises electrode particles, and
wherein the one or more functional, conformal surface layer coatings are at least partially deposited at least upon outer surfaces of the electrode particles that are accessible via the pores of the porous electrode.

37. The porous electrode of claim 30, wherein the one or more functional, conformal surface layer coatings exhibit the average thickness in the range from around 0.3 nm to around 50 nm:
across a bottom 20% part of the active material-comprising coating that is on a first side of the active material-comprising coating adjacent to the current collector, or
across a top 20% part of the active material-comprising coating that is on a second side of the active material-comprising coating away from the current collector, or
across an entirety of the active material-comprising coating.

38. A Li-ion battery cell, comprising the porous electrode of claim 30.

39. The Li-ion battery cell of claim 38,
wherein the Li-ion battery cell is capable of charging to above about 4.4 V during operation, or
wherein the Li-ion battery cell is capable of exhibiting a calendar life in excess of about 10 years, or
wherein the Li-ion battery cell is capable of remaining operable in response to exposure to over about 60° C. for over about 10 hours during manufacturing, operation or storage, or
any combination thereof.

40. A Li-ion battery module or Li-ion battery pack, comprising:
the Li-ion battery cell of claim 38.

41. A battery electrode composition for use in an Li-ion battery cell, comprising:
an electrode particle comprising an active material and internal pores,
wherein one or more functional, conformal surface layer coatings are at least partially deposited on an internal surface of the internal pores of the electrode particle, and
wherein the one or more functional, conformal surface layer coatings exhibit an average thickness in the range from around 0.3 nm to around 50 nm on at least part of the internal surface.

42. The battery electrode composition of claim 41, wherein the electrode particle is an anode particle or a cathode particle.

43. The battery electrode composition of claim 41, wherein the electrode particle comprises one or more closed internal pores that are inaccessible via the internal pores and upon which no functional, conformal surface layer coating is deposited.

44. A Li-ion battery cell, comprising:
the battery electrode composition of claim 41.

45. The Li-ion battery cell of claim 44,
wherein the Li-ion battery cell is capable of charging to above about 4.4 V during operation, or
wherein the Li-ion battery cell is capable of exhibiting a calendar life in excess of about 10 years,
wherein the Li-ion battery cell is capable of remaining operable in response to exposure to over about 60° C. for over about 10 hours during manufacturing, operation or storage, or
any combination thereof.

46. A Li-ion battery module or Li-ion battery pack, comprising:
the Li-ion battery cell of claim 44.
